(19) United States
(12) Patent Application Publication
(10) Pub. No.: US 2026/0123029 A1
(43) Pub. Date: Apr. 30, 2026

(54) SEMICONDUCTOR PROCESSING FOR FACET TRAPPING IN EPITAXIAL GROWTH

(71) Applicant: TEXAS INSTRUMENTS INCORPORATED, Dallas, TX (US)

(72) Inventors: Ian Laboriante, Lehi, UT (US); Jonathan Lane, Sandy, UT (US)

(21) Appl. No.: 18/930,046

(22) Filed: Oct. 29, 2024

(51) Int. Cl. H01L 27/06; H01L 21/02; H01L 29/08; H01L 29/66; H01L 29/737

(52) U.S. Cl. CPC H10D 84/401; H10D 10/021; H10D 10/80; H10D 62/137; H10P 14/6336; H10P 14/69215

(57) ABSTRACT

In examples, a device includes a semiconductor substrate, a pedestal dielectric stack, a bipolar junction transistor (BJT), a field effect transistor (FET), and a composite structure. The substrate includes a BJT region, a FET region, and a transition region between the BJT and FET regions. The BJT and FET are on the substrate in the BJT and FET regions, respectively. A BJT portion is in an opening through the pedestal dielectric stack. The opening is defined at least in part by a retrograde sidewall. The composite structure is on the substrate in the transition region and includes a residual dielectric stack, a dielectric layer over the residual dielectric stack, and a first material over the dielectric layer. The residual dielectric stack has a material same as the pedestal dielectric stack. The dielectric layer includes a nitride. The first material is same as a gate electrode of the FET.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices. Further, integrating a BJT with other devices may complicate that semiconductor processing.

### SUMMARY

An example described herein is a semiconductor device. The semiconductor device includes a semiconductor substrate, a pedestal dielectric stack, a bipolar junction transistor (BJT), a field effect transistor (FET), and a composite structure. The semiconductor substrate includes a BJT region, a complementary FET (CFET) region, and a transition region between the BJT region and the CFET region. The pedestal dielectric stack is on the semiconductor substrate in the BJT region. The BJT is on the semiconductor substrate in the BJT region. At least a portion of the BJT is in an opening through the pedestal dielectric stack. The opening is defined at least in part by a retrograde sidewall. The FET is on the semiconductor substrate in the CFET region. The composite structure is on the semiconductor substrate in the transition region. The composite structure includes a residual dielectric stack, a dielectric layer, and a first material. The residual dielectric stack is over the semiconductor substrate. The residual dielectric stack has a material that is the same as the pedestal dielectric stack. The dielectric layer is over the residual dielectric stack. The dielectric layer includes a nitride. The first material is the same as a gate electrode of the FET. The first material is over the dielectric layer.

Another example is a method. A pedestal dielectric stack is formed over a semiconductor substrate in a BJT region. The pedestal dielectric stack includes a first dielectric sub-layer and a second dielectric sub-layer over the first dielectric sub-layer. The first dielectric sub-layer has a lateral etch rate to an etchant that is greater than a lateral etch rate to the etchant of the second dielectric sub-layer. A protective dielectric layer is formed over the pedestal dielectric stack. The protective dielectric layer includes a nitride. After forming the protective dielectric layer, a gate oxide layer of a FET is formed on the semiconductor substrate in a CFET region. An opening is formed through the protective dielectric layer and the pedestal dielectric stack. Forming the opening includes using an etch process that includes using the etchant. A BJT is formed on the semiconductor substrate in the BJT region. At least a portion of the BJT is in the opening.

A further example is a method. A pedestal oxide stack is formed over a semiconductor substrate in a BJT region. The pedestal oxide stack includes a first oxide sub-layer and a second oxide sub-layer over the first oxide sub-layer. The first oxide sub-layer has a first density. The second oxide sub-layer has a second density greater than the first density. A protective dielectric layer is formed over the pedestal oxide stack. The protective dielectric layer includes a nitride. A gate oxide layer of a FET is formed on the semiconductor substrate in a CFET region while the protective dielectric layer is over the pedestal oxide stack. Forming the gate oxide layer includes performing an oxidation process. An opening is formed through the protective dielectric layer and the pedestal oxide stack. The opening is defined at least in part by a retrograde sidewall. A BJT is formed on the semiconductor substrate in the BJT region. At least a portion of the BJT is in the opening.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1A and 1B through FIGS. 38A and 38B are respective cross-sectional views of a semiconductor device in intermediate stages of manufacturing according to some examples.

FIGS. 39A and 39B through FIGS. 45A and 45B are respective cross-sectional views of a semiconductor device in intermediate stages of manufacturing according to some examples.

FIGS. 46, 47, and 48 are respective profiles of collector openings in a pedestal dielectric stack according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing including epitaxial growth of a semiconductor material, and more particularly for some examples, to semiconductor processing integration for a bipolar junction transistor (BJT). Some examples include a semiconductor device including a BJT in a BJT region on a semiconductor substrate and a field effect transistor (FET) in a complementary FET (CFET) region on the semiconductor substrate. A pedestal dielectric stack is over the semiconductor substrate in the BJT region. An opening is through the pedestal dielectric stack to the semiconductor substrate and is defined at least in part by a retrograde sidewall. At least a portion of the BJT is on the semiconductor substrate and in the opening through the pedestal dielectric stack, and another portion of the BJT is over the pedestal dielectric stack. A composite structure is on the semiconductor substrate in a region between the BJT region and the CFET region. The composite structure includes a residual dielectric stack (e.g., a residual portion of the pedestal dielectric stack) over the semiconductor substrate, a dielectric layer that includes a nitride over the residual dielectric stack, and a material that is the same as a gate electrode of the FET over the dielectric layer.

More broadly, a pedestal dielectric stack is formed over a semiconductor substrate. The pedestal dielectric stack has a gradient lateral etch rate to an etchant, where a lower portion (e.g., a lower sub-layer) has a greater lateral etch rate to the etchant than a lateral etch rate to the etchant of an upper portion (e.g., an upper sub-layer). For example, multiple dielectric sub-layers may be formed over the semiconductor substrate that have the varying lateral etch rates. An opening is formed through the pedestal dielectric stack to the semiconductor substrate. The opening is formed using the etchant to etch the pedestal dielectric stack. The etchant laterally etches the lower portion faster than the upper portion, which forms a retrograde sidewall that defines at least a part of the opening. A semiconductor material may then be epitaxially grown in the opening and on the semiconductor substrate. The retrograde sidewall of the opening may have a geometric configuration that traps a facet that is formed during epitaxial growth, thereby suppressing further propagation of the facet during epitaxial growth after the trapping. By suppressing or trapping facets, subsequent epitaxially grown semiconductor material may avoid having a facet, which may improve performance of a device (e.g., a BJT) formed with the epitaxially grown material(s). Other benefits and advantages may be achieved.

The pedestal dielectric stack may be formed using any dielectric material, for example, that may achieve the lateral etch rates for forming the retrograde sidewall. Specific examples described below implement oxide sub-layers in the pedestal dielectric stack that is used in forming a BJT. The different oxide sub-layers, as described subsequently, have different lateral etch rates to achieve the retrograde sidewall. Different examples, particularly different examples implemented with different devices, may implement different dielectric material(s).

Examples described herein are implemented in a process flow that integrates formation of a BJT and formation of one or more FETs. Generally, pedestal dielectric sub-layers of a pedestal dielectric stack are deposited such that the pedestal dielectric sub-layers implement the gradient lateral etch rate to an etchant described above. A protective dielectric layer is deposited over the pedestal dielectric stack. The protective dielectric layer may be a nitride as deposited. Thereafter, a gate oxide layer of a FET is formed in the CFET region, such as by one or more oxidation processes. The oxidation process(es) may oxidize a portion of the protective dielectric layer. The protective dielectric layer may prevent or reduce an increase in density to one or more of the pedestal dielectric sub-layers (e.g., an upper sub-layer of the pedestal dielectric stack), which may avoid or reduce a change in a lateral etch rate of the pedestal dielectric sub-layer(s) (e.g., a lower sub-layer of the pedestal dielectric stack). Further, the protective dielectric layer may also prevent or reduce further oxidation of the semiconductor substrate underlying the protective dielectric layer. Thereafter, a gate layer is formed over the gate oxide layer and the pedestal dielectric stack. The gate layer is patterned and removed from the BJT region, and a collector opening is formed through the pedestal dielectric stack. The collector opening is formed using an etch process that uses the etchant (to which the pedestal dielectric sub-layers have different lateral etch rates). The BJT is formed, such as including epitaxially growing a collector layer in the collector opening. The gate layer is further patterned into a gate electrode of the FET. Additional processing may be performed, such as to further form the FET.

Various examples are described subsequently. Although the specific examples may illustrate various aspects of the above generally described features, examples may incorporate any combination of the above generally described features (which are described in more detail in examples below).

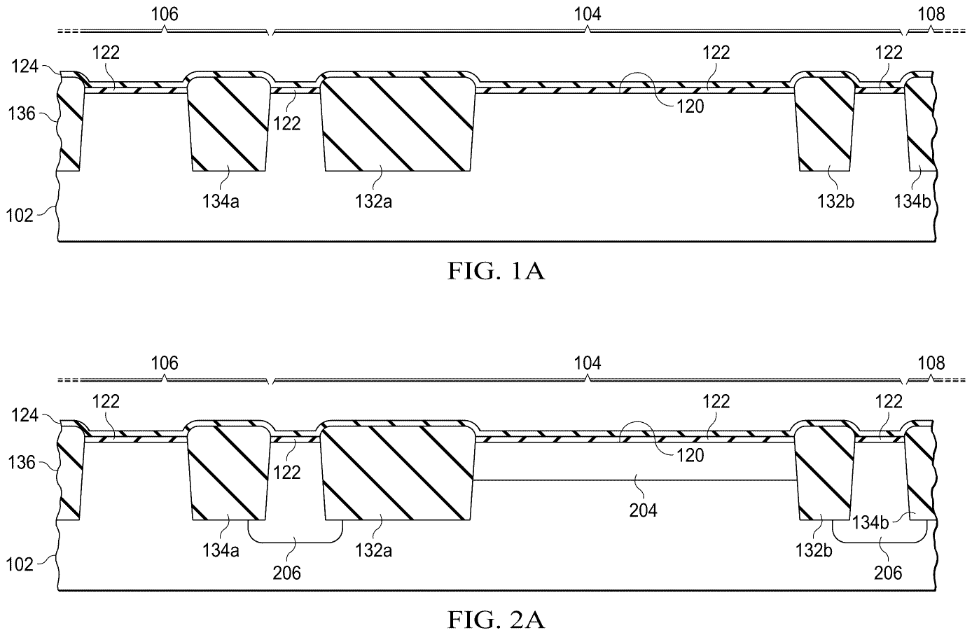

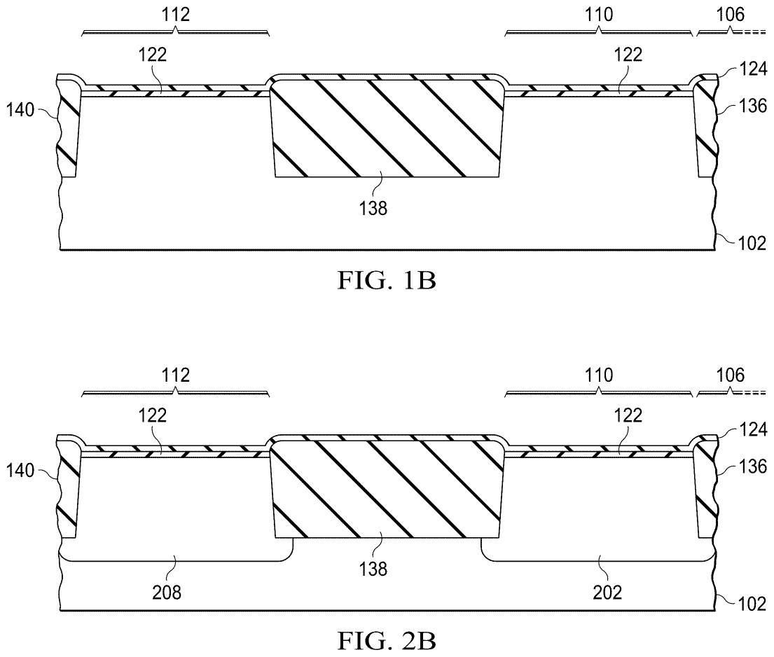

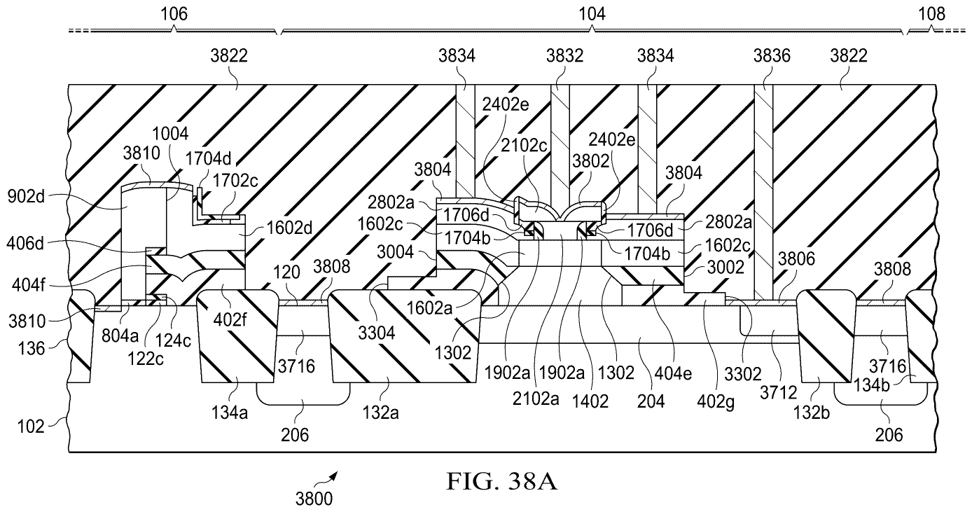

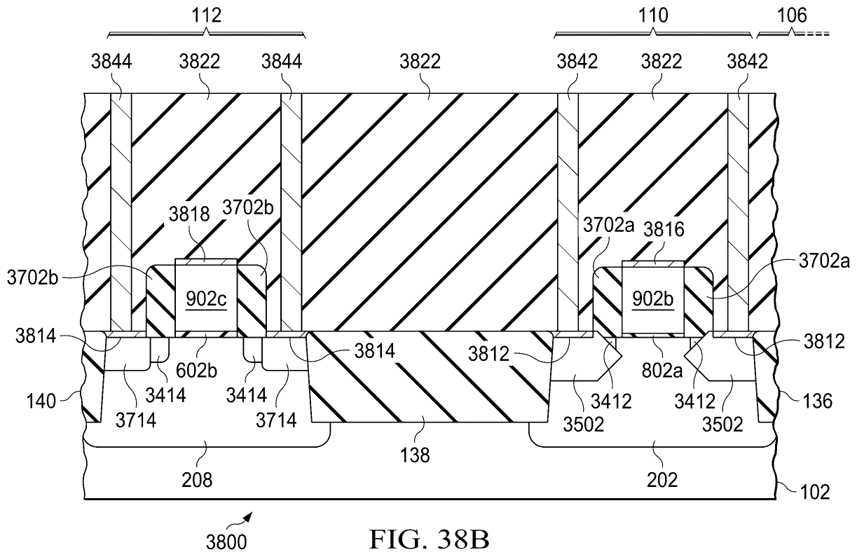

FIGS. 1A and 1B through FIGS. 38A and 38B are respective cross-sectional views of a semiconductor device in intermediate stages of manufacturing according to some examples. The method illustrated in these figures forms the semiconductor device 3800 of FIGS. 38A and 38B. As an example, a lower operating voltage rated pFET (e.g., having a lower magnitude threshold voltage) is formed in the pFET region (e.g., as illustrated by a thinner gate oxide layer subsequently), and a higher operating voltage rated nFET (e.g., having a higher magnitude threshold voltage) is formed in the nFET region (e.g., as illustrated by a thicker gate oxide layer subsequently). In other examples, a higher operating voltage rated pFET may alternatively or additionally be formed in the pFET region. In other examples, a lower operating voltage rated nFET may alternatively or additionally be formed in the nFET region.

Referring to FIGS. 1A and 1B, a semiconductor substrate 102 is provided. The semiconductor substrate 102 includes a BJT region 104, a first transition region 106, a second transition region 108, a p-type FET (pFET) region 110, and an n-type FET (nFET) region 112. Together, the pFET region 110 and the nFET region 112 are included in a CFET region. In the following description and in the figures, some structures are formed in the first transition region 106. Although not illustrated and/or not described, such structures may also be formed in the second transition region 108, such as in a mirrored configuration relative to those formed in the first transition region 106. Further explicit description of such structures in the second transition region 108 is omitted for brevity.

The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes a semiconductor material in and/or on which devices, such as the BJT, the pFET, and the nFET (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 102 has an upper surface 120 in and/or on which devices (e.g., the BJT, pFET, and nFET) are formed. In the illustrated example, the semiconductor material of the semiconductor substrate 102 is p-type doped with a p-type dopant. In some examples, the semiconductor substrate 102 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

A first oxide layer 122 is over (e.g., on) the upper surface 120 of the semiconductor substrate 102. Isolation structures 132 (including a first portion 132a and a second portion 132b), 134 (including a first portion 134a and a second portion 134b), 136, 138, 140 are formed through the first oxide layer 122 and in the semiconductor substrate 102. In the illustrated example, the isolation structures 132-140 are shallow trench isolation structures (STIs) extending from the upper surface 120 of the semiconductor substrate 102 into the semiconductor substrate 102. As illustrated, the isolation structures 132-140 are also raised above the upper surface 120 of the semiconductor substrate 102, and in other examples, the isolation structures 132-140 may have respective upper surfaces co-planar with and/or below the upper surface 120 of the semiconductor substrate 102. The isolation structures 132-140 may include, for example, a liner layer, such as including silicon oxide or silicon nitride, conformally along surfaces of a respective trench in the semiconductor substrate 102 and a fill isolation material, such as silicon oxide, over and on the liner layer. A second oxide layer 124 is conformally over (e.g., on) the first oxide layer 122 and the isolation structures 132-140.

The isolation structures 132-140 may be formed as described herein. The first oxide layer 122 is formed on the upper surface of the semiconductor substrate 102. The first oxide layer 122 is or includes an oxide, such as silicon oxide, formed using appropriate formation or deposition processes. In some examples, the first oxide layer 122 is or includes silicon oxide formed using in situ steam generation (ISSG) oxidation, thermal oxidation, another oxidation process, or the like. A hardmask layer may then be deposited over the first oxide layer 122. The hardmask layer may be any appropriate material, such as silicon nitride, silicon oxynitride, or the like, and may be deposited using any appropriate deposition process, such as chemical vapor deposition (CVD).

The hardmask layer is patterned, such as by using photolithography and an etching process (e.g., reactive ion etch (RIE)). Recesses or trenches are etched, such as by RIE, through the first oxide layer 122 and into the semiconductor substrate 102 using the patterned hardmask layer as a mask. The liner layer may then be conformally deposited in the recesses or trenches and over the patterned hardmask layer, such as by plasma enhanced CVD (PECVD) or formed on exposed surfaces of the recesses or trenches (e.g., by an oxidation process), and the fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by an etch selective to the hardmask layer, which may be a wet etch process. In other examples, the isolation structures 132-140 may be field oxide structures, such as local oxidation of silicon (LOCOS) structures, at the upper surface 120 of the semiconductor substrate 102, which may be formed using a LOCOS process. The isolation structures 132-140 may be further developed (e.g., by etching, oxidation, deposition, etc.) by further processing although not specifically described or illustrated.

The second oxide layer 124 is formed on the first oxide layer 122 and the isolation structures 132-140. The second oxide layer 124 is or includes an oxide, such as silicon oxide, formed using appropriate formation or deposition processes. In some examples, the second oxide layer 124 is or includes silicon oxide formed by a high temperature oxide (HTO) low pressure chemical vapor deposition (LPCVD) or the like.

The isolation structure 132 laterally defines an active area of the upper surface 120 of the semiconductor substrate 102 on which the BJT is to be formed. The isolation structure 132 laterally encircles or encompasses the active area of the upper surface 120 of the semiconductor substrate 102 on which the BJT is to be formed. As indicated subsequently, an active portion (e.g., a base layer) of the BJT extends laterally beyond the active area of the upper surface 120 of the semiconductor substrate 102 on which the BJT is formed and over the first portion 132a of the isolation structure 132. Further, the isolation structure 134 defines lateral boundaries of the BJT region 104. The isolation structure 134 laterally encircles or encompasses the isolation structure 132 with a doped isolation or guardring well therebetween, as described subsequently.

The isolation structures 136, 138 laterally define, at least in part, an active area of the upper surface 120 of the semiconductor substrate 102 on which the pFET is to be formed. The active area of the upper surface 120 of the semiconductor substrate 102 on which the pFET is formed defines the lateral boundary of the pFET region 110. Similarly, the isolation structures 138, 140 laterally define, at least in part, an active area of the upper surface 120 of the semiconductor substrate 102 on which the nFET is to be formed. The active area of the upper surface 120 of the semiconductor substrate 102 on which the nFET is formed defines the lateral boundary of the nFET region 112. The CFET region includes the pFET region 110 and the nFET region 112. The laterally exterior boundaries of the pFET region 110 and/or nFET region 112 (or other pFET and/or nFET regions) define the lateral boundary of the CFET region.

The first transition region 106 is defined from a lateral boundary of the BJT region 104 to a nearest lateral boundary of the CFET region (which in the illustrated example is a boundary of the pFET region 110). The first transition region 106 includes the isolation structure 136 and the first portion 134a of the isolation structure 134. As illustrated, a portion of the upper surface 120 of the semiconductor substrate 102 is between the first portion 134a of the isolation structure 134 and the isolation structure 136 in the first transition region 106. In other examples, the first transition region 106 may have an isolation structure laterally throughout the first transition region 106. The second transition region 108 is defined from a lateral boundary of the BJT region 104 to a nearest lateral boundary of another region (not illustrated). The second transition region 108 includes the second portion 134b of the isolation structure 134. The second transition region 108 may be formed and/or structured like the first transition region 106.

Referring to FIGS. 2A and 2B, an n-type doped well 202 is formed in the semiconductor substrate 102 in the pFET region 110. The n-type doped well 202 may be formed by masking (e.g., by a photoresist using photolithography) areas of the semiconductor substrate 102 where an n-type doped well is not to be formed and implanting n-type dopants into the semiconductor substrate 102. The n-type doped well 202 extends from the upper surface 120 of the semiconductor substrate 102 into a depth in the semiconductor substrate 102 and is in the pFET region 110 laterally between the isolation structures 136, 138. A concentration of the n-type dopant of the n-type doped well 202 is greater than a concentration of the p-type dopant of the p-type doped semiconductor substrate 102. In some examples, the n-type doped well 202 is doped with an n-type dopant (e.g., phosphorus (P) or arsenic (As)) with a concentration in a range from 1×10¹⁵ cm⁻³ to 1×10¹⁷ cm⁻³. Another dopant and/or other doping concentrations may be implemented.

An n-type doped sub-collector diffusion region 204 is formed in the semiconductor substrate 102 in the BJT region 104 and laterally between the portions 132a, 132b of the isolation structure 132. The n-type doped sub-collector diffusion region 204 may be formed by masking (e.g., by a photoresist using photolithography) areas of the semiconductor substrate 102 where an n-type doped sub-collector diffusion region is not to be formed and implanting n-type dopants into the semiconductor substrate 102. The n-type doped sub-collector diffusion region 204 extends from the upper surface 120 of the semiconductor substrate 102 into a depth in the semiconductor substrate 102 and is in the BJT region 104 laterally between the portions 132a, 132b of the isolation structure 132. A concentration of the n-type doped sub-collector diffusion region 204 is greater than a concentration of the p-type dopant of the semiconductor substrate 102. In some examples, the n-type doped sub-collector diffusion region 204 is doped with an n-type dopant with a concentration in a range from 1×10¹⁸ cm⁻³ to 1×10²⁰ cm⁻³. Another dopant and/or other doping concentrations may be implemented.

P-type doped wells 206, 208 are formed in the semiconductor substrate 102. The p-type doped wells 206, 208 may be formed by masking (e.g., by a photoresist using photolithography) areas of the semiconductor substrate 102 where a p-type doped well is not to be formed and implanting p-type dopants into the semiconductor substrate 102. The p-type doped well 206 extends from the upper surface 120 of the semiconductor substrate 102 into a depth in the semiconductor substrate 102 and is in the BJT region 104 laterally between the isolation structures 132, 134. The p-type doped well 206 is an isolation ring or guardring laterally encircling or encompassing the active area in which the BJT is to be formed. The p-type doped well 208 extends from the upper surface 120 of the semiconductor substrate 102 into a depth in the semiconductor substrate 102 and is in the nFET region 112 laterally between the isolation structures 138, 140. A concentration of the p-type dopant of the p-type doped wells 206, 208 is greater than a concentration of the p-type dopant of the p-type doped semiconductor substrate 102. In some examples, the p-type doped wells 206, 208 are doped with a p-type dopant with a concentration in a range from 1×10¹⁵ cm⁻³ to 1×10¹⁷ cm⁻³. Another dopant and/or other doping concentrations may be implemented.

Although the semiconductor substrate 102, n-type doped well 202, n-type doped sub-collector diffusion region 204, and p-type doped wells 206, 208 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

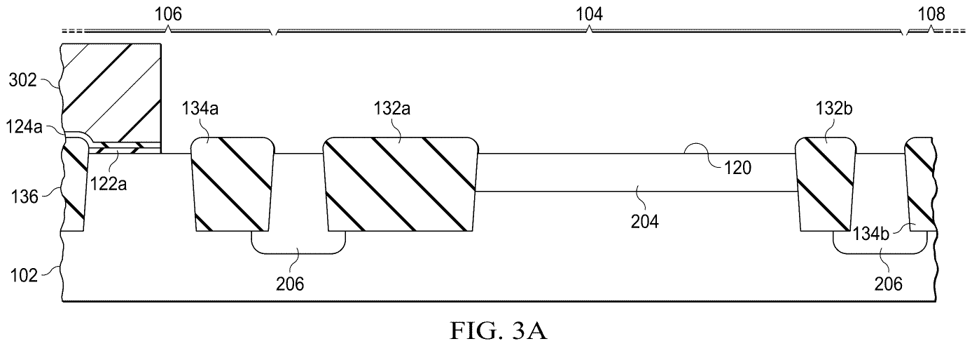

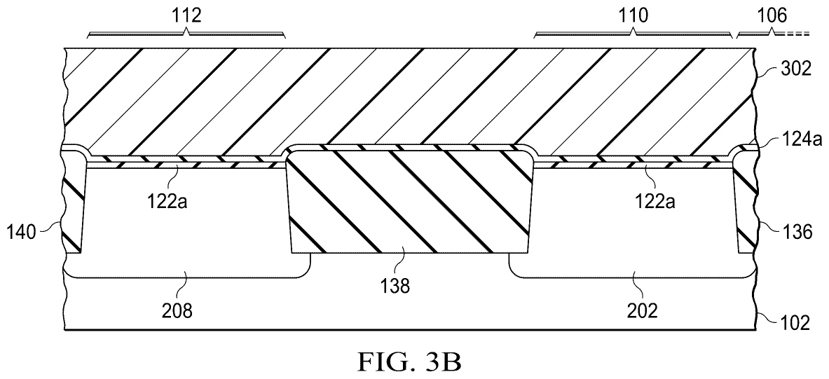

Referring to FIGS. 3A and 3B, the first and second oxide layers 122, 124 are removed from the semiconductor substrate 102 in the BJT region 104 such that the first oxide layer 122a and second oxide layer 124a remain in the pFET region 110 and nFET region 112 and extending into the first transition region 106. In the illustrated example, the portions of the first and second oxide layers 122, 124 are removed using appropriate photolithography and etch processes. A photoresist 302 is deposited (e.g., by spin-on) over the second oxide layer 124 and patterned using photolithography. The photoresist 302 is patterned to remain in pFET region 110 and nFET region 112 and extending into the first transition region 106 and to have an opening exposing portions of layers in the BJT region 104 that are to be removed. Using the patterned photoresist 302 as a mask, an etch process, such as an anisotropic etch like an RIE or the like, is performed to remove the exposed portions of the first and second oxide layers 122, 124 and to pattern the first and second oxide layers 122a, 124a. After the etch process, the photoresist 502 is removed, such as by ashing.

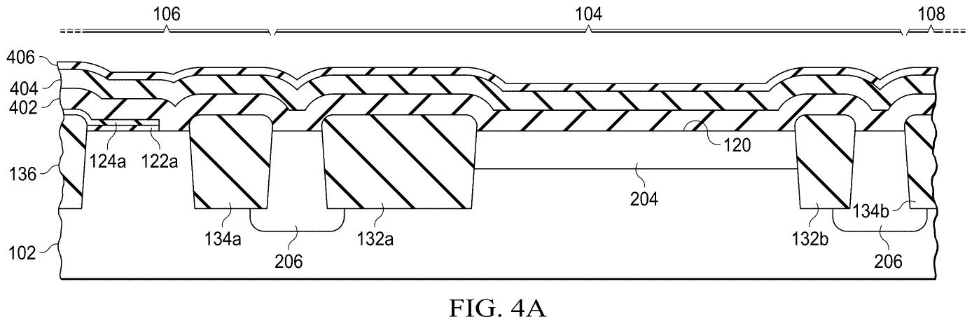

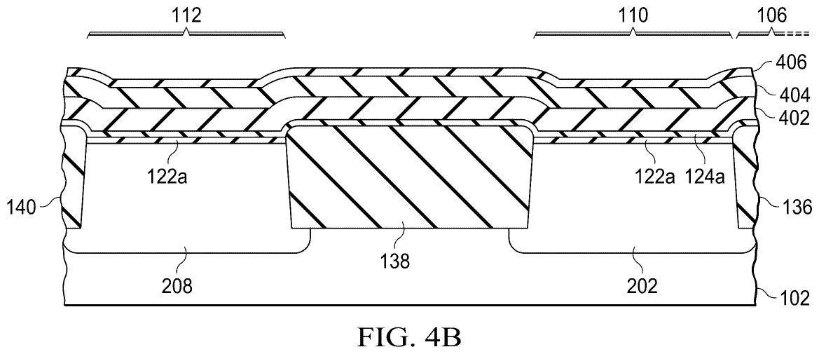

Referring to FIGS. 4A and 4B, a first pedestal dielectric sub-layer 402 is formed over (e.g., on) the upper surface 120 of the semiconductor substrate 102 in the BJT region 104, the second oxide layer 124a, and the isolation structures 132, 134, and a second pedestal dielectric sub-layer 404 is formed over (e.g., on) the first pedestal dielectric sub-layer 402. The first pedestal dielectric sub-layer 402 has a lateral etch rate to an etchant that is greater than a lateral etch rate to the etchant of the second pedestal dielectric sub-layer 404. The first and second pedestal dielectric sub-layers 402, 404 may be any appropriate dielectric material deposited or formed by any appropriate technique. In some examples, the first pedestal dielectric sub-layer 402 is or includes an oxide, such as silicon oxide, deposited by atomic layer deposition (ALD) (e.g., plasma enhanced ALD (PEALD)), low pressure CVD (LPCVD), or the like, and the second pedestal dielectric sub-layer 404 is or includes an oxide, such as silicon oxide, deposited by PECVD or the like. In such examples, the deposition process of the first pedestal dielectric sub-layer 402 may result in the first pedestal dielectric sub-layer 402 having a relatively low density and higher lateral etch rate, and the deposition process of the second pedestal dielectric sub-layer 404 may result in the second pedestal dielectric sub-layer 404 having a higher density and lower lateral etch rate relative to the first pedestal dielectric sub-layer 402. In some examples, respective thicknesses of the first and second pedestal dielectric sub-layers 402, 404 as deposited are sufficient to achieve target thicknesses of the respective sub-layers in the semiconductor device 3800, 4500, as described subsequently. In some instances, a thickness of the second pedestal dielectric sub-layer 404 as deposited is greater than the thickness of the second pedestal dielectric sub-layer 404 in the semiconductor device 3800, 4500 to accommodate subsequent processing, such as various etches and/or cleans, that may reduce the thickness of the second pedestal dielectric sub-layer 404.

A protective dielectric layer 406 is formed over (e.g., on) the second pedestal dielectric sub-layer 404. Generally, the protective dielectric layer 406 may be or include any dielectric material that may be selectively removed (e.g., have etch selectivity) from the second pedestal dielectric sub-layer 404. In some examples, the protective dielectric layer 406 is or includes a nitride, such as silicon nitride, deposited by CVD, although other protective (e.g., dielectric) materials and/or other deposition processes may be used in other examples.

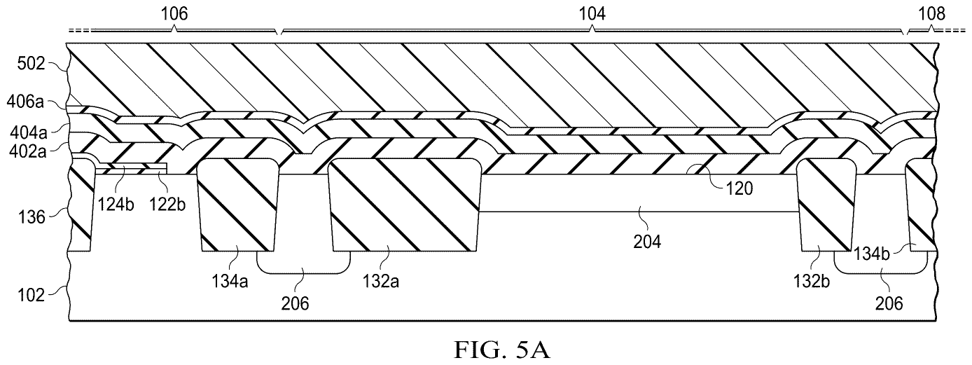

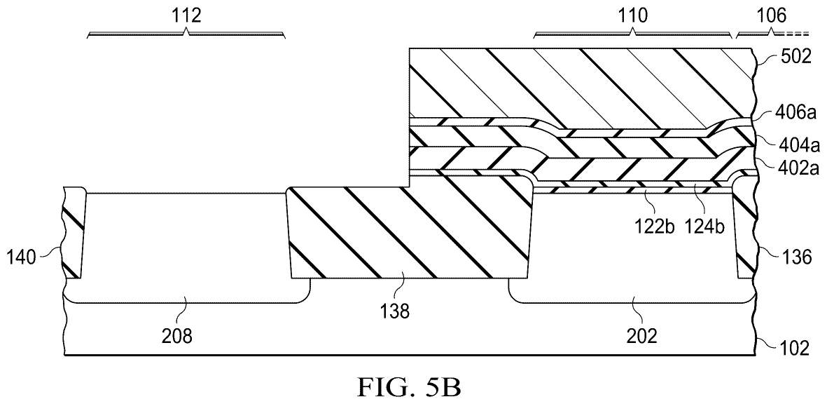

Referring to FIGS. 5A and 5B, the first and second oxide layers 122a, 124a, the first and second pedestal dielectric sub-layers 402, 404, and the protective dielectric layer 406 are removed from the semiconductor substrate 102 in the nFET region 112. The first oxide layer 122b and second oxide layer 124b remain in the pFET region 110 and extending into the first transition region 106, and the first pedestal dielectric sub-layer 402a, second pedestal dielectric sub-layer 404a, and protective dielectric layer 406a remain in the BJT region 104, transition regions 106, 108, and pFET region 110. In the illustrated example, the portions of the first and second oxide layers 122a, 124a, the first and second pedestal dielectric sub-layers 402, 404, and the protective dielectric layer 406 are removed using appropriate photolithography and etch processes. A photoresist 502 is deposited (e.g., by spin-on) over the protective dielectric layer 406 and patterned using photolithography. The photoresist 502 is patterned to remain in regions 104-110 in which the layers 122a, 124a, 402, 404, 406 are to remain and to have an opening exposing portions of layers in the nFET region 112 that are to be removed. Using the patterned photoresist 502 as a mask, an etch process, such as an anisotropic etch like an RIE or the like, is performed to remove the exposed portions of the layers 122a, 124a, 402, 404, 406 and to pattern the layers 122b, 124b, 402a, 404a, 406a. After the etch process, the photoresist 502 is removed, such as by ashing.

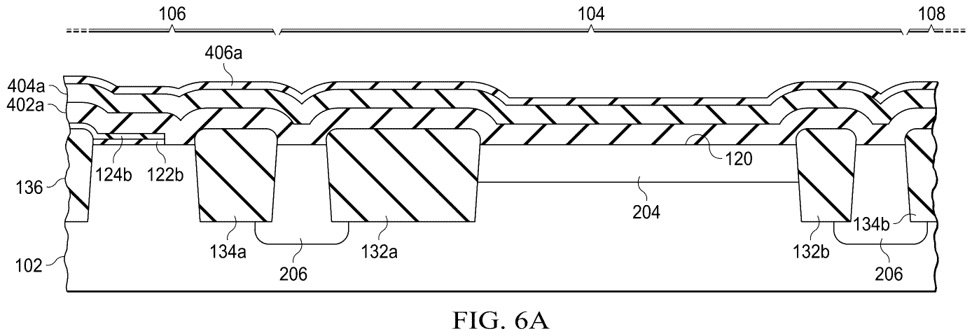

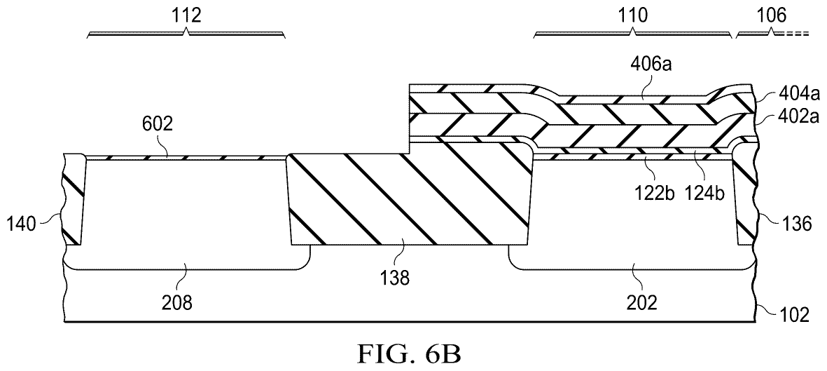

Referring to FIGS. 6A and 6B, a gate oxide layer 602 is formed over (e.g., on) the upper surface 120 of the semiconductor substrate 102 in the nFET region 112. The gate oxide layer 602 is formed using an oxidation process. Accordingly, in some examples, the gate oxide layer 602 may be an oxide, such as silicon oxide, and may be formed using ISSG oxidation or another oxidation process. Although not illustrated, the oxidation process that forms the gate oxide layer 602 may oxidize an upper portion of the protective dielectric layer 406a. The oxidation process may cause oxygen radicals to react with the protective dielectric layer 406a which may cause nitrogen to outgas from the protective dielectric layer 406a.

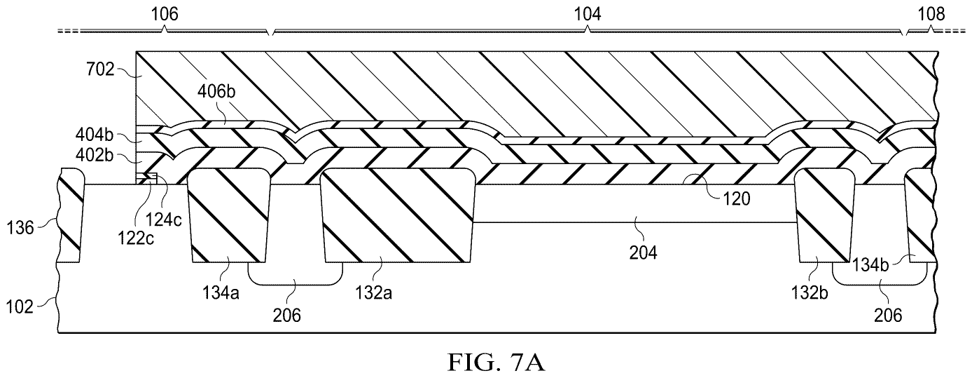

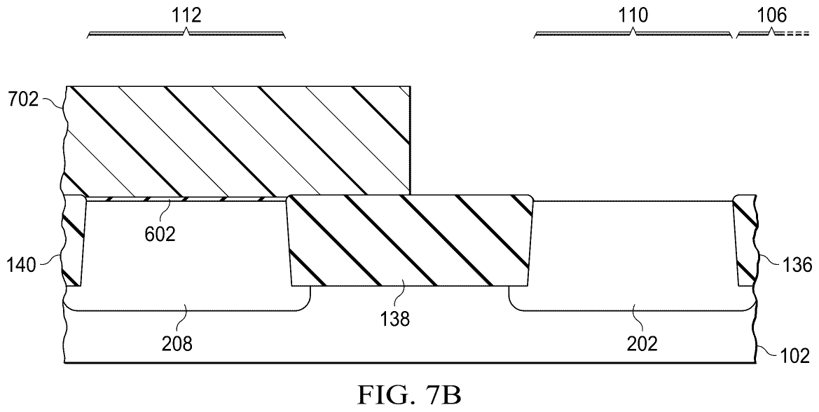

Referring to FIGS. 7A and 7B, the first and second oxide layers 122b, 124b, the first and second pedestal dielectric sub-layers 402a, 404a, and the protective dielectric layer 406a are removed from the semiconductor substrate 102 in the pFET region 110 and a portion of the first transition region 106. Residual first oxide layer 122c and residual second oxide layer 124c remain in the first transition region 106, and the first pedestal dielectric sub-layer 402b, second pedestal dielectric sub-layer 404b, and protective dielectric layer 406b remain in the BJT region 104 and over the residual first and second oxide layers 122c, 124c in the first transition region 106. In the illustrated example, the portions of the layers 122b, 124b, 402a, 404a, 406a are removed using appropriate photolithography and etch processes. A photoresist 702 is deposited (e.g., by spin-on) over the protective dielectric layer 406a and patterned using photolithography. The photoresist 702 is patterned to remain in the regions 104-108 in which the layers 122b, 124b, 402a, 404a, 406a are to remain and in the nFET region 112 where the gate oxide layer 602 is to remain, and to have an opening exposing portions of layers in the pFET region 110 and first transition region 106 that are to be removed. Using the patterned photoresist 702 as a mask, an etch process, such as an anisotropic etch like an RIE or the like, is performed to remove the exposed portions of the layers 122b, 124b, 402a, 404a, 406a and to pattern the layers 122c, 124c, 402b, 404b, 406b. After the etch process, the photoresist 702 is removed, such as by ashing.

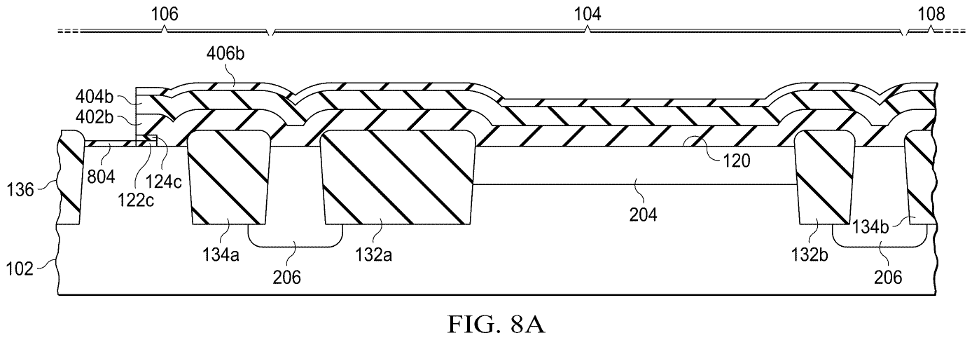

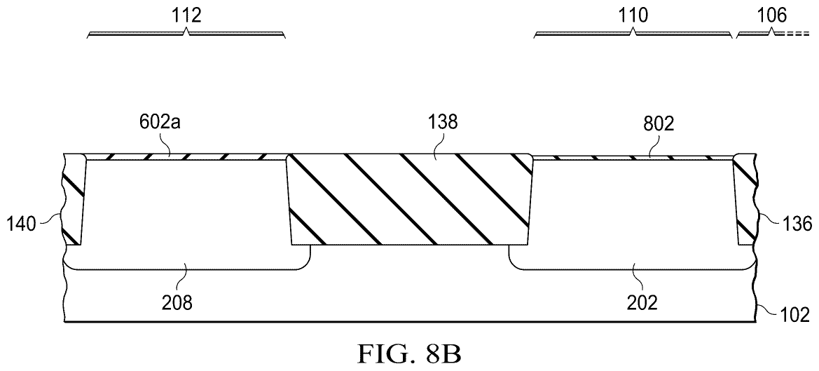

Referring to FIGS. 8A and 8B, a gate oxide layer 802 is formed over (e.g., on) the upper surface 120 of the semiconductor substrate 102 in the pFET region 110. The gate oxide layer 802 is formed using an oxidation process. Accordingly, in some examples, the gate oxide layer 802 may be an oxide, such as silicon oxide, and may be formed using ISSG oxidation or another oxidation process. Further, the oxidation process further oxidizes the gate oxide layer 602 to form a gate oxide layer 602a. The gate oxide layer 602a may therefore have a thickness that is greater than a thickness of the gate oxide layer 802. Also, the oxidation process may form an oxide layer 804 on the upper surface 120 of the semiconductor substrate 102 that is exposed in the first transition region 106. Although not illustrated, the oxidation process that forms the gate oxide layer 802 may further oxidize the protective dielectric layer 406b. The oxidation process may cause oxygen radicals to react with the protective dielectric layer 406b which may cause nitrogen to outgas from the protective dielectric layer 406b.

In some examples, additional different gate oxide layers with different thicknesses may be formed in different regions, such as to form pFETs and/or nFETs rated for different operating voltages (e.g., in high voltage applications, medium voltage applications, or low voltage applications). In such examples, iterative processes for oxidizing the upper surface 120 of the semiconductor substrate 102 may be performed by extending the processing described with respect to FIGS. 5A and 5B through FIGS. 8A and 8B.

The protective dielectric layer 406 generally protects the second pedestal dielectric sub-layer 404 from being densified (e.g., having a density increase) by the oxidation process(es) that form the gate oxide layer(s). The protective dielectric layer 406 may have a sufficient thickness that prevents oxygen radicals from penetrating the protective dielectric layer 406 and reaching the second pedestal dielectric sub-layer 404. In some examples, a thickness of the protective dielectric layer 406 is in a range from 50 Å to 100 Å. If the oxidation process(es) increase the density of the second pedestal dielectric sub-layer 404, the lateral etch rate to the etchant of the second pedestal dielectric sub-layer 404 may be changed (e.g., increased).

Accordingly, the protective dielectric layer 406, in some examples, prevents the oxidation process(es) that form the gate oxide layer(s) from reaching and densifying the second pedestal dielectric sub-layer 404. Also, the protective dielectric layer 406 may further protect the semiconductor substrate 102 underlying the protective dielectric layer 406 from further being oxidized. Further, an upper portion of the protective dielectric layer 406 may be oxidized by the oxidation process(es), and a lower portion of the protective dielectric layer 406 is or includes a nitride, such as silicon nitride (e.g., when the protective dielectric layer 406 is deposited as silicon nitride).

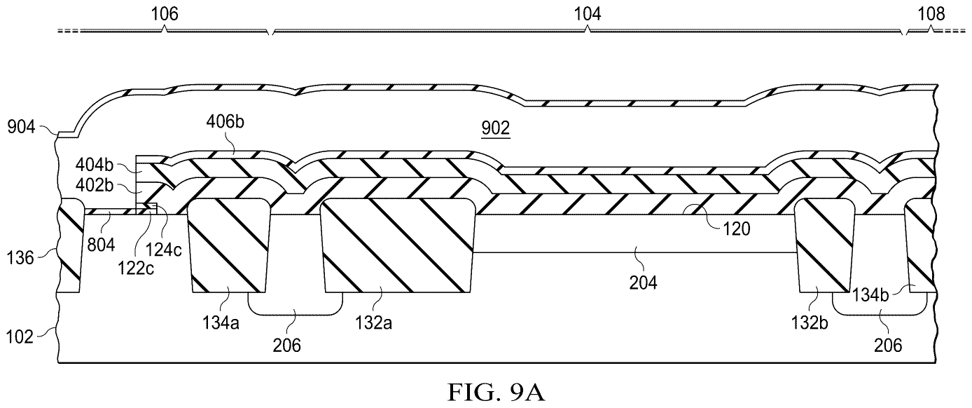

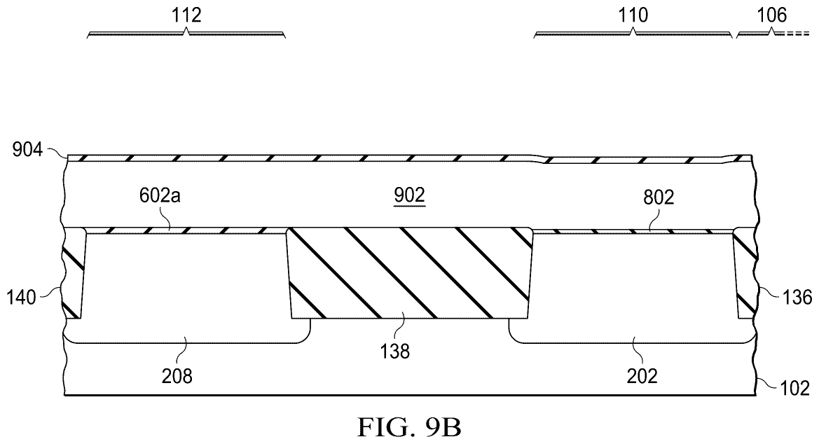

Referring to FIGS. 9A and 9B, a gate layer 902 is formed over the semiconductor substrate 102, and a protective dielectric layer 904 is formed over the gate layer 902. The gate layer 902 is formed over (e.g., on) the gate oxide layers 602a, 802, the oxide layer 804, the isolation structures 136-140, and the protective dielectric layer 406b, and along aligned respective sidewalls (e.g., in the first transition region 106) of the first and second pedestal dielectric sub-layers 402b, 404b and the protective dielectric layer 406b. In some examples, the gate layer 902 is or includes a semiconductor material, such as polycrystalline silicon (polysilicon), and may be formed by any deposition process, such as CVD. In some examples, the semiconductor material may be doped in situ during deposition and/or may be implanted by a dopant after deposition. For example, the gate layer 902 may be in situ doped during deposition with a p-type dopant, and after deposition, a portion of the gate layer 902 may be implanted with an n-type dopant to a greater concentration than the p-type dopant while another portion of the gate layer 902 is masked (e.g., by a photoresist formed by photolithography). In some examples, the gate layer 902 in the BJT region 104, transition regions 106, 108, and pFET region 110 is polysilicon doped with a p-type dopant with a concentration in a range from 1×10¹⁹ cm⁻³ to 1×10²¹ cm⁻³ after deposition and/or implantation, and the gate layer 902 in the nFET region 112 is polysilicon doped with an n-type dopant with a concentration in a range from 5×10¹⁹ cm⁻³ to 5×10²¹ cm⁻³ after implantation. Other materials (e.g., conductive material) may be implemented as the gate layer 902, which may be formed by any deposition process. In some examples, the protective dielectric layer 904 is silicon oxide (e.g., a tetraethyl orthosilicate (TEOS) oxide) deposited by CVD, although other dielectric materials and/or other deposition processes may be used in other examples.

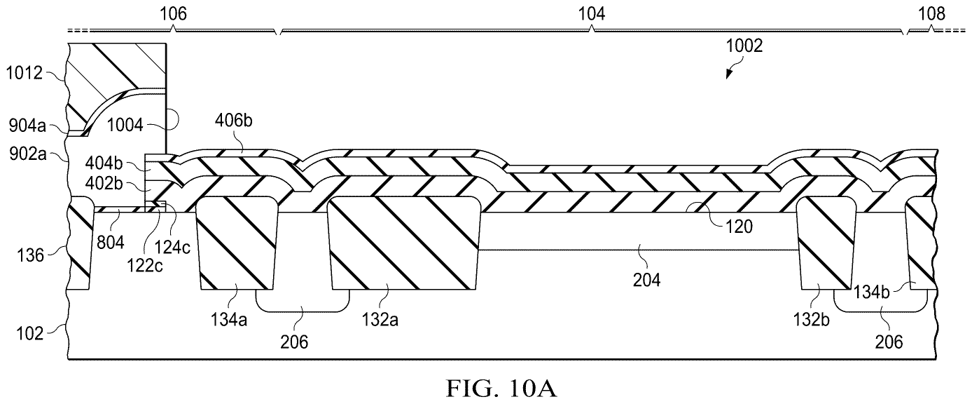

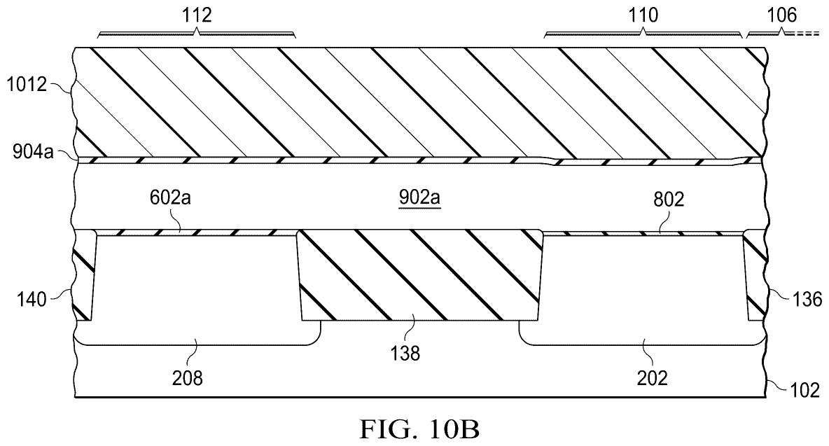

Referring to FIGS. 10A and 10B, the protective dielectric layer 904 and gate layer 902 are etched to form an opening 1002 through the protective dielectric layer 904a and gate layer 902a to the protective dielectric layer 406b. The opening 1002 is in the BJT region 104 and the transition regions 106, 108. The formation of the opening 1002 results in the protective dielectric layer 904 and the gate layer 902 being removed from the BJT region 104. The opening 1002 is defined, at least in part, by a sidewall 1004, of the gate layer 902a (and further by a corresponding sidewall of the protective dielectric layer 904a, which is not indicated by a reference numeral). The sidewall 1004 of the gate layer 902a is over the protective dielectric layer 406b and the second pedestal dielectric sub-layer 404b in the first transition region 106.

Although not illustrated, another sidewall of the gate layer 902a may be over the protective dielectric layer 406b and the second pedestal dielectric sub-layer 404b in the second transition region 108. As will be shown subsequently, the BJT is formed through the opening 1002 through the gate layer 902a.

In the illustrated example, the protective dielectric layer 904 and gate layer 902 are patterned using appropriate photolithography and etch processes. A photoresist 1012 is deposited (e.g., by spin-on) over the protective dielectric layer 904 and patterned using photolithography. The photoresist 1012 is patterned to remain in regions in which the protective dielectric layer 904 and gate layer 902 are to remain and to have an opening corresponding to the opening 1002. A lithography mask used to pattern the photoresist 1012 may be a same lithography mask used to pattern the photoresist 302 in FIGS. 3A and 3B. Using the patterned photoresist 1012 as a mask, an etch process, such as an anisotropic etch like an RIE or the like, is performed to remove portions of the protective dielectric layer 904 and gate layer 902 and to pattern the protective dielectric layer 904a and gate layer 902a. As indicated by FIGS. 10A and 10B, resulting sidewalls (including the sidewall 1004) of the gate layer 902a are disposed in the transition regions 106, 108 encompassing the BJT region 104. After the etch process, the photoresist 1012 is removed, such as by ashing.

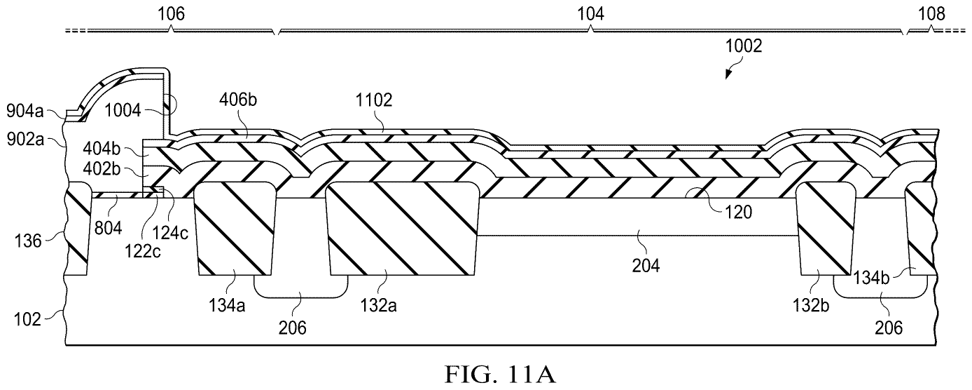

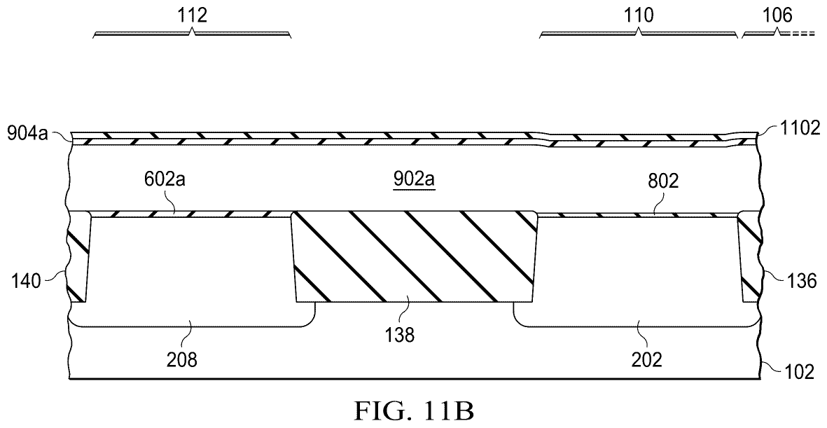

Referring to FIGS. 11A and 11B, a hardmask layer 1102 is formed conformally over the protective dielectric layer 406b and the protective dielectric layer 904a. The hardmask layer 1102 is formed on the sidewall 1004 of the gate layer 902a in the first transition region 106. In some examples, the hardmask layer 1102 is or includes silicon nitride deposited by CVD, although other hardmask (e.g., dielectric) materials and/or other deposition processes may be used in other examples.

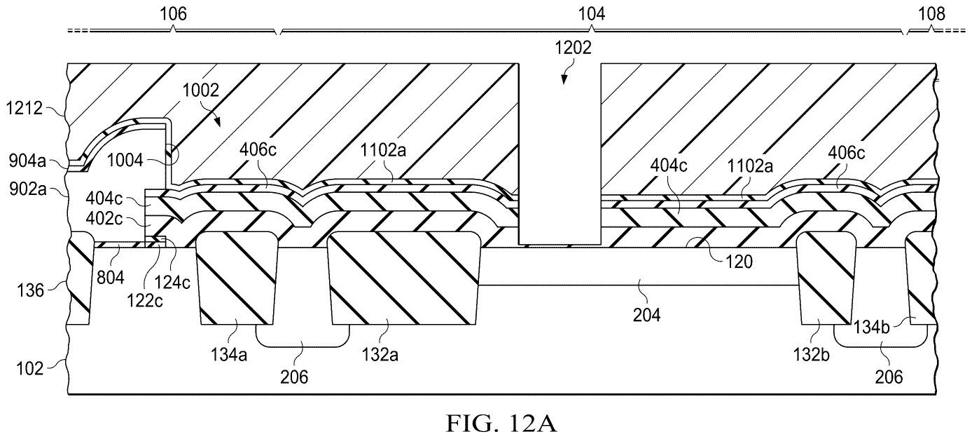

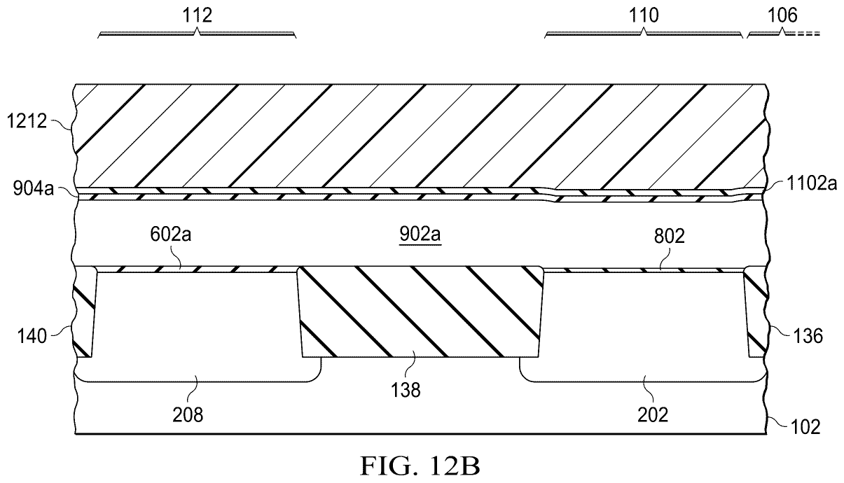

Referring to FIGS. 12A and 12B, the hardmask layer 1102, the protective dielectric layer 406b, and the second and first pedestal dielectric sub-layers 404b, 402b are etched to form a collector recess 1202 through the hardmask layer 1102a, the protective dielectric layer 406c, and the second pedestal dielectric sub-layer 404c, and to and/or into the first pedestal dielectric sub-layer 402c. The collector recess 1202 is formed in the BJT region 104 laterally over the n-type doped sub-collector diffusion region 204 between the first portion 132a and the second portion 132b of the isolation structure 132. In the illustrated example, the collector recess 1202 is formed using appropriate photolithography and etch processes. A photoresist 1012 (e.g., a tri-layer photoresist structure) is deposited (e.g., by spin-on) on or over the hardmask layer 1102 and patterned using photolithography. The photoresist 1012 is patterned to have an opening corresponding to the collector recess 1202. Using the patterned photoresist 1012 as a mask, an etch process, such as an anisotropic etch like an RIE or the like, is performed to etch the hardmask layer 1102, the protective dielectric layer 406b, and the second and first pedestal dielectric sub-layers 404b, 402b. After the etch process, the photoresist 1012 is removed, such as by ashing. A portion of the first pedestal dielectric sub-layer 402c may remain over the upper surface 120 of the semiconductor substrate 102 under the collector recess 1202. In some examples, the collector recess 1202 may be an opening that exposes the upper surface 120 of the semiconductor substrate 102.

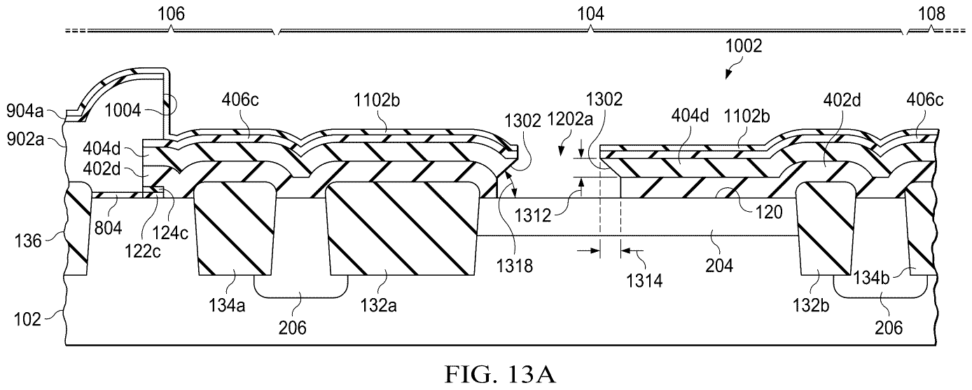

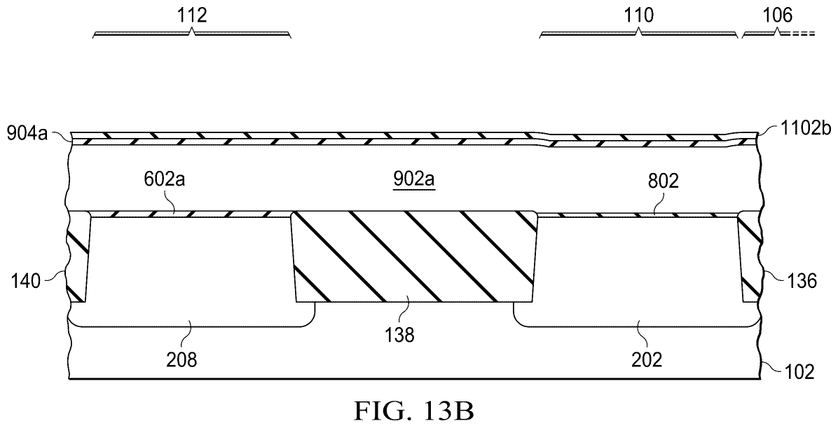

Referring to FIGS. 13A and 13B, an etch process that includes an etchant is performed that laterally etches the second and first pedestal dielectric sub-layers 404c, 402c at the collector recess 1202 and forms a collector opening 1202a through the second pedestal dielectric sub-layer 404d and the first pedestal dielectric sub-layer 402d. The etch process may be an isotropic etch process, such as a wet etch process. In examples in which the second and first pedestal dielectric sub-layers 404c, 402c are silicon oxide, the etch process includes using an etchant including hydrofluoric (HF) acid. For example, the etch process may use or be diluted hydrofluoric (dHF) acid, a buffered oxide etch (BOE), or the like. The etch process etches through the first pedestal dielectric sub-layer 402c to expose the upper surface 120 of the semiconductor substrate 102 through the collector opening 1202a and laterally etches the second and first pedestal dielectric sub-layers 404c, 402c to form retrograde sidewalls 1302 in the second and first pedestal dielectric sub-layers 404d, 402d that define, at least in part, the collector opening 1202a. Each retrograde sidewall 1302 is retrograde, at least partially, into the second and first pedestal dielectric sub-layers 404d, 402d from a distance distal from the upper surface 120 of the semiconductor substrate 102 towards the upper surface 120. The collector opening 1202a is generally proximate to (or some lateral distance from) the first portion 132a of the isolation structure 132 and over the n-type doped sub-collector diffusion region 204 in the BJT region 104.

The retrograde sidewalls 1302 may be formed as a result of different lateral etch rates of the second and first pedestal dielectric sub-layers 404c, 402c to the etchant of the etch process. In some examples, a lateral etch rate to the etchant of the second pedestal dielectric sub-layer 404c is less than the lateral etch rate to the etchant of the first pedestal dielectric sub-layer 402c. Hence, during the etch process, more of the first pedestal dielectric sub-layer 402c may be laterally etched from sidewalls of the collector recess 1202 than the second pedestal dielectric sub-layer 404c.

In some examples, the retrograde sidewalls 1302 may trap a facet that is formed during subsequent epitaxial growth in the collector opening 1202a. Any portion of the retrograde sidewall 1302 may have a geometric configuration that may trap a facet. For such a portion, a ratio of a vertical dimension from a lower retrograde portion to an upper overhang portion to a lateral dimension from the lower retrograde portion to the upper retrograde portion is such that a facet may be trapped. For example, as illustrated, the retrograde sidewall 1302 has a vertical dimension 1312 from a lower retrograde portion (e.g., a lower point in the retrograde sidewall 1302) to an upper overhang portion (e.g., an upper point in the retrograde sidewall 1302 relative to the lower point) and has a lateral dimension 1314 from the lower retrograde portion to the upper retrograde portion. The vertical dimension 1312 is orthogonal to the upper surface 120 of the semiconductor substrate 102, and the lateral dimension 1314 is parallel to the upper surface 120 of the semiconductor substrate 102. The vertical dimension 1312 and lateral dimension 1314 result in an angle 1318 between the upper surface 120 of the semiconductor substrate 102 and a line from the lower retrograde portion to the upper overhang portion. The angle 1318 is laterally interior to the collector opening 1202a. The angle 1318 is the inverse tangent of the ratio of the vertical dimension 1312 to the lateral dimension 1314

$$( e . g . , {θ}_{1318} = {tan}^{- 1} ( \frac{{V}_{1312}}{{L}_{1314}} ) ,$$

where θ₁₃₁₈ is the angle 1318, V₁₃₁₂ is the vertical dimension 1312, and L₁₃₁₄ is the lateral dimension 1314). In some examples, the lateral dimension 1314 is equal to or greater than 10 nm, such as equal to or greater than 20 nm.

The angle 1318 (and hence, the ratio of the vertical dimension 1312 to the lateral dimension 1314) is such that a facet formed in a subsequent epitaxial growth is trapped by the retrograde sidewall 1302. For example, when the upper surface 120 is a (001) or (100) plane of monocrystalline silicon, the sidewall orientation of the collector opening 1202a includes a (110) surface orientation, and silicon is epitaxially grown on the upper surface 120, the silicon epitaxially grown may have a facet with a (111) surface orientation. In such an example, the angle 1318 may be equal to or less than 54.7° (e.g., equal to or less than 54°). Correspondingly, the ratio of the vertical dimension 1312 to the lateral dimension 1314 may be equal to or less than 1.376. With such an angle 1318, the facet with a (111) surface orientation may intersect the retrograde sidewall 1302 when the silicon is grown to a sufficient thickness, which may cause propagation of the facet to be arrested in subsequent epitaxial growth. The angle 1318 may be another angle depending on, e.g., which surface orientation of a facet may be trapped by the retrograde sidewall 1302. Further, defects, such as stacking faults, that are generated at the interface between the pedestal dielectric stack and the epitaxially grown material may be trapped by the retrograde sidewalls 1302. This may result in higher quality epitaxially grown material in the collector opening 1202a.

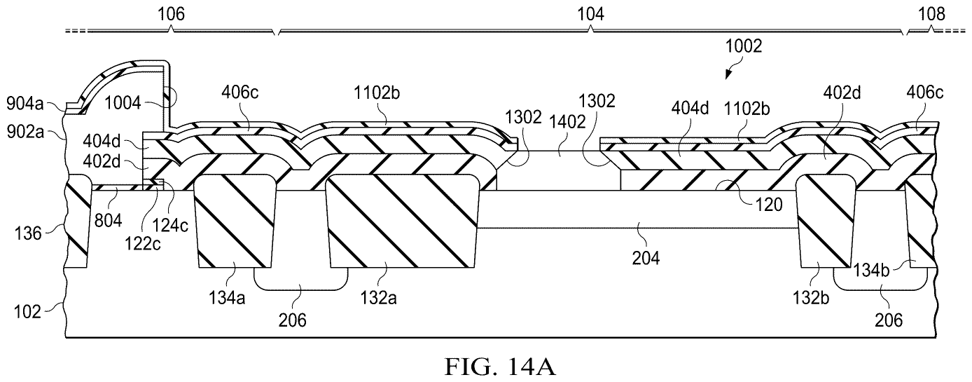

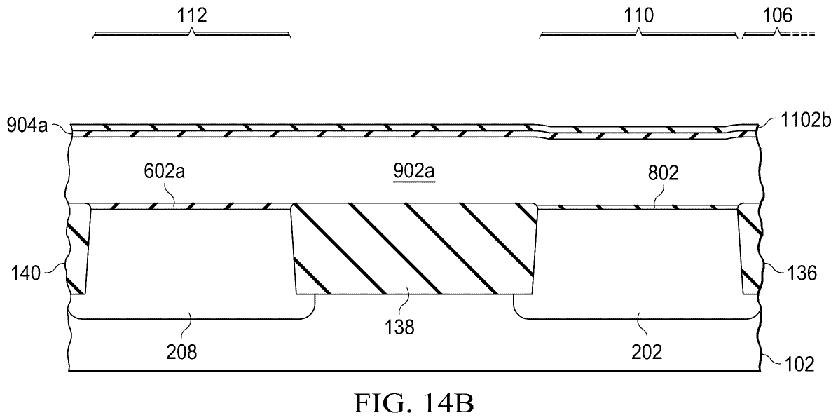

Referring to FIGS. 14A and 14B, a collector layer 1402 is formed over (e.g., on) the upper surface 120 of the semiconductor substrate 102 and in the collector opening 1202a. In some examples, the collector layer 1402 is or includes a semiconductor layer doped with an n-type dopant (e.g., a same dopant type as the n-type doped sub-collector diffusion region 204). In some examples, the collector layer 1402 is or includes silicon. In some examples, the collector layer 1402 is doped with an n-type dopant with a concentration in a range from 1×10¹⁹ cm⁻³ to 1×10²¹ cm⁻³. The collector layer 1402 may be epitaxially grown on the upper surface 120 of the semiconductor substrate 102. The collector layer 1402 may be epitaxially grown by a selective epitaxial growth process in some examples. The epitaxial growth of the collector layer 1402 on the upper surface 120 of the semiconductor substrate 102 may result in the collector layer 1402 being monocrystalline. Further, the collector layer 1402 may be in situ doped during the epitaxial growth process (e.g., the selective epitaxial growth process). The epitaxial growth process may be a CVD process, such as a LPCVD, reduced pressure CVD (RPCVD), metal organic CVD (MOCVD), or the like. The retrograde sidewalls 1302 of the collector opening 1202a may trap facets that propagate during epitaxial growth of the collector layer 1402. Hence, an upper surface of the collector layer 1402 may replicate the upper surface 120 of the semiconductor substrate 102. Other materials, dopant type, dopant concentration, and/or deposition process may be implemented.

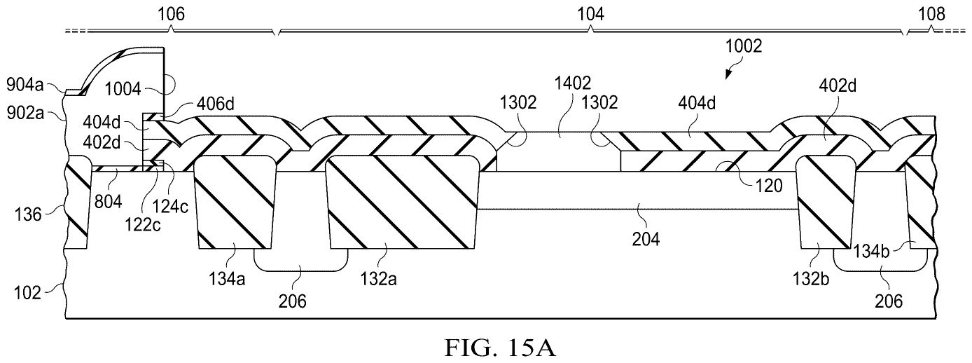

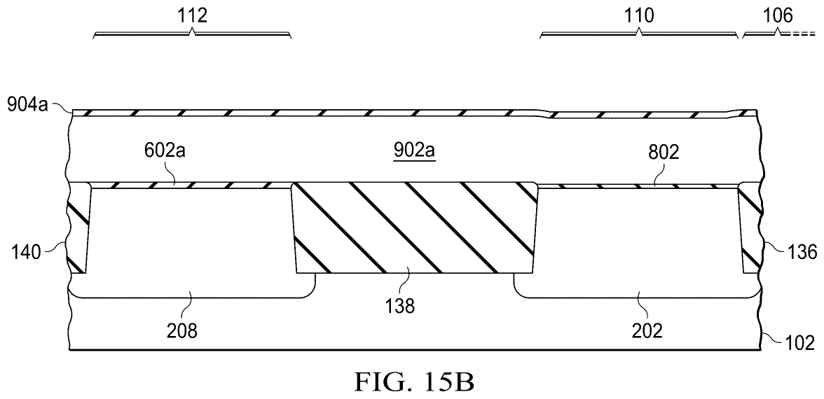

Referring to FIGS. 15A and 15B, the hardmask layer 1102b and exposed portions of the protective dielectric layer 406c are removed. The hardmask layer 1102b and the protective dielectric layer 406c may be removed using an etch selective to the material of the hardmask layer 1102b and the protective dielectric layer 406c. The etch process may be a wet or dry etch process and may be isotropic. For example, when the hardmask layer 1102b and the protective dielectric layer 406c are silicon nitride, the etch process may be or include using phosphoric (H₃PO₄) acid. A residual protective dielectric layer 406d remains in the first transition region 106 under the gate layer 902a.

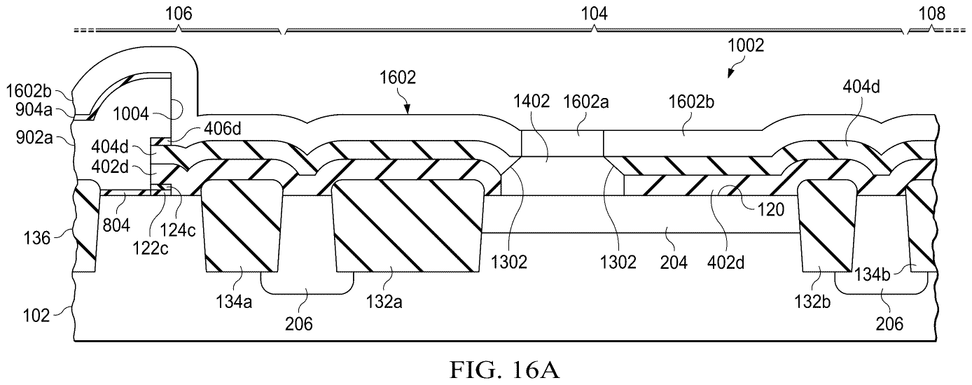

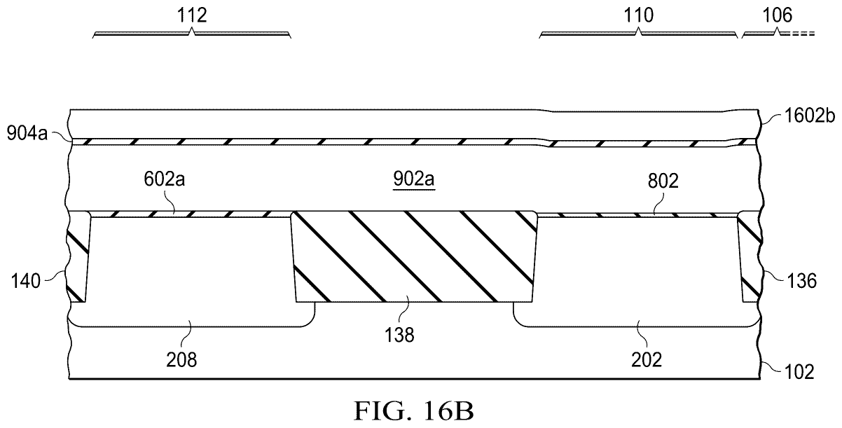

Referring to FIGS. 16A and 16B, a base layer 1602 is formed over the collector layer 1402. The base layer 1602 includes a monocrystalline base layer 1602a and a polycrystalline base layer 1602b. The monocrystalline base layer 1602a and polycrystalline base layer 1602b together form the base layer 1602. In some examples, the base layer 1602 is or includes a semiconductor layer doped with a p-type dopant (e.g., an opposite dopant type as the collector layer 1402). In some examples, the base layer 1602 is or includes silicon germanium. In some examples, the base layer 1602 is doped with a p-type dopant with a concentration in a range from 1×10¹⁷ cm⁻³ to 1×10²¹ cm⁻³. The base layer 1602 may also be doped with carbon (C) to prevent or reduce diffusion of the p-type dopant. The base layer 1602 may be epitaxially grown on the collector layer 1402 and conformally on the second pedestal dielectric sub-layer 404d, the protective dielectric layer 904a, the sidewall 1004 of the gate layer 902a, and a sidewall of the residual protective dielectric layer 406d (that aligns with the sidewall 1004). The base layer 1602 may be epitaxially grown by a non-selective epitaxial growth process in some examples. The non-selective epitaxial growth process grows the monocrystalline base layer 1602a from the collector layer 1402 and grows the polycrystalline base layer 1602b on other amorphous or polycrystalline surfaces, such as the second pedestal dielectric sub-layer 404d and the protective dielectric layer 904a. The monocrystalline base layer 1602a may meet the polycrystalline base layer 1602b at a facet that is not specifically illustrated. The non-selective deposition of the base layer 1602 forms the base layer 1602 conformally. The base layer 1602 may be in situ doped during the epitaxial growth process. The base layer 1602 (e.g., the monocrystalline base layer 1602a and polycrystalline base layer 1602b each) may further include multiple sub-layers, such as a nucleation sub-layer of the same material as the collector layer 1402, an undoped sub-layer, a doped sub-layer, and a cap sub-layer of the same material of the emitter layer (described subsequently). The epitaxial growth process may be a CVD process, such as LPCVD, RPCVD, MOCVD, or the like. Other materials, dopant type, dopant concentration, and/or deposition process may be implemented.

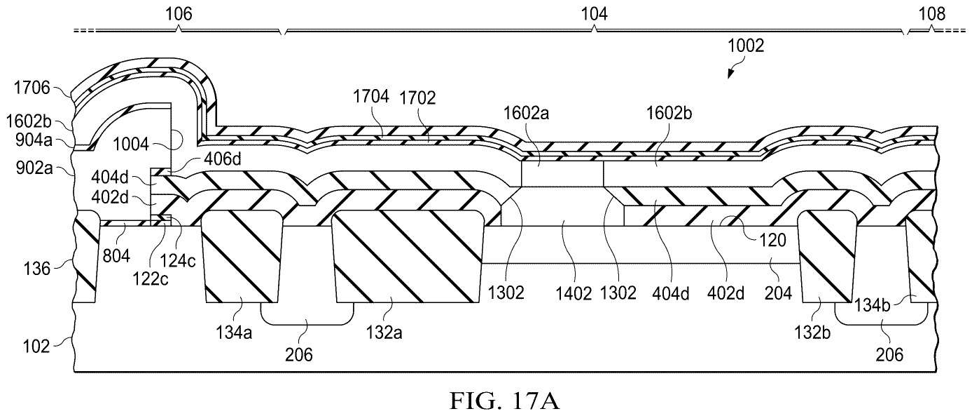

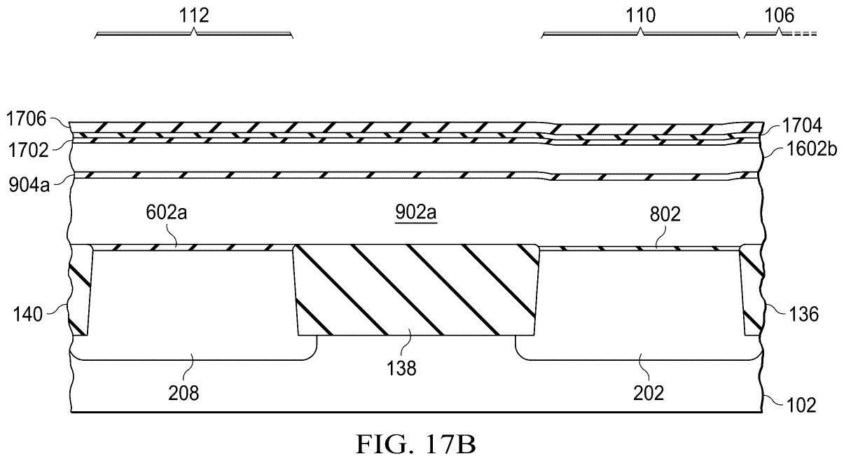

Referring to FIGS. 17A and 17B, a first dielectric spacer layer 1702 is formed conformally over the base layer 1602. A second dielectric spacer layer 1704 is formed conformally over the first dielectric spacer layer 1702, and a third dielectric spacer layer 1706 is formed conformally over the second dielectric spacer layer 1704. In some examples, the first dielectric spacer layer 1702 and third dielectric spacer layer 1706 are a same dielectric material, and the second dielectric spacer layer 1704 is a dielectric material different from the dielectric material of the first dielectric spacer layer 1702 and third dielectric spacer layer 1706. In some examples, the first dielectric spacer layer 1702 and third dielectric spacer layer 1706 are silicon oxide (e.g., a TEOS oxide), and the second dielectric spacer layer 1704 is silicon nitride. The dielectric spacer layers 1702-1706 may be deposited by CVD. Other dielectric materials and/or other deposition processes may be used in other examples.

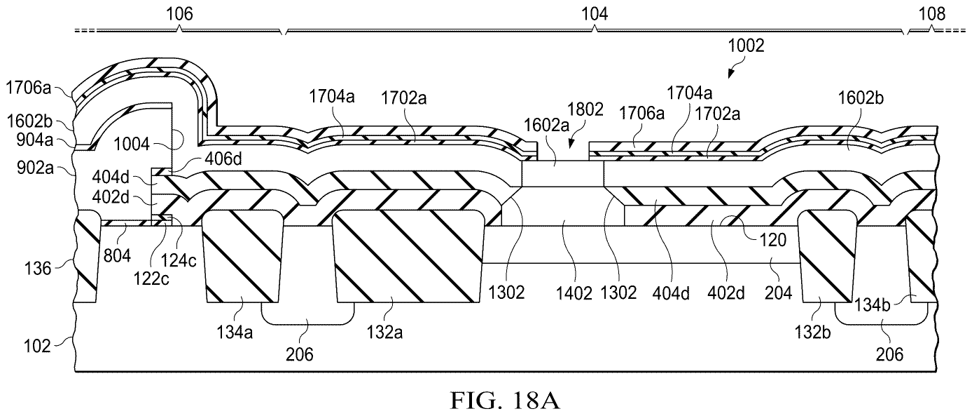

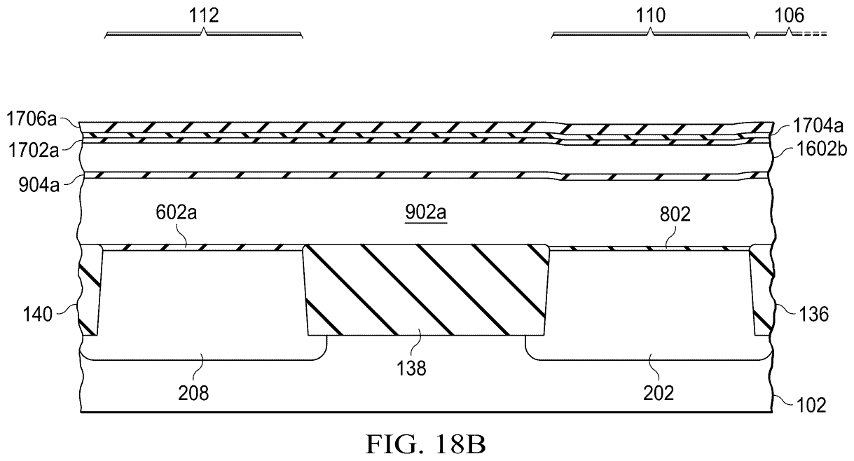

Referring to FIGS. 18A and 18B, the dielectric spacer layers 1702-1706 are etched to form a first emitter opening 1802 in the BJT region 104 through the first dielectric spacer layer 1702a, second dielectric spacer layer 1704a, and third dielectric spacer layer 1706a. The monocrystalline base layer 1602a (of the base layer 1602) is exposed through the first emitter opening 1802. The dielectric spacer layers 1702-1706 may be patterned using appropriate photolithography and etch (e.g., RIE) processes.

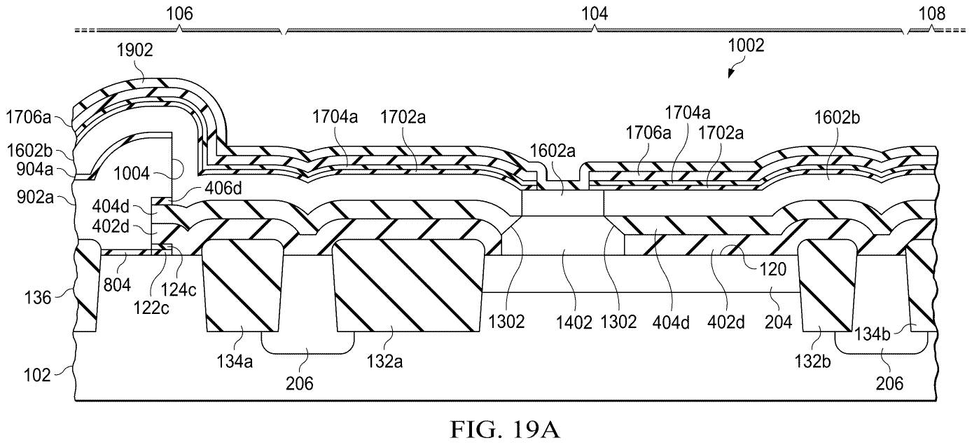

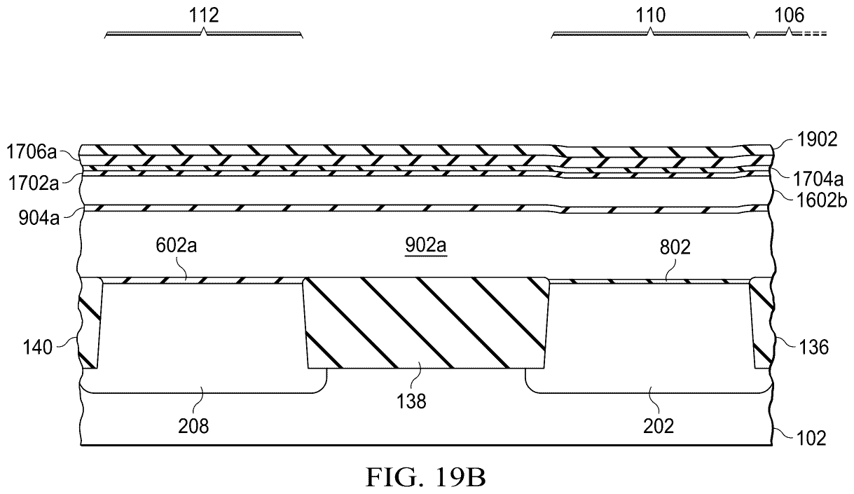

Referring to FIGS. 19A and 19B, an emitter dielectric spacer layer 1902 is conformally formed over the third dielectric spacer layer 1706a and in the first emitter opening 1802. In some examples, the emitter dielectric spacer layer 1902 is silicon oxide (e.g., a TEOS oxide) deposited by CVD, although other dielectric materials and/or other deposition processes may be used in other examples.

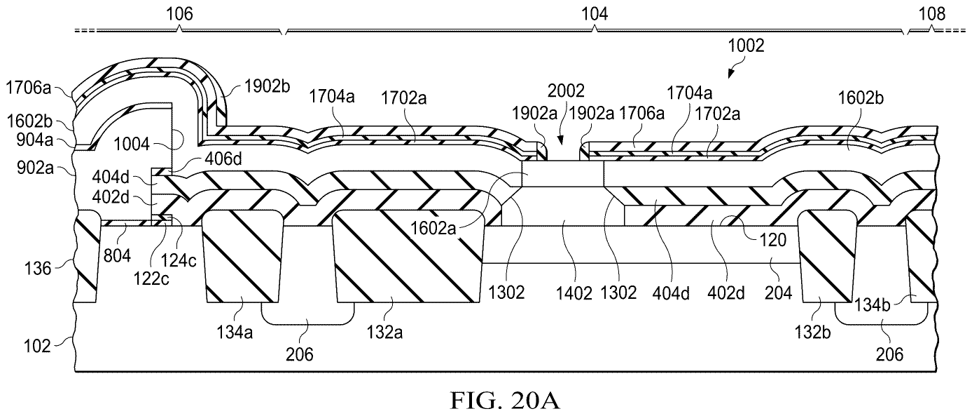

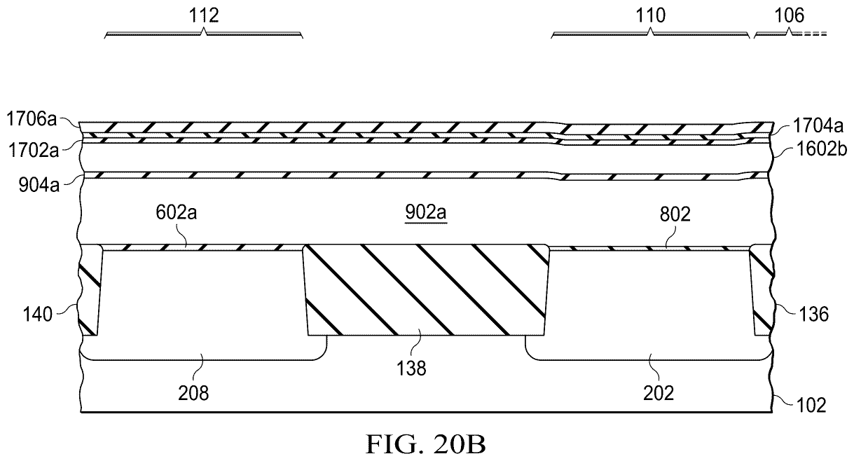

Referring to FIGS. 20A and 20B, the emitter dielectric spacer layer 1902 is anisotropically etched to form emitter dielectric spacers 1902a along sidewalls of the dielectric spacer layers 1702a, 1704a, 1706a that define the first emitter opening 1802. The emitter dielectric spacers 1902a constrict the first emitter opening 1802 to form a second emitter opening 2002. Additionally, a residual emitter dielectric spacer 1902b may remain on a vertical surface, such as a vertical surface at the sidewall 1004 of the gate layer 902a in the first transition region 106. The anisotropic etch may be an RIE, for example.

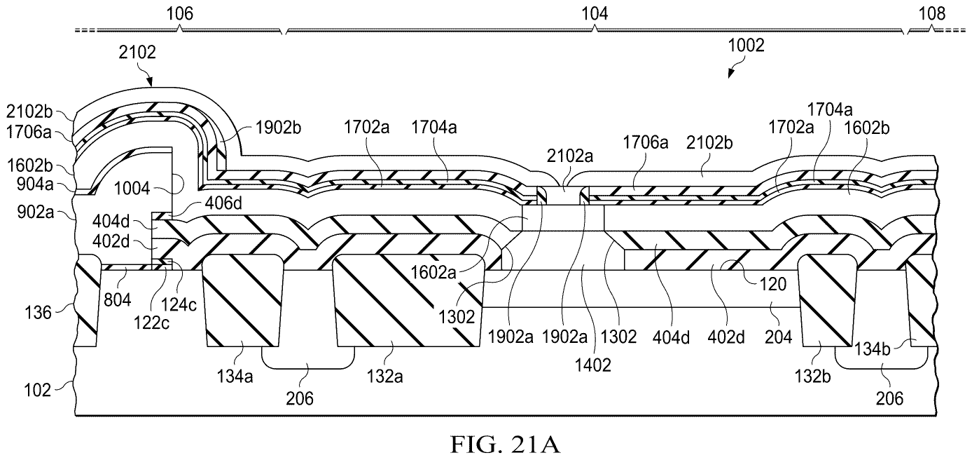

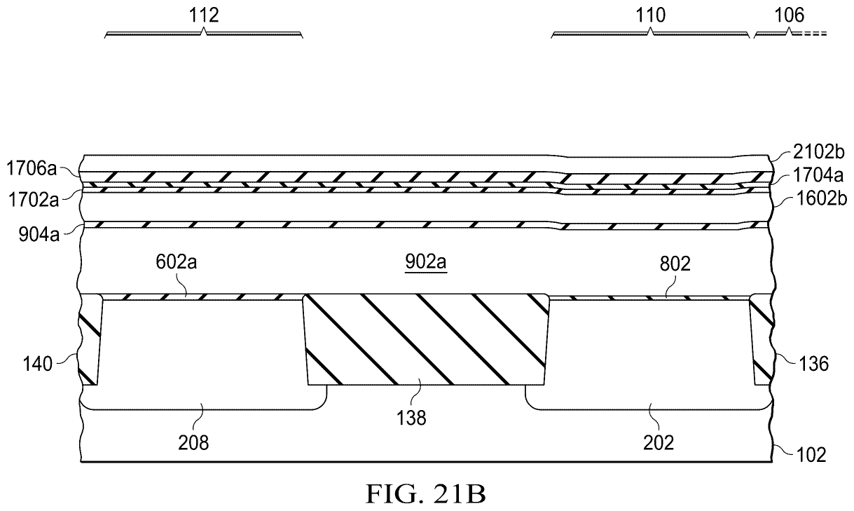

Referring to FIGS. 21A and 21B, an emitter layer 2102 is formed over the base layer 1602 (e.g., on the monocrystalline base layer 1602a). The emitter layer 2102 includes a monocrystalline emitter layer 2102a and a polycrystalline emitter layer 2102b. The monocrystalline emitter layer 2102a and polycrystalline emitter layer 2102b together form the emitter layer 2102. In some examples, the emitter layer 2102 is or includes a semiconductor layer doped with an n-type dopant (e.g., an opposite dopant type from the base layer 1602). In some examples, the emitter layer 2102 is or includes silicon. In some examples, the emitter layer 2102 is doped with an n-type dopant with a concentration in a range from 1×10¹⁹ cm⁻³ to 1×10²¹ cm⁻³. The emitter layer 2102 may be epitaxially grown on the base layer 1602 (e.g., the monocrystalline base layer 1602a) exposed through the second emitter opening 2002, the emitter dielectric spacers 1902a, the third dielectric spacer layer 1706a, and the residual emitter dielectric spacer 1902b. The emitter layer 2102 may be epitaxially grown by a non-selective epitaxial growth process in some examples. The non-selective epitaxial growth process grows the monocrystalline emitter layer 2102a from the monocrystalline base layer 1602a and grows the polycrystalline emitter layer 2102b on other amorphous or polycrystalline surfaces, such as the emitter dielectric spacers 1902a, the third dielectric spacer layer 1706a, and the residual emitter dielectric spacer 1902b. The monocrystalline emitter layer 2102a may meet the polycrystalline emitter layer 2102b at a facet that is not specifically illustrated. The non-selective deposition of the emitter layer 2102 forms the emitter layer 2102 conformally. The emitter layer 2102 may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

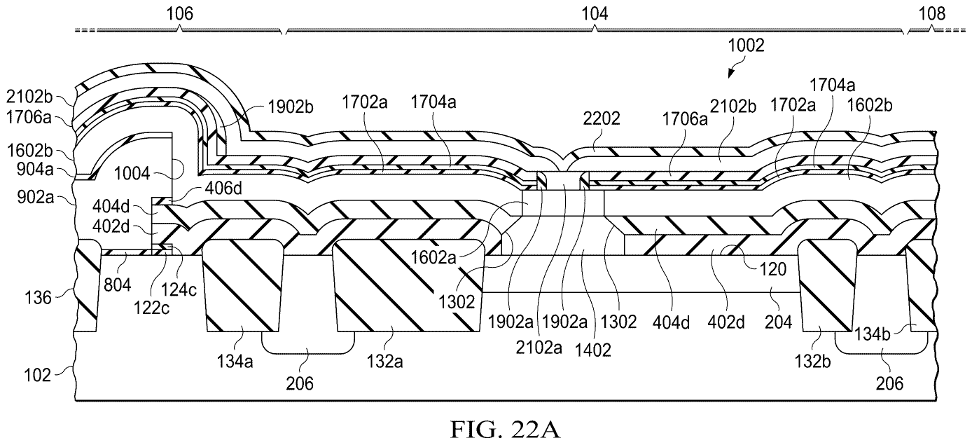

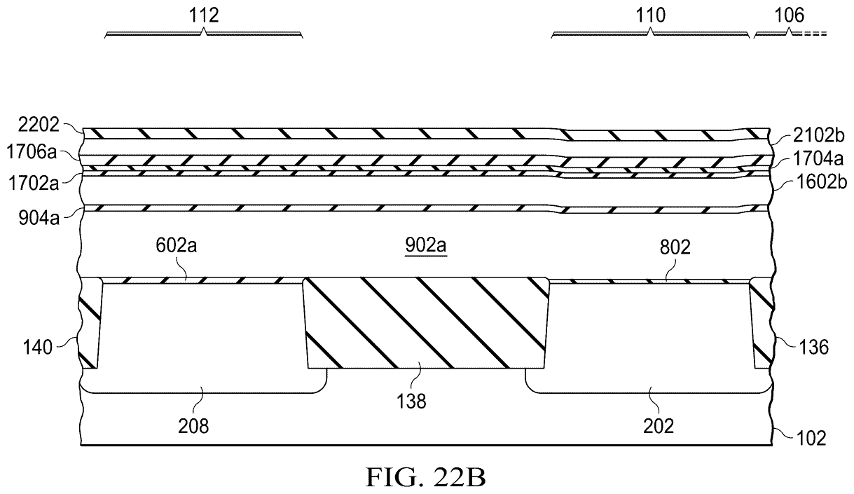

Referring to FIGS. 22A and 22B, an emitter dielectric cap layer 2202 is conformally formed over the emitter layer 2102. In some examples, the emitter dielectric cap layer 2202 is silicon oxide (e.g., a TEOS oxide) deposited by CVD, although other dielectric materials and/or other deposition processes may be used in other examples.

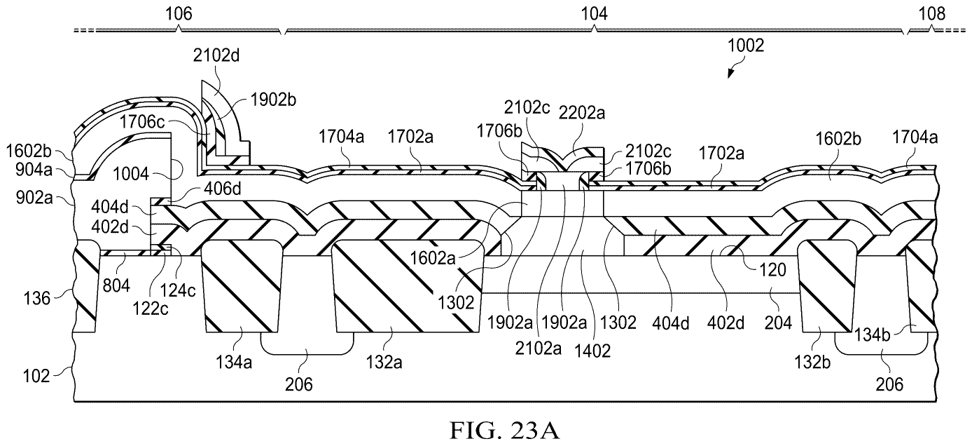

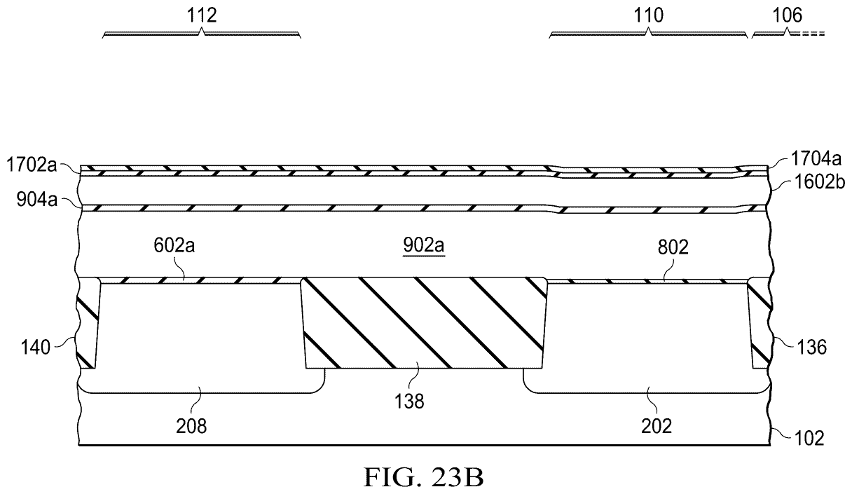

Referring to FIGS. 23A and 23B, the emitter dielectric cap layer 2202, polycrystalline emitter layer 2102b, and third dielectric spacer layer 1706a are patterned to form the emitter dielectric cap layer 2202a, polycrystalline emitter layer 2102c, and third dielectric spacer layer 1706b in the BJT region 104. In the illustrated example, the layers 2202, 2102b, 1706a are patterned using appropriate photolithography and etch (e.g., anisotropic etch, such as RIE) processes. A residual polycrystalline emitter layer 2102d and a residual third dielectric spacer layer 1706c may remain at the sidewall 1004 of the gate layer 902a in the first transition region 106 due to the etch process (e.g., anisotropic etch).

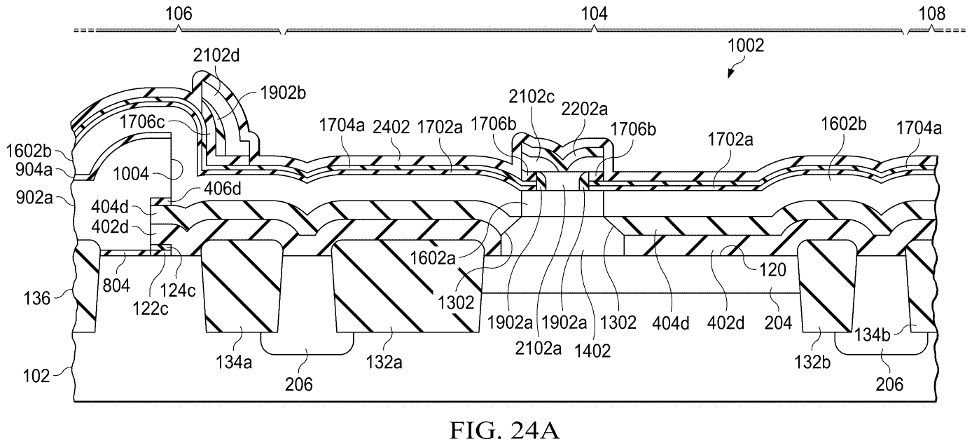

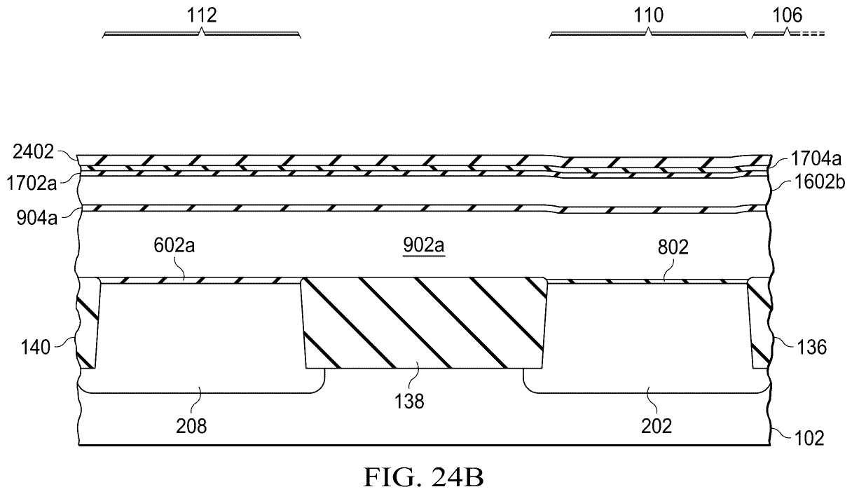

Referring to FIGS. 24A and 24B, an emitter dielectric protective spacer layer 2402 is conformally formed over the emitter dielectric cap layer 2202a and the second dielectric spacer layer 1704a and along sidewalls of the emitter dielectric cap layer 2202a, polycrystalline emitter layer 2102c, and third dielectric spacer layer 1706b in the BJT region 104. Additionally, the emitter dielectric protective spacer layer 2402 is conformally formed over the residual polycrystalline emitter layer 2102d and along sidewalls of the residual polycrystalline emitter layer 2102d and residual third dielectric spacer layer 1706c in the first transition region 106 and over the second dielectric spacer layer 1704a in the first transition region 106. The emitter dielectric protective spacer layer 2402 is formed over the second dielectric spacer layer 1704a in the pFET region 110 and nFET region 112. In some examples, the emitter dielectric protective spacer layer 2402 is silicon oxide (e.g., a TEOS oxide) deposited by CVD, although other dielectric materials and/or other deposition processes may be used in other examples.

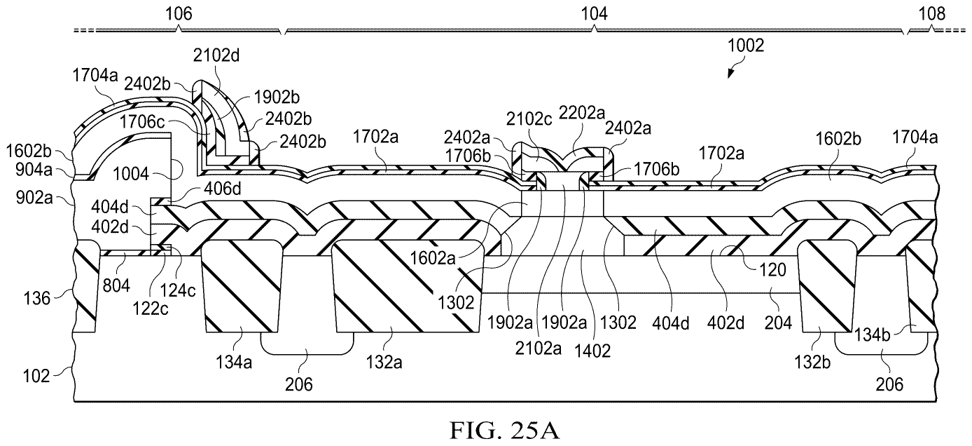

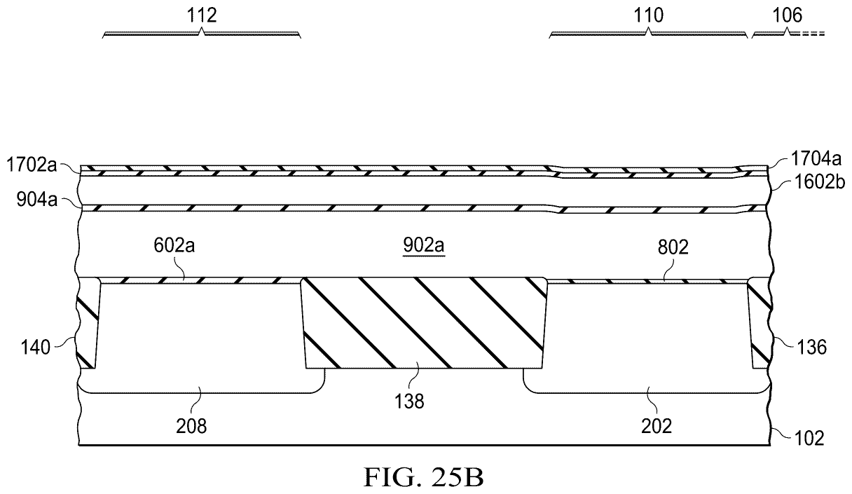

Referring to FIGS. 25A and 25B, the emitter dielectric protective spacer layer 2402 is anisotropically etched to form emitter dielectric protective spacers 2402a along sidewalls of the emitter dielectric cap layer 2202a, polycrystalline emitter layer 2102c, and third dielectric spacer layer 1706b. The emitter dielectric protective spacers 2402a protect sidewalls of the polycrystalline emitter layer 2102c. Additionally, residual emitter dielectric protective spacers 2402b may remain on vertical surfaces, such as vertical surfaces of the residual polycrystalline emitter layer 2102d and residual third dielectric spacer layer 1706c in the first transition region 106. The anisotropic etch may be an RIE, for example.

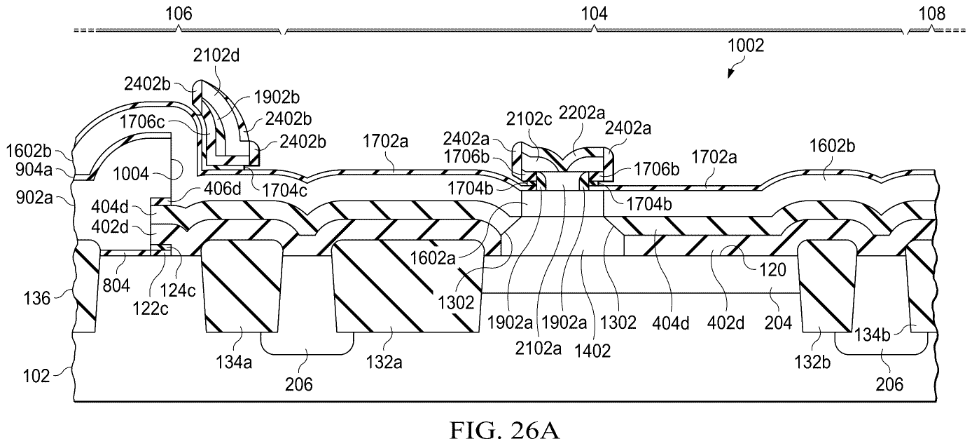

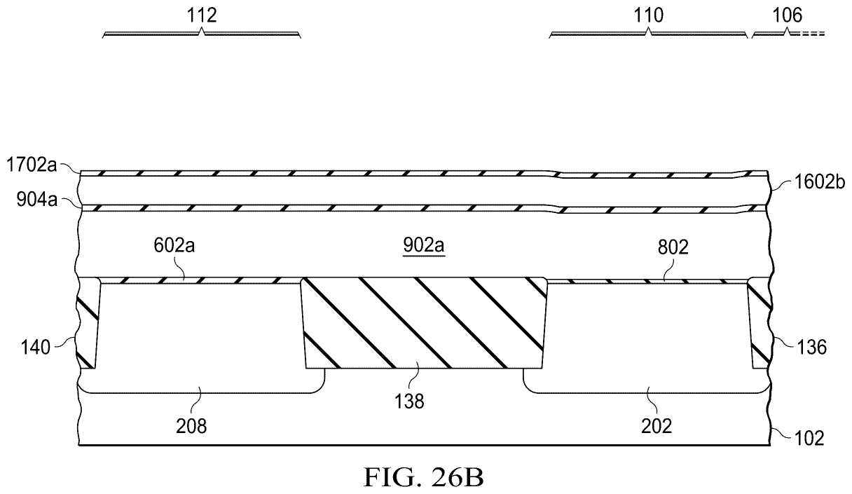

Referring to FIGS. 26A and 26B, the second dielectric spacer layer 1704a is etched. The etch removes exposed portions of the second dielectric spacer layer 1704a and undercuts the emitter dielectric protective spacers 2402a and third dielectric spacer layer 1706b laterally distal from the monocrystalline emitter layer 2102a, which results in second dielectric spacer layer 1704b under the third dielectric spacer layer 1706b. The etch may also undercut any of the residual emitter dielectric protective spacers 2402b in the first transition region 106, which further forms residual second dielectric spacer layer 1704c. The etch may be a wet or dry etch selective to the material of the second dielectric spacer layer 1704a, which etch is also isotropic. For example, when the second dielectric spacer layer 1704a is silicon nitride, the etch process may be or include using phosphoric acid.

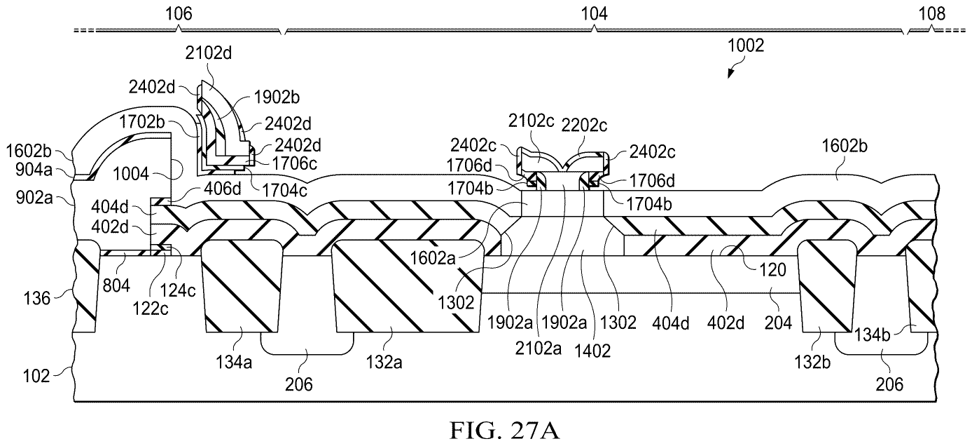

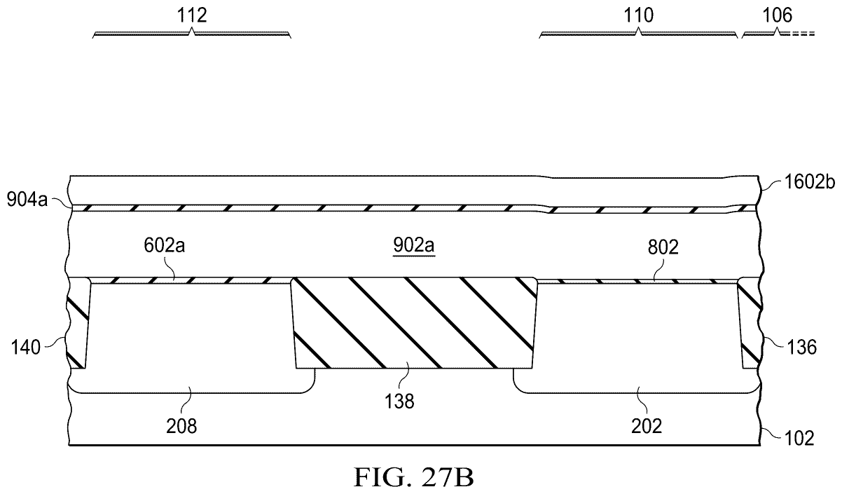

Referring to FIGS. 27A and 27B, the first dielectric spacer layer 1702a is etched. Etching the first dielectric spacer layer 1702a removes exposed portions of the first dielectric spacer layer 1702a, such as from the monocrystalline base layer 1602a. The etch may be a wet etch selective to the first dielectric spacer layer 1702a. A wet etch may remove the first dielectric spacer layer 1702a that underlies the emitter dielectric protective spacers 2402a and the second dielectric spacer layer 1704b. For example, when the first dielectric spacer layer 1702a is silicon oxide, the first dielectric spacer layer 1702a may be etched using a dilute hydrofluoric (dHF) acid etch. The removal of the first dielectric spacer layer 1702a opens (e.g., exposes) an area on the base layer 1602 near the monocrystalline emitter layer 2102a on which a raised base layer may be formed. Additionally, the wet etch may further etch the emitter dielectric cap layer 2202a, emitter dielectric protective spacers 2402a, and the third dielectric spacer layer 1706b when those layer and spacers are a same material as the first dielectric spacer layer 1702a, which reduces respective thicknesses of those layer and spacers and results in emitter dielectric cap layer 2202c, emitter dielectric protective spacers 2402c, and third dielectric spacer layer 1706d, such as illustrated. A residual first dielectric spacer layer 1702b remains under the residual second dielectric spacer layer 1704c in the first transition region 106. Additionally, in the first transition region 106, the wet etch may further etch the residual emitter dielectric protective spacers 2402b when those spacers are a same material as the first dielectric spacer layer 1702a, which reduces the spacers resulting in residual emitter dielectric protective spacers 2402d, such as illustrated.

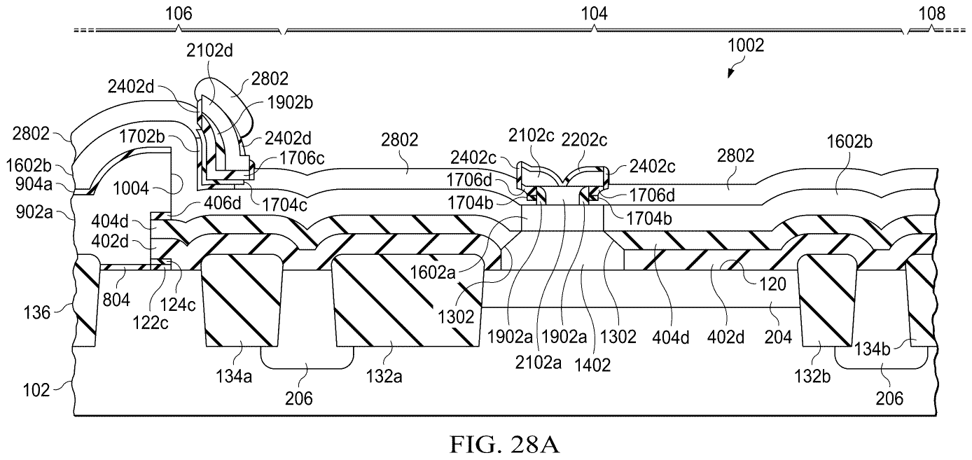

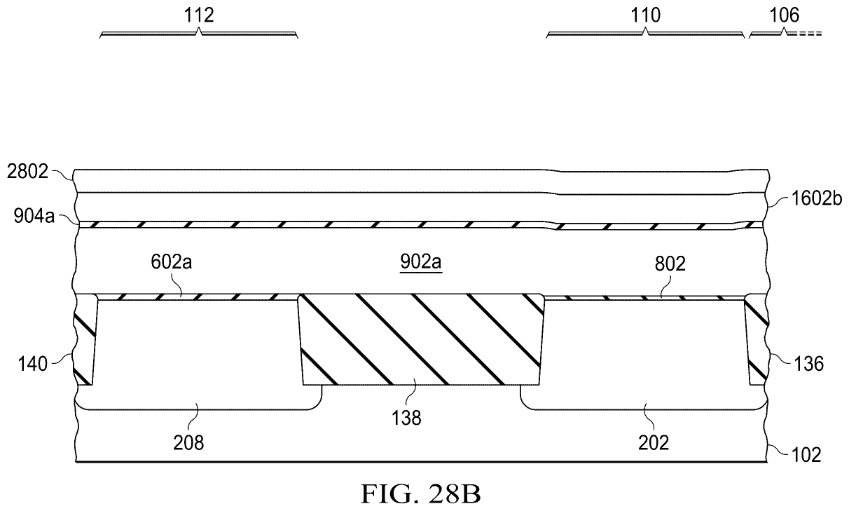

Referring to FIGS. 28A and 28B, a raised base layer 2802 is formed over (e.g., on) the base layer 1602. The raised base layer 2802 includes at least a polycrystalline raised base layer on the polycrystalline base layer 1602b. The raised base layer 2802 may include a monocrystalline raised base layer. If the monocrystalline base layer 1602a is exposed by etching the first dielectric spacer layer 1702a, the raised base layer 2802 may include a monocrystalline portion on the monocrystalline base layer 1602a. In some examples, the raised base layer 2802 is or includes a semiconductor layer doped with a p-type dopant (e.g., a same dopant type as the base layer 1602). In some examples, the raised base layer 2802 is or includes silicon. In some examples, the raised base layer 2802 is doped with a p-type dopant with a concentration in a range from 1×10¹⁹ cm⁻³ to 1×10²¹ cm⁻³. The raised base layer 2802 may be epitaxially grown on the base layer 1602. The raised base layer 2802 may be epitaxially grown by a selective epitaxial growth process in some examples. The selective deposition of the raised base layer 2802 forms the raised base layer 2802 conformally on crystalline (e.g., polycrystalline and monocrystalline) surfaces, which include exposed portions of the base layer 1602 (e.g., the polycrystalline base layer 1602b). Further, the raised base layer 2802 may be in situ doped during the epitaxial growth process (e.g., the selective epitaxial growth process). The epitaxial growth process may be a CVD process, such as LPCVD, RPCVD, MOCVD, or the like. Other materials, dopant type, dopant concentration, and/or deposition process may be implemented.

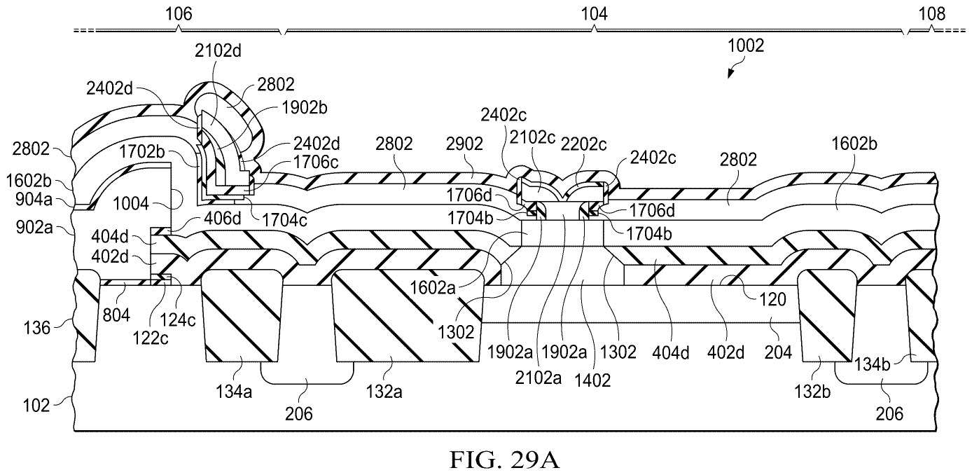

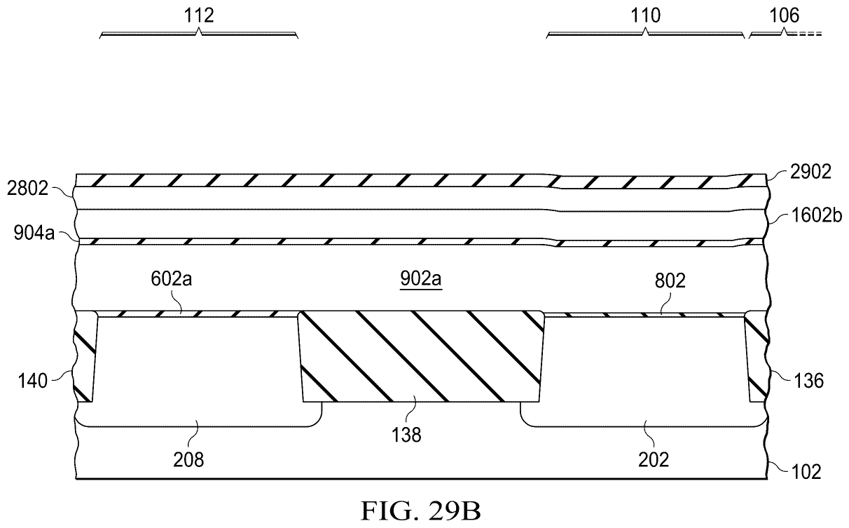

Referring to FIGS. 29A and 29B, a protective dielectric layer 2902 is conformally formed over and along the emitter dielectric cap layer 2202c, the emitter dielectric protective spacers 2402c, and the raised base layer 2802 in the BJT region 104. The protective dielectric layer 2902 is further conformally formed over and along the raised base layer 2802 and the residual emitter dielectric protective spacers 2402d in the first transition region 106 and over the raised base layer 2802 in the pFET region 110 and nFET region 112. In some examples, the protective dielectric layer 2902 is silicon oxide (e.g., a TEOS oxide) deposited by CVD, although other dielectric materials and/or other deposition processes may be used in other examples.

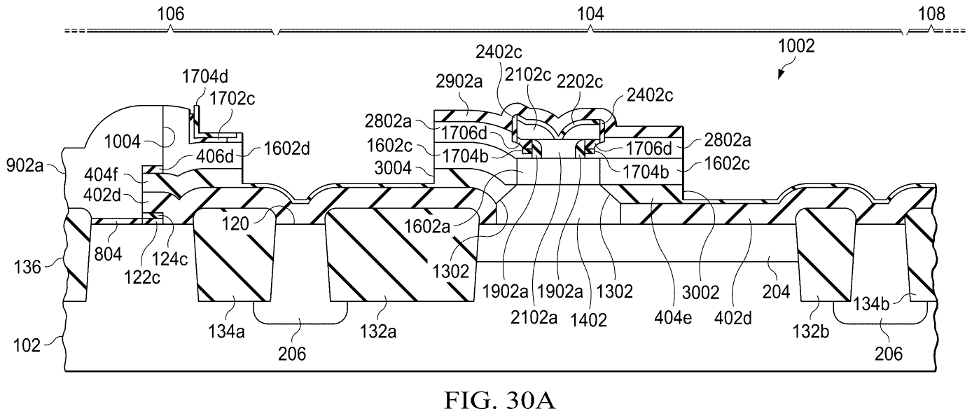

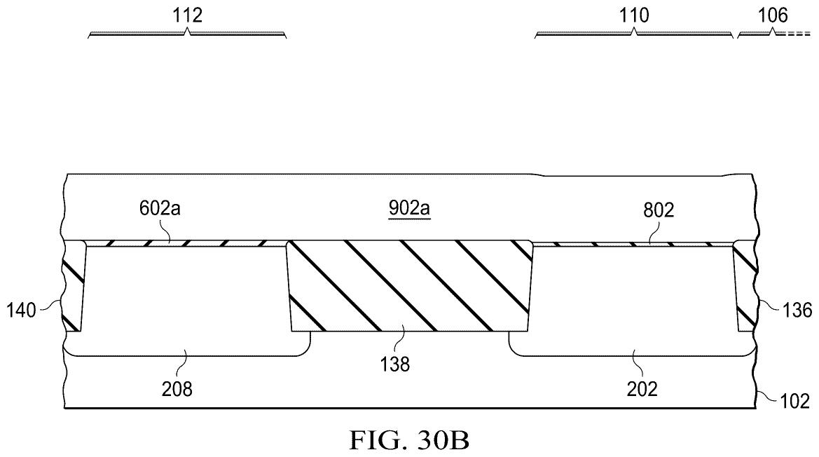

Referring to FIGS. 30A and 30B, the protective dielectric layer 2902, the raised base layer 2802, the base layer 1602 (e.g., the polycrystalline base layer 1602b), and the second pedestal dielectric sub-layer 404d are patterned in the BJT region 104. The protective dielectric layer 2902, raised base layer 2802, the polycrystalline base layer 1602b, and the second pedestal dielectric sub-layer 404d are patterned to remain as the protective dielectric layer 2902a, the raised base layer 2802a, the polycrystalline base layer 1602c, and the second pedestal dielectric sub-layer 404e, respectively, in the BJT region 104. Patterning the second pedestal dielectric sub-layer 404d results in sidewalls 3002, 3004 of the second pedestal dielectric sub-layer 404e that align with respective sidewalls of the polycrystalline base layer 1602c and, further, the raised base layer 2802a. The layers 2902, 2802, 1602b, 404d may be patterned or thinned using appropriate photolithography and etch (e.g., RIE) processes.

As illustrated, etching the protective dielectric layer 2902, the raised base layer 2802, and the polycrystalline base layer 1602b may remove the protective dielectric layer 2902, the residual emitter dielectric protective spacers 2402d, the raised base layer 2802, and the residual polycrystalline emitter layer 2102d from the first transition region 106. Thereafter, etching the second pedestal dielectric sub-layer 404d may remove any remaining residual emitter dielectric protective spacers 2402d, the residual emitter dielectric spacer 1902b, the residual third dielectric spacer layer 1706c, and the protective dielectric layer 904a in the first transition region 106.

Etching the second pedestal dielectric sub-layer 404d results in a residual second pedestal dielectric sub-layer 404f remaining in the first transition region 106. A residual polycrystalline base layer 1602d remains in the first transition region 106 along the sidewall 1004 of the gate layer 902a and the sidewall of the residual protective dielectric layer 406d (aligned with the sidewall 1004) and over the residual second pedestal dielectric sub-layer 404f. The various etches may also reduce the residual dielectric spacer layers 1704c, 1702b such that residual dielectric spacer layers 1704d, 1702c remain over the residual polycrystalline base layer 1602d. Further, the various etches remove the protective dielectric layer 2902, the raised base layer 2802, the polycrystalline base layer 1602b, and the protective dielectric layer 904a from the pFET region 110 and the nFET region 112.

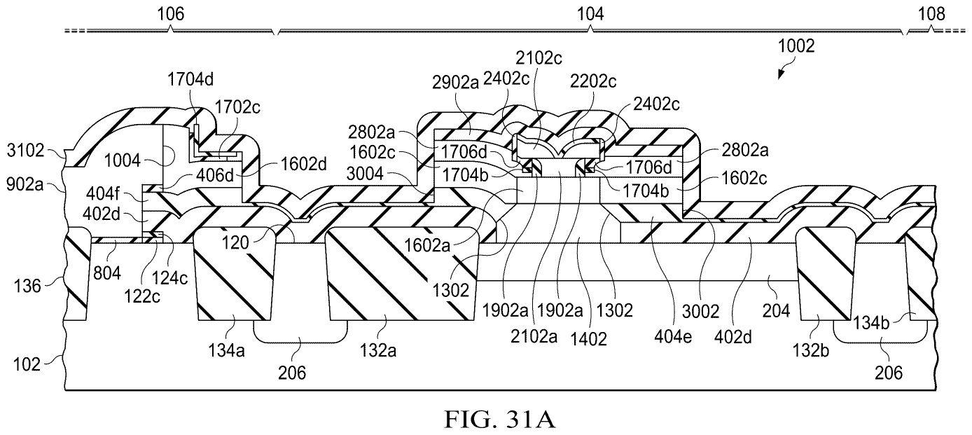

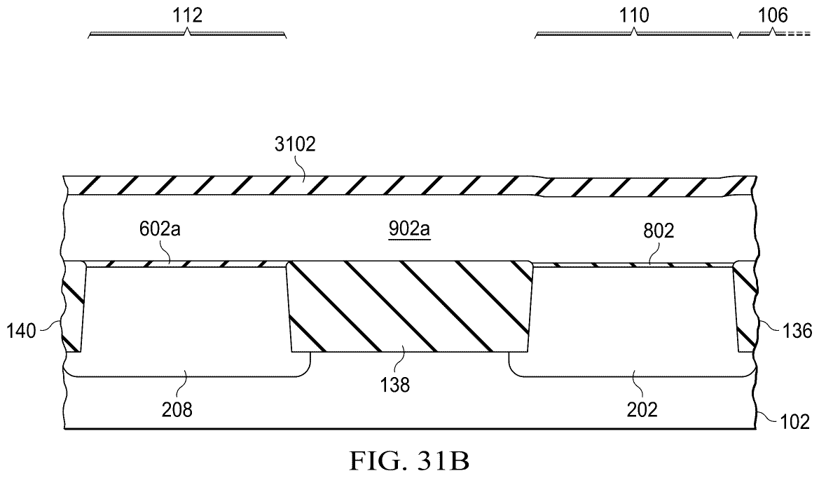

Referring to FIGS. 31A and 31B, a hardmask layer 3102 is conformally formed over the semiconductor substrate 102. More specifically, the hardmask layer 3102 is conformally formed over the first pedestal dielectric sub-layer 402d and the protective dielectric layer 2902a and along sidewalls of the protective dielectric layer 2902a, the raised base layer 2802a, the polycrystalline base layer 1602c, and the second pedestal dielectric sub-layer 404e in the BJT region 104. The hardmask layer 3102 is conformally formed over the gate layer 902a in the first transition region 106, the pFET region 110, and the nFET region 112 and is conformally formed over and along respective sidewalls of the residual second pedestal dielectric sub-layer 404f, residual polycrystalline base layer 1602d, and the residual dielectric spacer layers 1702c, 1704d in the first transition region 106. In some examples, the hardmask layer 3102 is or includes silicon nitride deposited by CVD, although other hardmask (e.g., dielectric) materials and/or other deposition processes may be used in other examples.

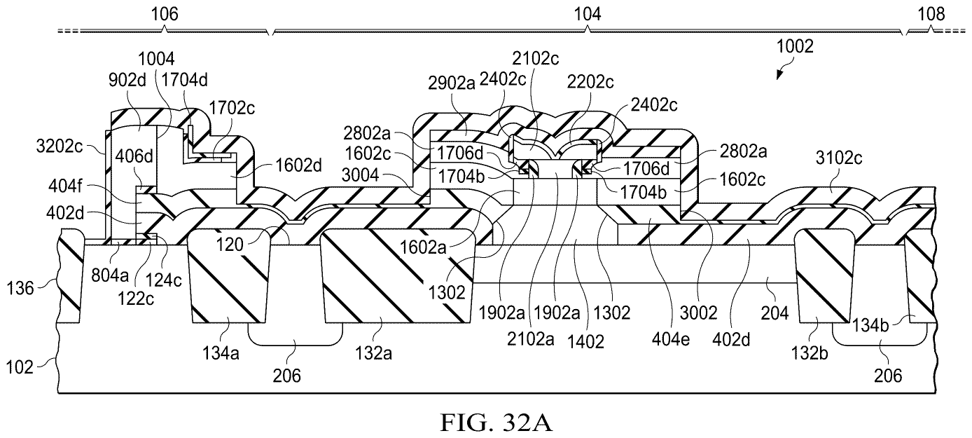

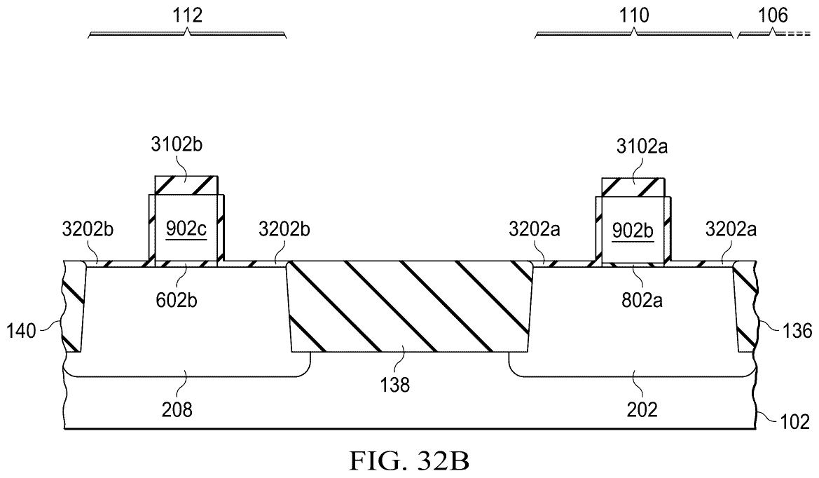

Referring to FIGS. 32A and 32B, the hardmask layer 3102, the gate layer 902a, and the gate oxide layers 802, 602a are patterned into hardmask layers 3102a, 3102b, gate electrodes 902b, 902c, and gate oxide layers 802a, 602b in the pFET region 110 and nFET region 112, respectively. The gate electrode 902b is over (e.g., on) the gate oxide layer 802a in the pFET region 110, and the gate electrode 902c is over (e.g., on) the gate oxide layer 602b in the nFET region 112. The hardmask layers 3102a, 3102b remain over (e.g., on) the gate electrodes 902b, 902c, respectively. The hardmask layer 3102, the gate layer 902a, and the gate oxide layers 802, 602a may be patterned using appropriate photolithography and etch (e.g., RIE) processes.

Patterning the hardmask layer 3102 results in hardmask layer 3102c remaining in the BJT region and transition regions 106, 108. A residual oxide layer 804a remains in the first transition region 106. A residual gate layer 902d (with the sidewall 1004) remains in the first transition region 106 along aligned sidewalls of the residual protective dielectric layer 406d, the residual second pedestal dielectric sub-layer 404f, and the first pedestal dielectric sub-layer 402d. The residual gate layer 902d is further over the residual oxide layer 804a and the residual protective dielectric layer 406d and is along a sidewall of the residual polycrystalline base layer 1602d.

Reoxidation layers 3202a, 3202b are formed along sidewalls of the gate electrodes 902b, 902c and exposed portions of the upper surface 120 of the semiconductor substrate 102.

The reoxidation layer 3202a is along sidewalls of the gate electrode 902b and exposed portions of the upper surface 120 in the pFET region 110, and the reoxidation layer 3202b is along sidewalls of the gate electrode 902c and exposed portions of the upper surface 120 in the nFET region 112. The reoxidation layers 3202a, 3202b may be formed by an oxidation process, such as by ISSG oxidation. The formation of the reoxidation layers 3202a, 3202b may remove damage on the sidewalls of the gate electrodes 902b, 902c and/or the upper surface 120 formed by the etch process that patterns the gate electrodes 902b, 902c, which damage may be plasma-induced. The formation of the reoxidation layers 3202a, 3202b may reduce gate-induced drain leakage current in the FETs (that include the gate electrodes 902b, 902c) that are to be formed. additionally, the oxidation process the forms the reoxidation layers 3202a, 3202b, in some examples, forms a residual reoxidation layer 3202c on an exposed portion of the upper surface 120 and a sidewall of the residual gate layer 902d (opposite from the sidewall 1004) in the first transition region 106.

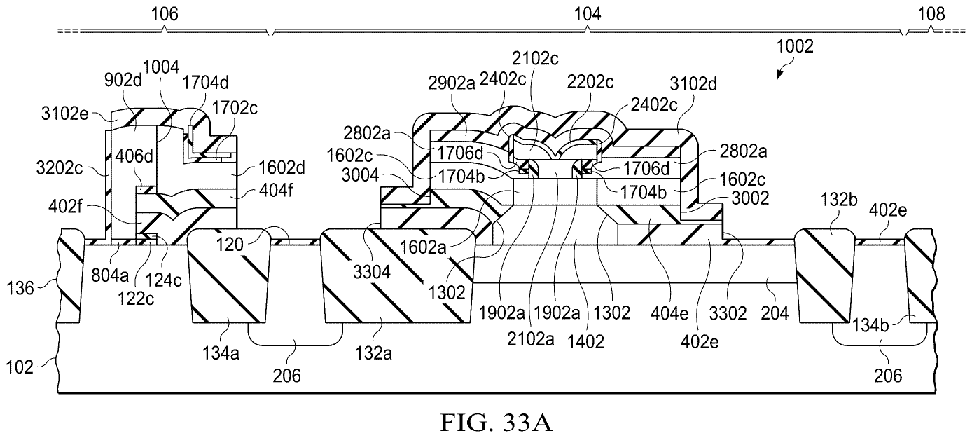

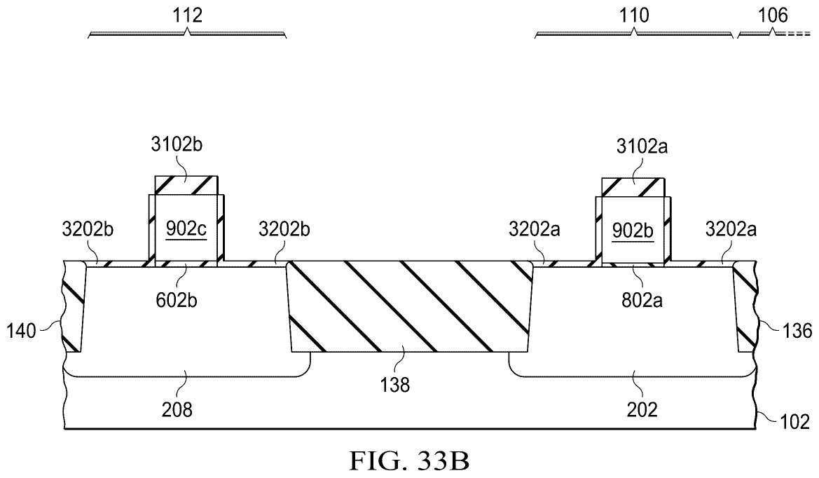

Referring to FIGS. 33A and 33B, the hardmask layer 3102c and the first pedestal dielectric sub-layer 402d are patterned into hardmask layers 3102d, 3102e, first pedestal dielectric sub-layer 402e, and residual first pedestal dielectric sub-layer 402f. The hardmask layer 3102d and first pedestal dielectric sub-layer 402e are in the BJT region 104. Specifically, the hardmask layer 3102d is over the protective dielectric layer 2902a and the first pedestal dielectric sub-layer 402e, along sidewalls of the protective dielectric layer 2902a, the raised base layer 2802a, and the polycrystalline base layer 1602c, and along the sidewalls 3002, 3004 of the second pedestal dielectric sub-layer 404e. The hardmask layer 3102d extends over the first pedestal dielectric sub-layer 402e laterally away from the polycrystalline base layer 1602c and from the sidewalls 3002, 3004 of the second pedestal dielectric sub-layer 404e. The first pedestal dielectric sub-layer 402e generally is laterally coextensive with the hardmask layer 3102d, although thin amounts of the first pedestal dielectric sub-layer 402emay remain on the upper surface 120 in the BJT region 104 laterally outside of the hardmask layer 3102 (e.g., to protect the upper surface 120 during processing). Patterning the first pedestal dielectric sub-layer 402d forms the first pedestal dielectric sub-layer 402e with sidewalls 3302, 3304. The sidewalls 3302, 3304 are laterally away from respective sidewalls 3002, 3004 of the second pedestal dielectric sub-layer 404e. The sidewall 3302 of the first pedestal dielectric sub-layer 402e is over the upper surface 120 of the semiconductor substrate 102 and the n-type doped sub-collector diffusion region 204. The sidewall 3304 of the first pedestal dielectric sub-layer 402e is over the first portion 132a of the isolation structure 132. Portions of the hardmask layer 3102c and the first pedestal dielectric sub-layer 402d are removed from over at least a portion of the n-type doped sub-collector diffusion region 204 and the p-type doped well 206. The hardmask layer 3102c and the first pedestal dielectric sub-layer 402d may be patterned using appropriate photolithography and etch (e.g., RIE) processes.

The hardmask layer 3102e and residual first pedestal dielectric sub-layer 402f are in the first transition region 106. The residual first pedestal dielectric sub-layer 402f is over the residual second oxide layer 124c and the first portion 134a of the isolation structure 134 and is under the residual second pedestal dielectric sub-layer 404f.

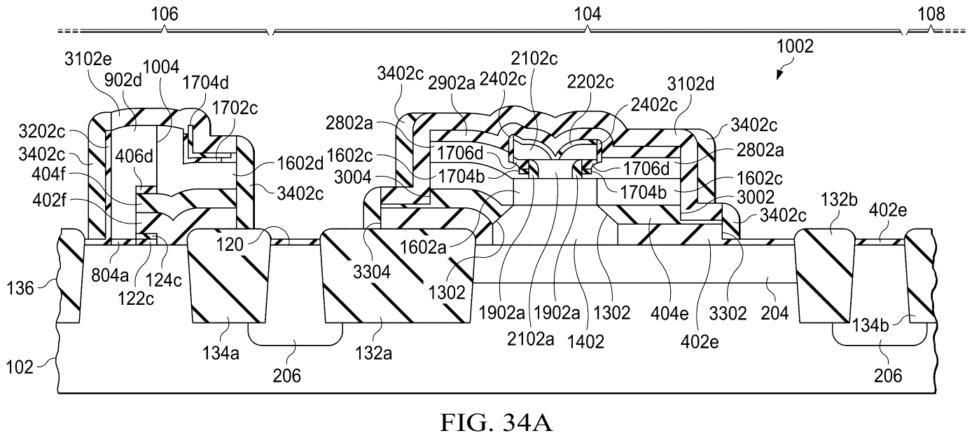

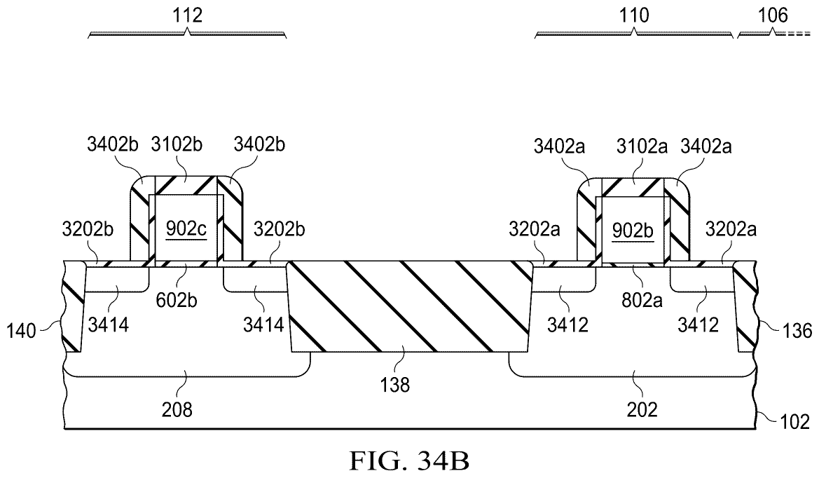

Referring to FIGS. 34A and 34B, first gate dielectric spacers 3402a, 3402b are formed along the sidewalls of the gate electrodes 902b, 902c (e.g., on the reoxidation layers 3202a, 3202b). The first gate dielectric spacers 3402a, 3402b may be formed by depositing a layer of the material of the first gate dielectric spacers 3402a, 3402b conformally over the semiconductor substrate 102 and anisotropically etching (e.g., by RIE) the layer such that the first gate dielectric spacers 3402a, 3402b remain. The material of the first gate dielectric spacers 3402a, 3402b may be any appropriate dielectric material, such as silicon nitride, silicon oxynitride, silicon carbon nitride, the like, or a combination thereof. The layer may be deposited by CVD, PECVD, ALD, or the like. The formation of the first gate dielectric spacers 3402a, 3402b may further form residual dielectric spacers 3402c on vertical surfaces in the BJT region 104 and first transition region 106, such as vertical surfaces of the hardmask layers 3102d, 3102e, etc.

P-type lightly doped drain regions (LDDs) 3412 and n-type LDDs 3414 are formed in the semiconductor substrate 102 in the pFET region 110 and the nFET region 112, respectively. The p-type LDDs 3412 and the n-type LDDs 3414 may be formed before forming the first gate dielectric spacers 3402a, 3402b in some examples and may be formed after forming the first gate dielectric spacers 3402a, 3402b in some examples. The p-type LDDs 3412 are in the semiconductor substrate 102 on laterally opposing sides of the gate electrode 902b, and the n-type LDDs 3414 are in the semiconductor substrate 102 on laterally opposing sides of the gate electrode 902c. The p-type LDDs 3412 may be formed by masking (e.g., by a photoresist using photolithography) the BJT region 104, transition regions 106, 108, and nFET region 112 and implanting a p-type dopant into the semiconductor substrate 102 in the pFET region 110. The n-type LDDs 3414 may be formed by masking (e.g., by a photoresist using photolithography) the BJT region 104, transition regions 106, 108, and pFET region 110 and implanting an n-type dopant into the semiconductor substrate 102 in the nFET region 112. A concentration of the p-type dopant of the p-type LDDs 3412 is greater than the concentration of the n-type dopant of the n-type doped well 202, and a concentration of the n-type dopant of the n-type LDDs 3414 is greater than the concentration of the p-type dopant of the p-type doped well 208. In some examples, the p-type LDDs 3412 are doped with a p-type dopant with a concentration in a range from 1×10¹⁹ cm⁻³ to 1×10²¹ cm⁻³, and the n-type LDDs 3414 are doped with an n-type dopant with a concentration in a range from 1×10¹⁹ cm⁻³ to 1×10²¹ cm⁻³. Other doping concentrations may be implemented. After performing implantation(s) to form the p-type LDDs 3412 and the n-type LDDs 3414, an activation anneal may be performed.

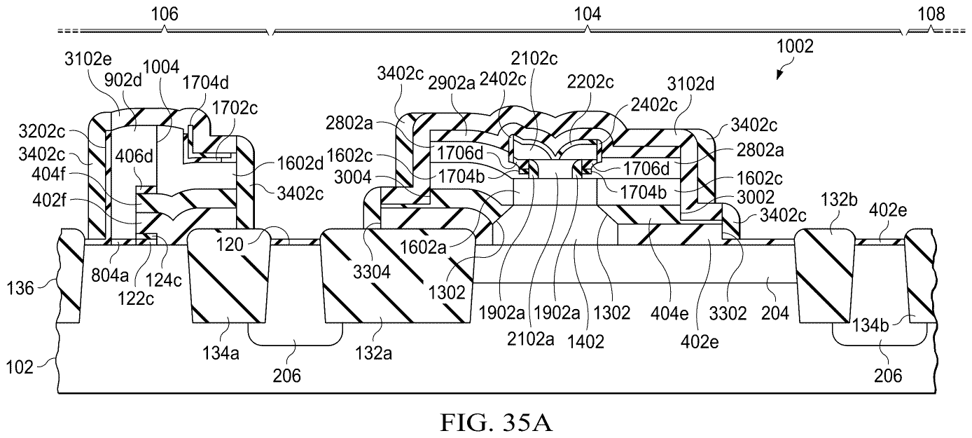

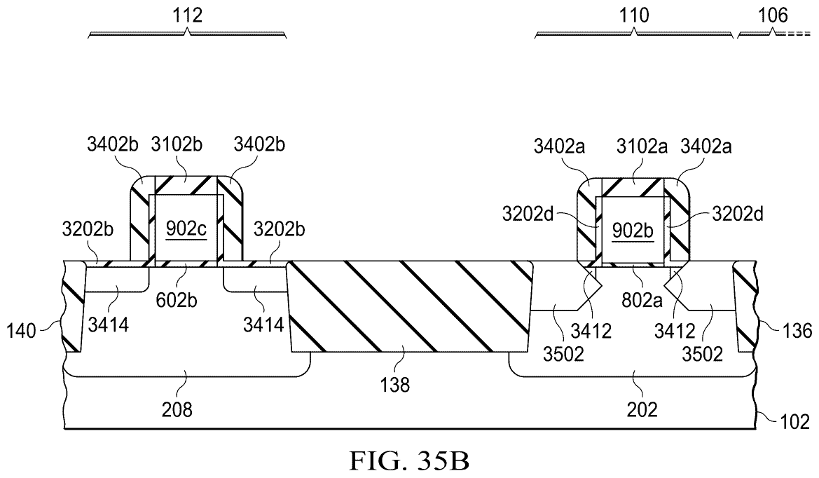

Referring to FIGS. 35A and 35B, embedded stressors 3502 are formed in the semiconductor substrate 102 in the pFET region 110. To form the embedded stressors 3502, respective recesses are formed in the semiconductor substrate 102. To form the recesses, a conformal hardmask layer (not illustrated) is formed over the semiconductor substrate 102 in the BJT region 104, transition regions 106, 108, and nFET region 112. The conformal hardmask layer may be or include silicon nitride, silicon oxynitride, the like, or a combination thereof. The conformal hardmask layer may be formed by conformally depositing and patterning the conformal hardmask layer. The conformal hardmask layer may be deposited by CVD, PECVD, ALD, or the like. The conformal hardmask layer may be patterned using photolithography and etching (e.g., RIE) processes. Then, stressor recesses are formed in the semiconductor substrate 102 in the pFET region 110. The stressor recesses are etched in the semiconductor substrate 102 where the embedded stressors are to be formed, which may pattern the reoxidation layers 3202a into reoxidation layers 3202d underlying respective first gate dielectric spacers 3402a. The stressor recesses may be formed using any appropriate etch process, which may be a wet or dry etch process. The etch process may be anisotropic and selective to (e.g., etching preferentially) a crystalline plane of the semiconductor substrate 102. The embedded stressors 3502 are then formed in the stressor recesses. The embedded stressors 3502 may be formed using a selective epitaxial growth process. The embedded stressors 3502 may be formed using MOCVD, molecular beam epitaxy (MBE), LPCVD, or another epitaxy process. In some examples, the embedded stressors 3502 are a semiconductor material that causes a compressive stress in the channel region in the semiconductor substrate 102 under the gate electrode 902b. For example, when the semiconductor substrate 102 is silicon, the embedded stressors 3502 may be or include silicon germanium.

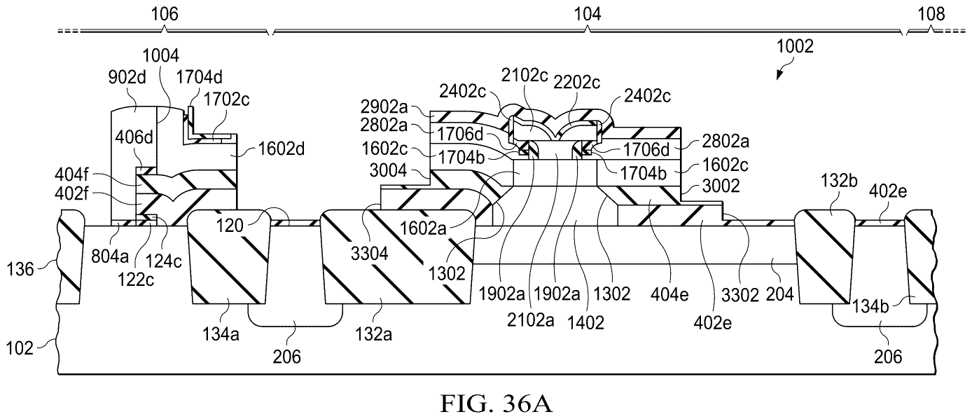

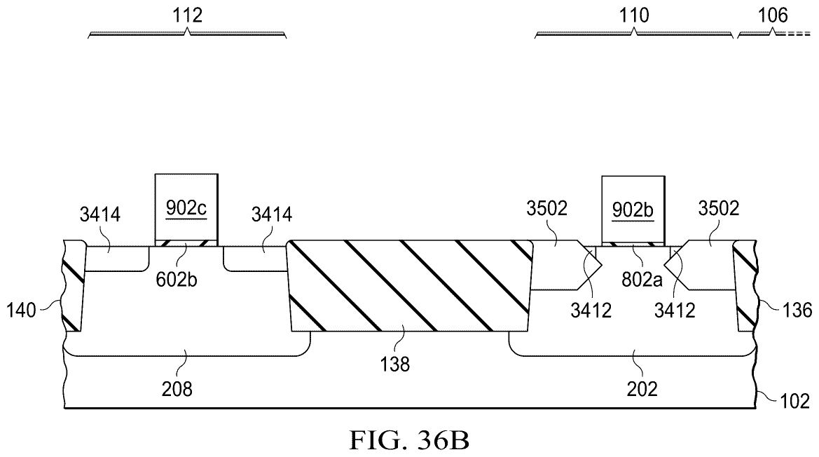

Referring to FIGS. 36A and 36B, the conformal hardmask layer for forming the embedded stressors 3502, the dielectric spacers 3402a, 3402b, 3402c, and the hardmask layers 3102a, 3102b, 3102d, 3102e are removed. These layers and spacers may be removed by an etch process selective to the material of the respective layers and spacers, which may be wet or dry etch processes and may be isotropic. As an example, when the conformal hardmask layer, the dielectric spacers 3402a, 3402b, 3402c, and the hardmask layers 3102a, 3102b, 3102d, 3102e are silicon nitride, a wet etch process including phosphoric acid may be implemented. Further, after removing the dielectric spacers 3402a, 3402b, 3402c, and the hardmask layers 3102a, 3102b, 3102d, 3102e, a cleaning process may remove, as illustrated, the reoxidation layers 3202b, 3202c, 3202d. Although not illustrated, the cleaning process may thin the first pedestal dielectric sub-layer 402e.

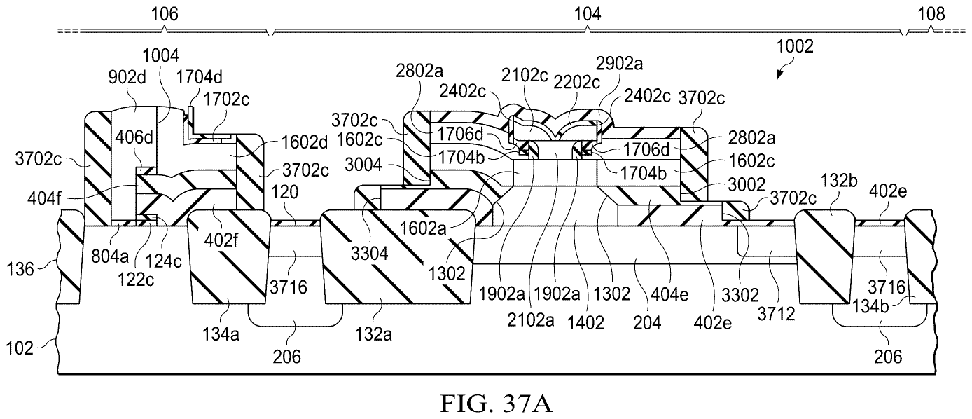

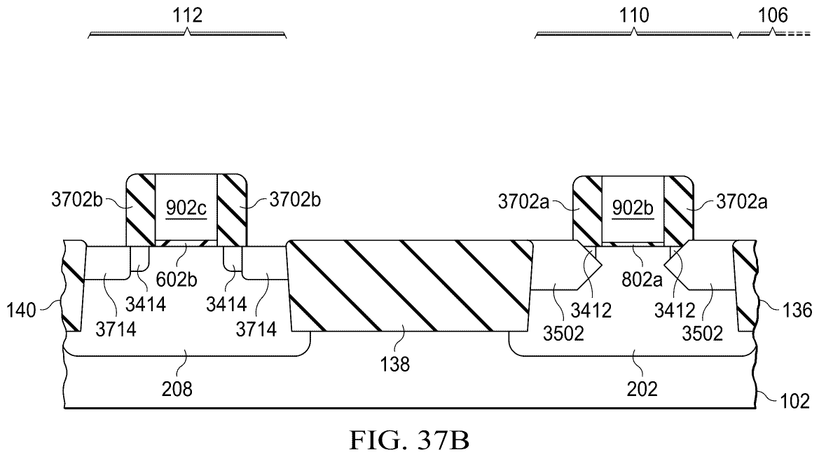

Referring to FIGS. 37A and 37B, second gate dielectric spacers 3702a, 3702b are formed along the sidewalls of the gate electrodes 902b, 902c, respectively. The second gate dielectric spacers 3702a, 3702b may be formed by depositing a layer of the material of the second gate dielectric spacers 3702a, 3702b conformally over the semiconductor substrate 102 and anisotropically etching (e.g., by RIE) the layer such that the second gate dielectric spacers 3702a, 3702b remain. The material of the second gate dielectric spacers 3702a, 3702b may be any appropriate dielectric material, such as silicon nitride, silicon oxynitride, silicon carbon nitride, the like, or a combination thereof. The layer may be deposited by CVD, PECVD, ALD, or the like. The formation of the second gate dielectric spacers 3702a, 3702b may further form residual dielectric spacers (e.g., residual dielectric spacers 3702c) on sidewalls of components in the BJT region 104 and/or the first transition region 106.

A stress memorization technique may be implemented, such as in the nFET region 112. A stressor dielectric layer is formed over the semiconductor substrate 102, gate electrode 902c, and second gate dielectric spacers 3702b in the nFET region 112. The stressor dielectric layer may be or include silicon nitride, the like, or a combination thereof. The stressor dielectric layer may be formed by conformally depositing and patterning the stressor dielectric layer. The stressor dielectric layer may be deposited by CVD, PECVD, ALD, or the like. The stressor dielectric layer may be patterned using photolithography and etching processes. An anneal process is performed with the stressor dielectric layer in the nFET region 112. The anneal process permits the lattice structure of the semiconductor substrate 102 to conform due to the stress induced by the stressor dielectric layer. After the anneal process, the stressor dielectric layer is removed. The stressor dielectric layer may be removed by an etch process selective to the material of the stressor dielectric layer, which may be a wet or dry etch process.

An n-type collector contact region 3712, n-type source/drain (NSD) regions 3714, p-type source/drain (PSD) regions, and a p-type guardring contact region 3716 are formed in the semiconductor substrate 102. The n-type collector contact region 3712 is formed in the BJT region 104 in the n-type doped sub-collector diffusion region 204 in the semiconductor substrate 102. The n-type collector contact region 3712 is laterally between the sidewall 3302 of the first pedestal dielectric sub-layer 402e and the second portion 132b of the isolation structure 132. The NSD regions 3714 are formed in the nFET region 112 in the p-type doped well 208 in the semiconductor substrate 102. The NSD regions 3714 are on opposing lateral sides of the gate electrode 902c with the n-type LDDs 3414 therebetween. The PSD regions are formed in the pFET region 110 and may be formed in the embedded stressors 3502 and/or may further extend below the embedded stressors 3502 into the n-type doped well 202 in the semiconductor substrate 102. The PSD regions are on opposing lateral sides of the gate electrode 902b with the p-type LDDs 3412 therebetween. The p-type guardring contact region 3716 is formed in the BJT region 104 in the p-type doped well 206 in the semiconductor substrate 102. The p-type guardring contact region 3716 is laterally between the isolation structures 132, 134.

An implantation is performed to form the n-type collector contact region 3712 and the NSD regions 3714. The n-type collector contact region 3712 and the NSD regions 3714 may be formed by masking (e.g., by a photoresist using photolithography) the pFET region 110 and the base layer 1602, raised base layer 2802a, and emitter layer 2102 in the BJT region 104 and implanting an n-type dopant into the semiconductor substrate 102 in the nFET region 112 and exposed portion of the BJT region 104. An implantation is performed to form the PSD regions and the p-type guardring contact region 3716. The PSD regions and the p-type guardring contact region 3716 may be formed by masking (e.g., by a photoresist using photolithography) the BJT region 104, except the p-type doped well 206, and the nFET region 112 and implanting a p-type dopant into the semiconductor substrate 102 in the pFET region 110 and in the p-type doped well 206. Simultaneously with implanting the PSD regions and the p-type guardring contact region 3716, the raised base layer 2802a and/or base layer 1602 may be implanted. An area of the raised base layer 2802a may be exposed by the mask during the implantation of the PSD regions and the p-type guardring contact region 3716 to also implant p-type dopant into the raised base layer 2802a and/or base layer 1602.

A concentration of the n-type dopant of the n-type collector contact region 3712 is greater than the concentration of the n-type dopant of the n-type doped sub-collector diffusion region 204. A concentration of the n-type dopant of the NSD regions 3714 is greater than the concentration of the n-type dopant of the n-type LDDs 3414 and the concentration of the p-type dopant of the p-type doped well 208. A concentration of the p-type dopant of the PSD regions is greater than the concentration of the p-type dopant of the p-type LDDs 3412 and the concentration of the n-type dopant of the n-type doped well 202. A concentration of the p-type guardring contact region 3716 is greater than the concentration of the p-type dopant of the p-type doped well 206. In some examples, the n-type collector contact region 3712 and the NSD regions 3714 are doped with an n-type dopant with a concentration in a range from 1×10²⁰ cm⁻³ to 1×10²¹ cm⁻³, and the PSD regions and the p-type guardring contact region 3716 are doped with a p-type dopant with a concentration in a range from 1×10²⁰ cm⁻³ to 1×10²¹ cm⁻³. Other doping concentrations may be implemented. After performing the implantations to form the n-type collector contact region 3712, NSD regions 3714, PSD regions, and p-type guardring contact region 3716, an activation anneal may be performed.

Referring to FIGS. 38A and 38B, metal-semiconductor compound 3802, 3804, 3806, 3808, 3810, 3812, 3814, 3816, 3818 are formed. The metal-semiconductor compound 3802 is on the emitter layer 2102 (e.g., the polycrystalline emitter layer 2102c and/or monocrystalline emitter layer 2102a). The metal-semiconductor compound 3804 is on the raised base layer 2802a. The metal-semiconductor compound 3806 is on the upper surface 120 of the semiconductor substrate 102 at the n-type collector contact region 3712. The metal-semiconductor compound 3808 is on the upper surface 120 of the semiconductor substrate 102 at the p-type guardring contact region 3716. The metal-semiconductor compound 3810 is on any exposed upper surface of a semiconductor material in the first transition region 106, such as the upper surface 120 of the semiconductor substrate 102 and upper surfaces of the residual gate layer 902d and residual polycrystalline base layer 1602d. The metal-semiconductor compound 3812 are on the embedded stressors 3502. The metal-semiconductor compound 3814 are on the NSD regions 3714 in the semiconductor substrate 102. The metal-semiconductor compound 3816, 3818 are on the gate electrodes 902b, 902c, respectively. The metal-semiconductor compound 3802-3818 may be a silicide (e.g., NiSix, TiSix, CoSix, PtSix), a germanicide, or the like.

To form the metal-semiconductor compound 3802-3818, any remaining dielectric material on surfaces on which the metal-semiconductor compound 3802-3818 are to be formed is removed. For example, if any of the protective dielectric layer 2902a, the emitter dielectric cap layer 2202c, and exposed portions of the first pedestal dielectric sub-layer 402e remain after forming the second gate dielectric spacers 3702a, 3702b, those layers, or exposed portions thereof, may be removed by an etch and/or cleaning process. For example, when the layers 2902a, 2202c, 402e are silicon oxide, dilute hydrofluoric (dHF) acid may be used. The portions of the first pedestal dielectric sub-layer 402e that may remain exposed on the upper surface 120 of the semiconductor substrate 102 are removed, which may further thin other exposed portions of the first pedestal dielectric sub-layer 402e into the first pedestal dielectric sub-layer 402g. More specifically, the exposed portions of the first pedestal dielectric sub-layer 402e between the sidewalls 3002, 3302 and between the sidewalls 3004, 3304 are thinned. Other layers and/or spacers may be reduced by the etch and/or cleaning process. For example, the emitter dielectric protective spacers 2402c may be reduced, such as to emitter dielectric protective spacers 2402e.

The metal-semiconductor compound 3802-3818 may then be formed by depositing a metal (e.g., Ni, Ti, Co, Pt) over the semiconductor substrate 102, such as by physical vapor deposition (PVD), CVD, or the like. The metal is reacted with a semiconductor material, such as the semiconductor material of the emitter layer 2102 (e.g., polycrystalline emitter layer 2102c and/or monocrystalline emitter layer 2102a), the semiconductor material of the raised base layer 2802a, the semiconductor material of the semiconductor substrate 102, the semiconductor material of the embedded stressors 3502, and the semiconductor material (e.g., silicon, such as polysilicon) of the gate electrodes 902b, 902c. An anneal process may be used to cause the metal to react with a semiconductor material.

After forming the metal-semiconductor compound 3802-3818, in some examples, the second gate dielectric spacers 3702a, 3702b and the residual dielectric spacers 3702c are removed. An appropriate etch process, such as a wet or dry etch and/or isotropic etch, may be implemented to remove the second gate dielectric spacers 3702a, 3702b and the residual dielectric spacers 3702c. In some examples, removal of the second gate dielectric spacers 3702a, 3702b and the residual dielectric spacers 3702c may be omitted. Further, in some examples, the second gate dielectric spacers 3702a, 3702b may remain, while the residual dielectric spacers 3702c are removed. In such cases, masking (e.g., by a photoresist) may permit removal of the residual dielectric spacers 3702c while the second gate dielectric spacers 3702a, 3702b remain.

A dielectric layer 3822 is formed over the semiconductor substrate 102, and contacts 3832, 3834, 3836, 3842, 3844 are formed through the dielectric layer 3822. The dielectric layer 3822 may include one or more dielectric sub-layers. For example, the dielectric layer 3822 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 3822 may be or include a pre-metal dielectric (PMD), an inter-layer dielectric (ILD), or the like. The dielectric layer 3822 may be deposited using CVD, PECVD, ALD, or the like. The dielectric layer 3822 may be planarized, such as by a CMP.

The contacts 3832, 3834, 3836, 3842, 3844 extend through the dielectric layer 3822 and contact respective metal-semiconductor compound 3802, 3804, 3806, 3812, 3814. The contacts 3832, 3834, 3836, 3842, 3844 may each include one or more barrier and/or adhesion layers (e.g., titanium nitride (TiN), tantalum nitride (TaN), the like, or a combination thereof) conformally in a respective opening through the dielectric layer 3822, and a fill metal (e.g., tungsten (W), copper (Cu), aluminum (Al), the like, or a combination thereof) over and/or on the barrier and/or adhesion layer(s).

To form the contacts 3832, 3834, 3836, 3842, 3844, respective openings may be formed through the dielectric layer 3822 to the metal-semiconductor compound 3802, 3804, 3806, 3812, 3814 using appropriate photolithography and etching processes. A metal(s) of the contacts 3832, 3834, 3836, 3842, 3844 are deposited in the openings through the dielectric layer 3822. The metal(s) may be deposited using an appropriate deposition process(es), such as CVD, PVD, or the like. Any excess metal(s) may be removed, such as by a CMP and/or by patterning using photolithography and etch processes.

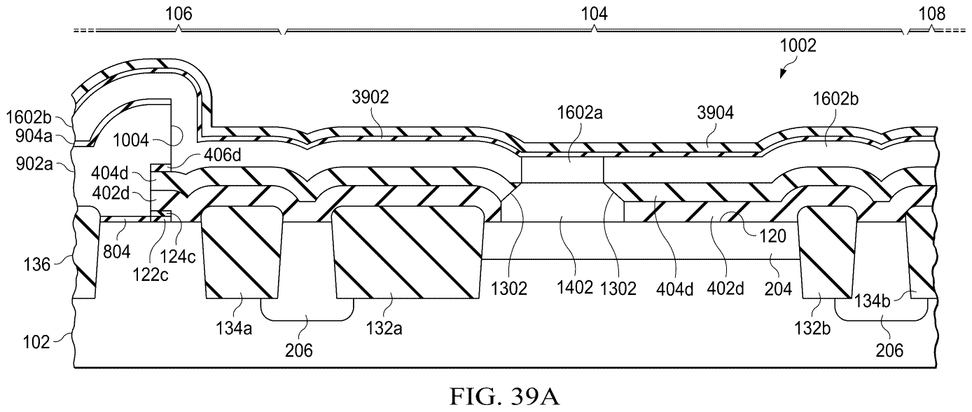

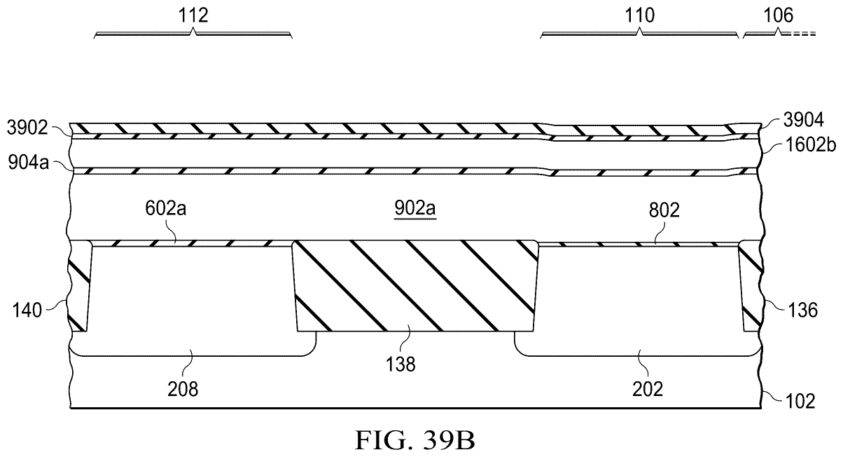

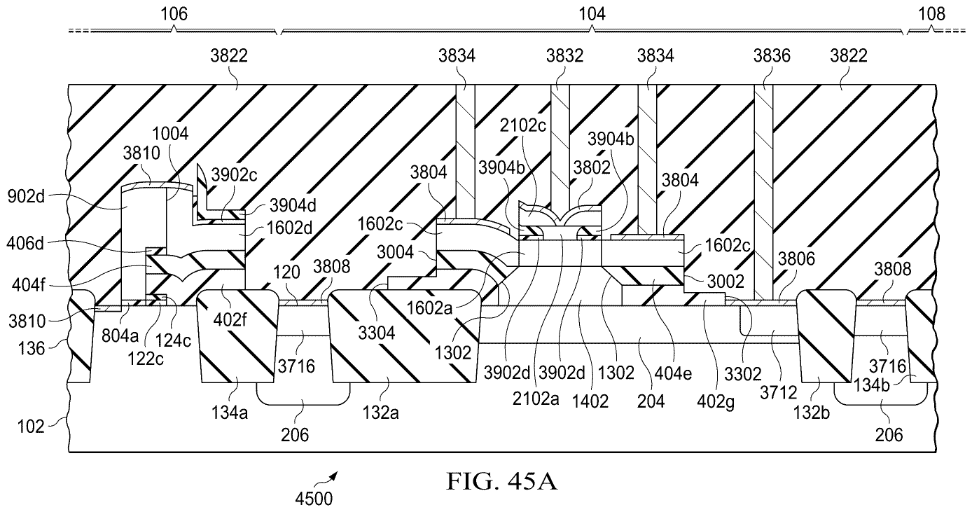

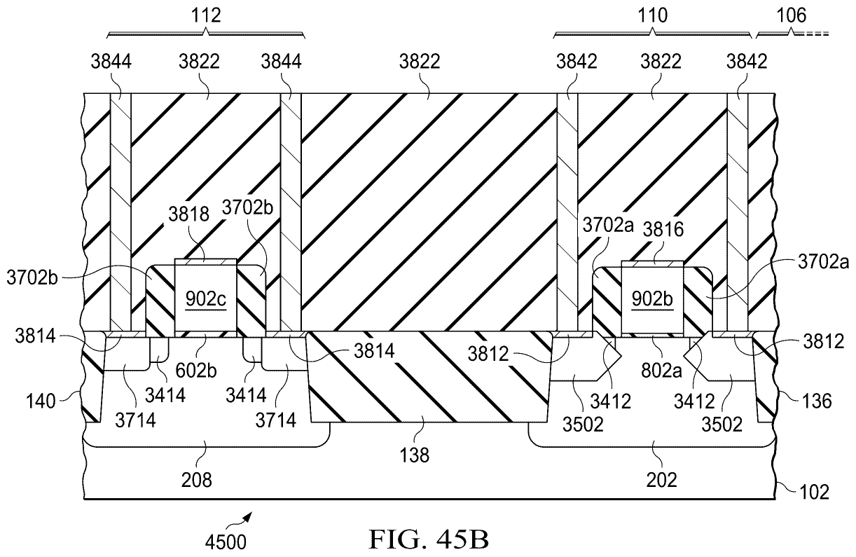

FIGS. 39A and 39B through FIGS. 45A and 45B are respective cross-sectional views of a semiconductor device in intermediate stages of manufacturing according to some examples. The method illustrated in these figures forms the semiconductor device 4500 of FIGS. 45A and 45B. Processing proceeds as described above with respect to FIGS. 1A and 1B through FIGS. 16A and 16B.

With reference to FIGS. 39A and 39B, a first dielectric spacer layer 3902 is formed conformally over the base layer 1602, and a second dielectric spacer layer 3904 is formed conformally over the first dielectric spacer layer 3902. In some examples, the second dielectric spacer layer 3904 is a dielectric material different from the dielectric material of the first dielectric spacer layer 3902. In some examples, the first dielectric spacer layer 3902 is silicon oxide (e.g., a TEOS oxide), and the second dielectric spacer layer 3904 is silicon nitride. The dielectric spacer layers 3902, 3904 may be deposited by CVD. Other dielectric materials and/or other deposition processes may be used in other examples.

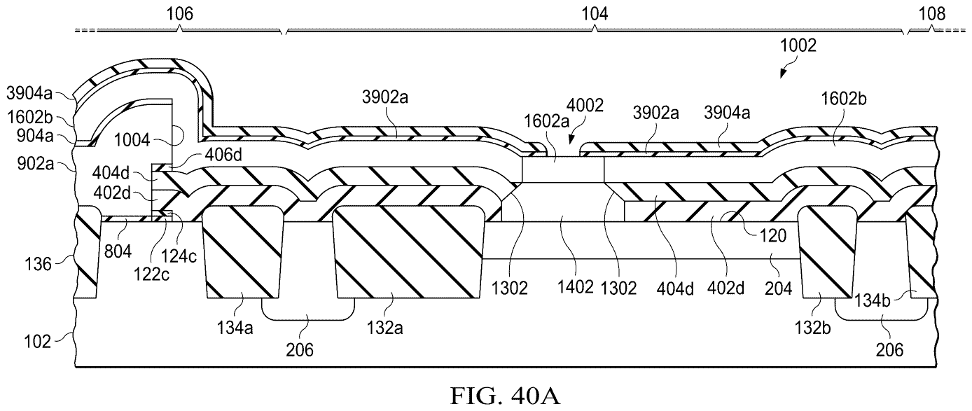

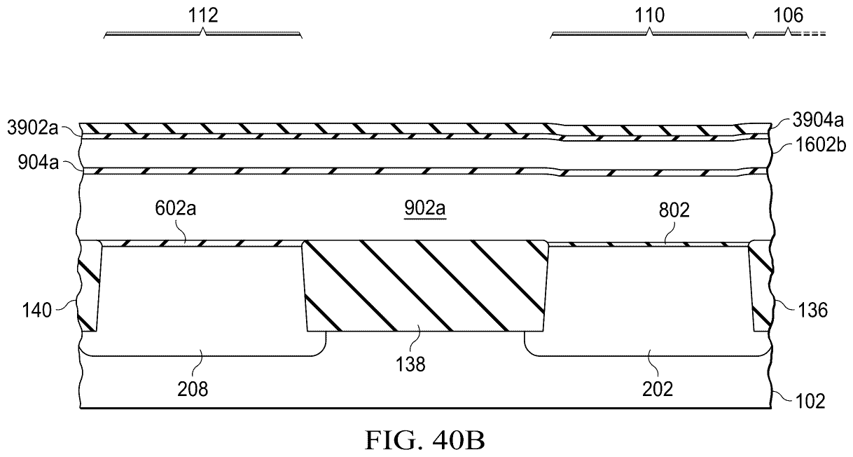

Referring to FIGS. 40A and 40B, the dielectric spacer layers 3902, 3904 are etched to form an emitter opening 4002 in the BJT region 104 through the first dielectric spacer layer 3902a and the second dielectric spacer layer 3904a. The monocrystalline base layer 1602a (of the base layer 1602) is exposed through the emitter opening 4002. The dielectric spacer layers 3902, 3904 may be patterned using appropriate photolithography and etch (e.g., RIE) processes.

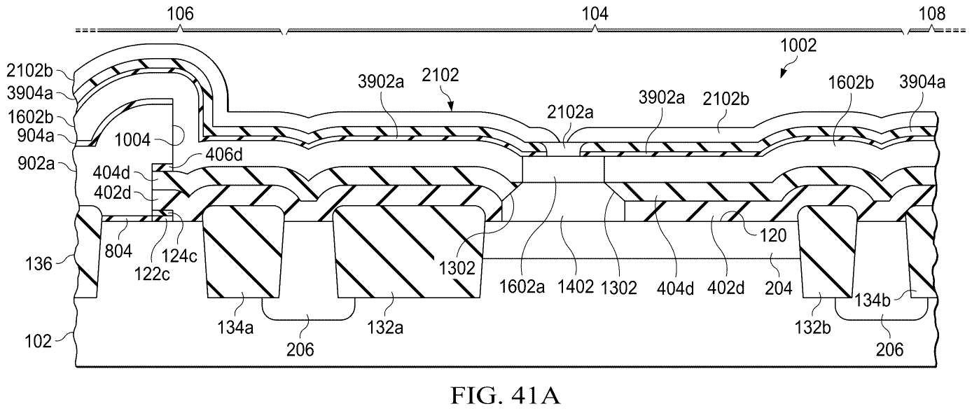

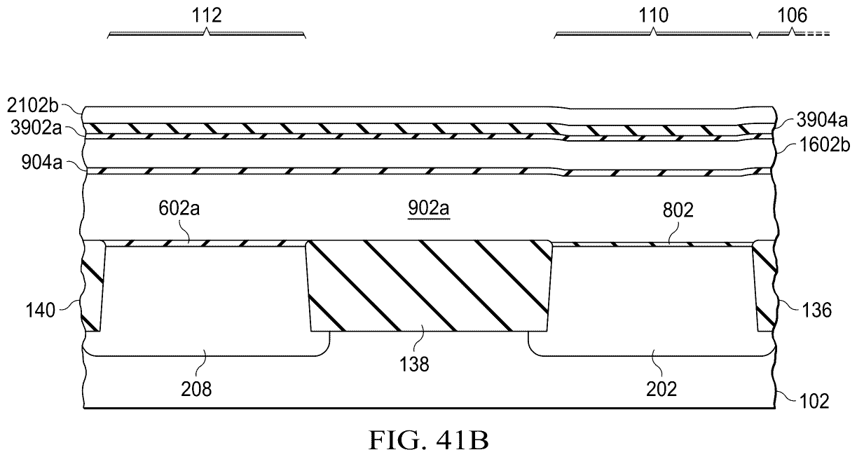

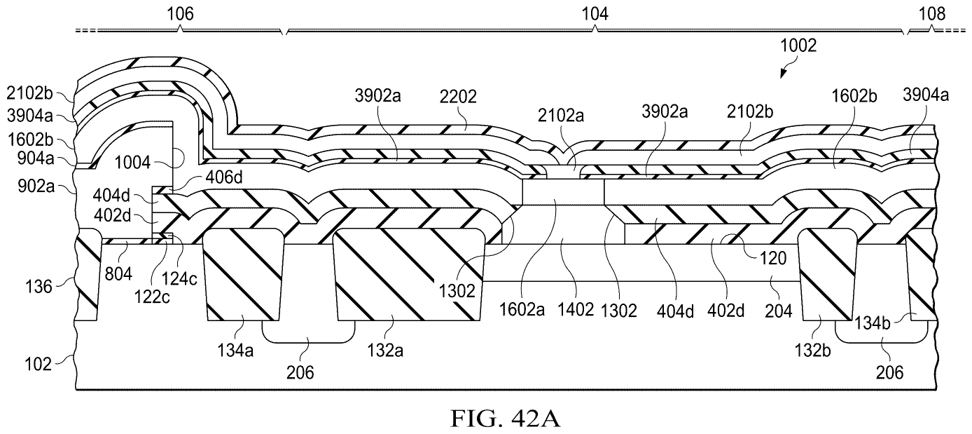

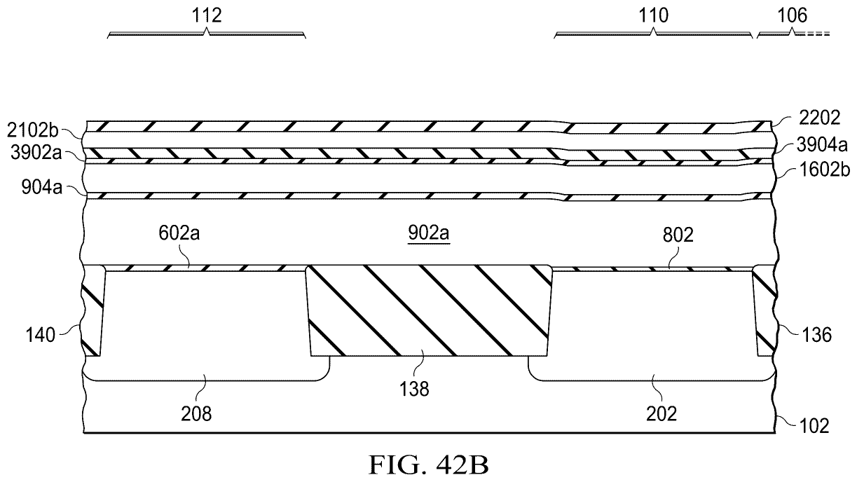

Referring to FIGS. 41A and 41B, an emitter layer 2102 is formed over the base layer 1602 (e.g., on the monocrystalline base layer 1602a) like described with respect to FIGS. 21A and 21B. The emitter layer 2102 may be epitaxially grown on the base layer 1602 (e.g., the monocrystalline base layer 1602a) exposed through the emitter opening 4002 and on the second dielectric spacer layer 3904a. Referring to FIGS. 42A and 42B, an emitter dielectric cap layer 2202 is conformally formed over the emitter layer 2102 like described with respect to FIGS. 22A and 22B.

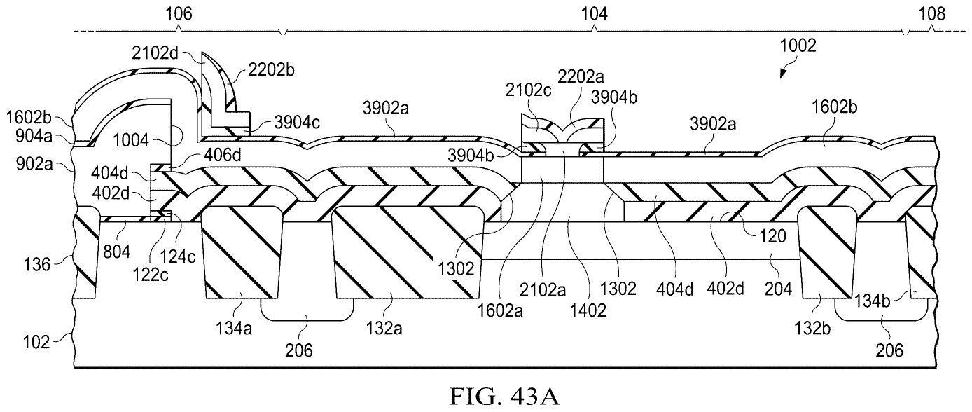

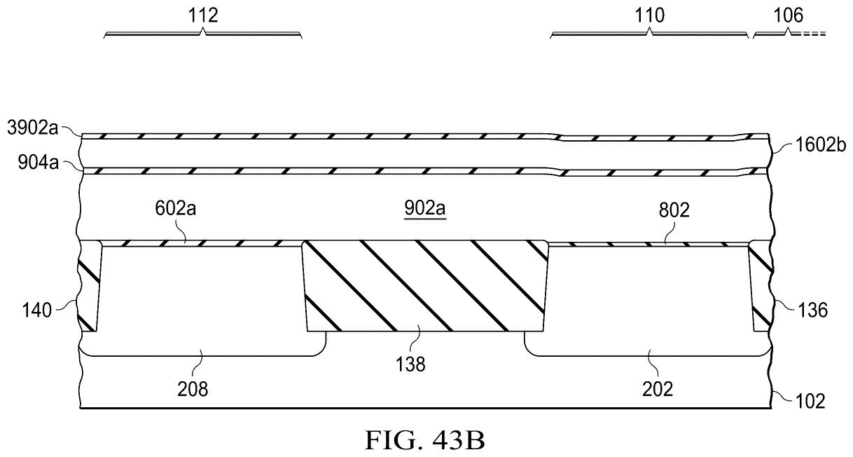

Referring to FIGS. 43A and 43B, the emitter dielectric cap layer 2202, the polycrystalline emitter layer 2102b, and the second dielectric spacer layer 3904a are patterned to form the emitter dielectric cap layer 2202a, polycrystalline emitter layer 2102c, and second dielectric spacer layer 3904b. The layers 2202, 2102b, 3904a may be patterned using appropriate photolithography and etch (e.g., RIE) processes. Residual emitter dielectric cap layer 2202b, residual polycrystalline emitter layer 2102d, and residual second dielectric spacer layer 3904c may remain, as illustrated, in the first transition region 106.

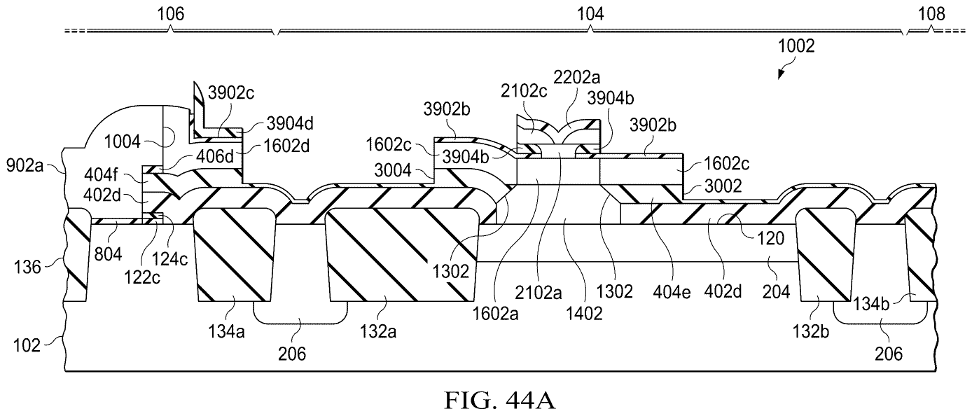

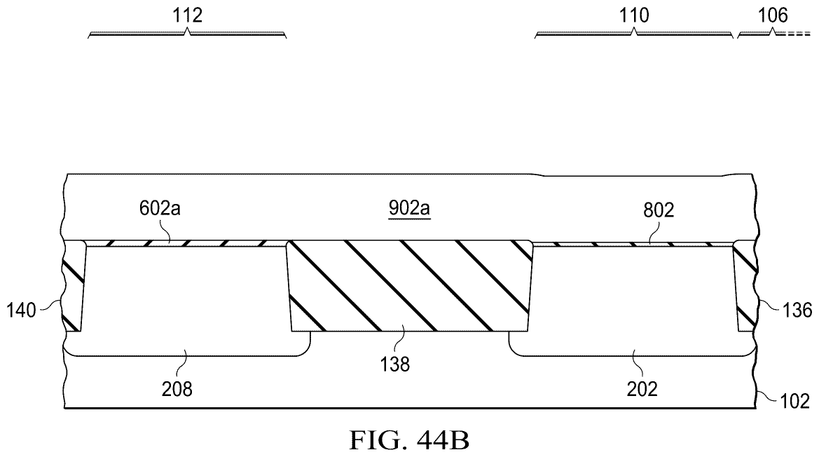

Referring to FIGS. 44A and 44B, the first dielectric spacer layer 3902a, the base layer 1602 (e.g., the polycrystalline base layer 1602b), and the second pedestal dielectric sub-layer 404d are patterned in the BJT region 104. The first dielectric spacer layer 3902a, the polycrystalline base layer 1602b, and the second pedestal dielectric sub-layer 404d are patterned to remain as the first dielectric spacer layer 3902b, the polycrystalline base layer 1602c, and the second pedestal dielectric sub-layer 404e, respectively, in the BJT region 104. Patterning the second pedestal dielectric sub-layer 404d results in sidewalls 3002, 3004 of the second pedestal dielectric sub-layer 404e that align with respective sidewalls of the polycrystalline base layer 1602c. The layers 3902a, 1602b, 404d may be patterned using appropriate photolithography and etch (e.g., RIE) processes.

As illustrated, etching the first dielectric spacer layer 3902a and the polycrystalline base layer 1602b may remove the residual emitter dielectric cap layer 2202b, the protective dielectric layer 904a, and the residual polycrystalline emitter layer 2102d from the first transition region 106. Thereafter, etching the second pedestal dielectric sub-layer 404d may remove any remaining residual emitter dielectric cap layer 2202b and protective dielectric layer 904a in the first transition region 106. Etching the second pedestal dielectric sub-layer 404d results in a residual second pedestal dielectric sub-layer 404f remaining in the first transition region 106. A residual polycrystalline base layer 1602d remains in the first transition region 106 along the sidewall 1004 of the gate layer 902a and a sidewall of the residual protective dielectric layer 406d (that aligns with the sidewall 1004) and over the residual second pedestal dielectric sub-layer 404f, and a residual first dielectric spacer layer 3902c remains on the residual polycrystalline base layer 1602d. The various etches may also reduce the residual second dielectric spacer layer 3904c such that residual second dielectric spacer layer 3904d remains over the residual polycrystalline base layer 1602d and first dielectric spacer layer 3902c. Further, the various etches remove the first dielectric spacer layer 3902a, the polycrystalline base layer 1602b, and the protective dielectric layer 904a from the pFET region 110 and the nFET region 112.

Thereafter, processing continues as described with respect to FIGS. 31A and 31B through FIGS. 38A and 38B above. FIGS. 45A and 45B correspond with processing through the processing described with respect to FIGS. 38A and 38B. With respect to the formation of metal-semiconductor compound described above with respect to FIGS. 38A and 38B, metal-semiconductor compound 3804 is on the base layer 1602 (e.g., the polycrystalline base layer 1602c) in FIGS. 45A and 45B. The deposited metal is reacted with the semiconductor material of the base layer 1602 (e.g., the polycrystalline base layer 1602c). In processing to form the metal-semiconductor compound, the first dielectric spacer layer 3902b not underlying the second dielectric spacer layer 3904b may be removed, such as by a cleaning or etch process, which may cause a first dielectric spacer layer 3902d to remain under the second dielectric spacer layer 3904b.

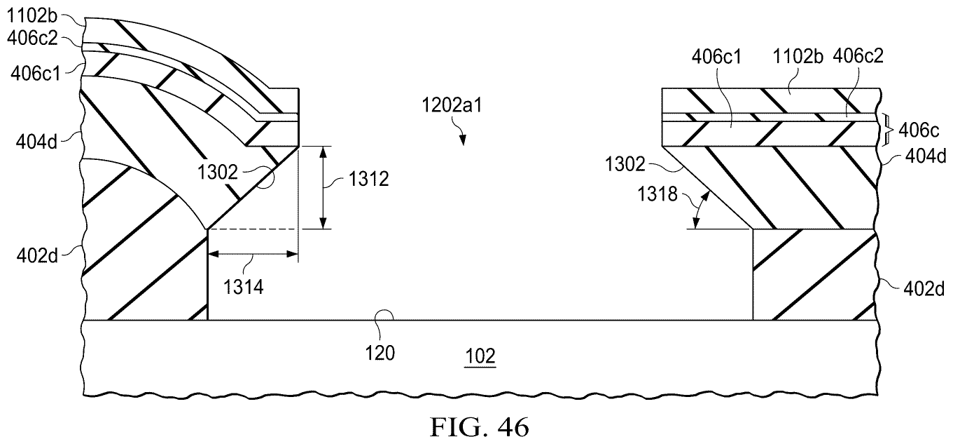

FIGS. 46, 47, and 48 illustrate respective profiles of collector openings 1202a1, 1202a2, 1202a3 through the pedestal dielectric stack and formed in FIGS. 13A and 13B according to some examples. FIGS. 46, 47, and 48 show the first and second pedestal dielectric sub-layers 402d, 404d over the upper surface 120 of the semiconductor substrate 102 and through which the respective collector opening 1202a1, 1202a2, 1202a3 formed. The protective dielectric layer 406c is over the second pedestal dielectric sub-layer 404d, and the hardmask layer 1102b is over the protective dielectric layer 406c. The protective dielectric layer 406c includes a lower portion 406c1 and an upper portion 406c2 over the lower portion 406c1. The upper portion 406c2 may be oxidized as described above. For example, the upper portion 406c2 may be an oxide, and the lower portion 406c1 may be or include a nitride (e.g., silicon nitride). The residual protective dielectric layer 406d in the first transition region 106 may also include the lower portion 406c1 and upper portion 406c2.

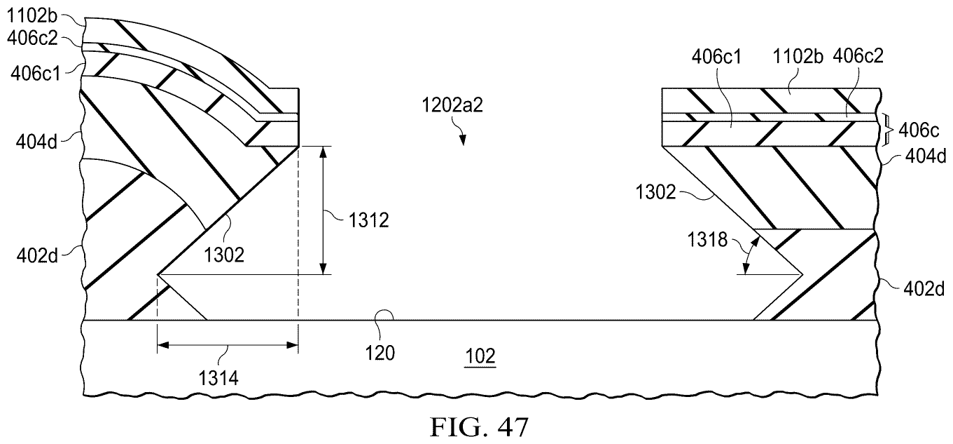

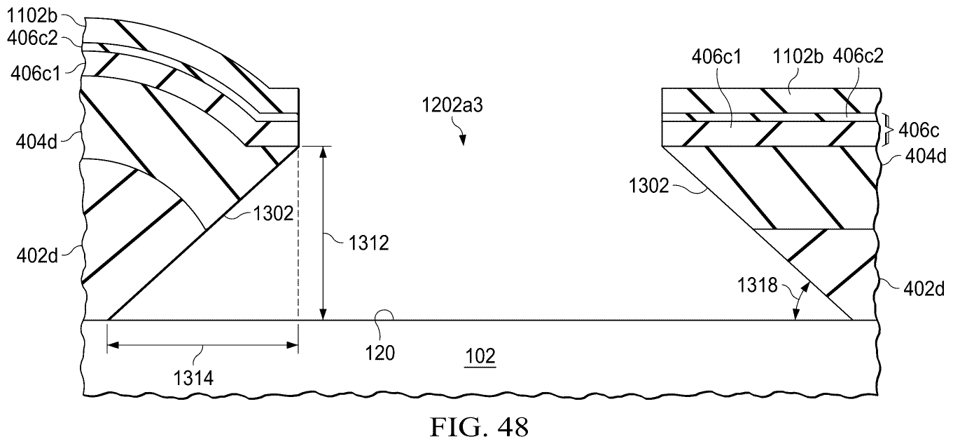

In FIG. 46, the first pedestal dielectric sub-layer 402d is etched laterally uniformly such that a sidewall portion (in the first pedestal dielectric sub-layer 402d) of the retrograde sidewall 1302 is vertical. In FIG. 47, the first pedestal dielectric sub-layer 402d is etched laterally at a greater rate in a mid-section relative to lower and upper sections such that a sidewall portion (in the first pedestal dielectric sub-layer 402d) of the retrograde sidewall 1302 is concave. In FIG. 48, the first pedestal dielectric sub-layer 402d is etched laterally at a greater rate at an interface between the semiconductor substrate 102 and the first pedestal dielectric sub-layer 402d such that a sidewall portion in the first pedestal dielectric sub-layer 402d is slanted. In FIGS. 46, 47, and 48, since the first pedestal dielectric sub-layer 402d is etched faster (because of the greater lateral etching rate) and undercuts the second pedestal dielectric sub-layer 404d, a lower portion of the second pedestal dielectric sub-layer 404d may become exposed to the etchant. The exposed lower portion of the second pedestal dielectric sub-layer 404d permits the etchant to etch the second pedestal dielectric sub-layer 404d with a vertical component (e.g., upward away from the semiconductor substrate 102) at that exposed portion. Additionally, the second pedestal dielectric sub-layer 404d is etched laterally at the exposed sidewalls. Etching the second pedestal dielectric sub-layer 404d with such lateral and vertical components may form slanted sidewall portions. The different profiles of the collector openings 1202a1, 1202a2, 1202a3 may result from different properties of the first and/or second pedestal dielectric sub-layers 402d, 404d, such as varying surface bond energies. The retrograde sidewalls 1302 have the vertical dimension 1312, lateral dimension 1314, and angle 1318 as described previously. Different profiles of the collector opening may be formed in different examples.

FIGS. 38A and 38B illustrate a semiconductor device 3800, and FIGS. 45A and 45B illustrate a semiconductor device 4500. Each illustrated semiconductor device 3800, 4500 includes a BJT in the BJT region 104. The BJT includes the collector layer 1402, base layer 1602 (e.g., monocrystalline base layer 1602a and polycrystalline base layer 1602c), and emitter layer 2102 (e.g., monocrystalline emitter layer 2102a and polycrystalline emitter layer 2102b). The BJT of the semiconductor device 3800 of FIGS. 38A and 38B also includes a raised base layer 2802a on the base layer 1602 (e.g., on the polycrystalline base layer 1602c).

The collector layer 1402 is over (e.g., on) the upper surface 120 of the semiconductor substrate 102 and is through an opening in a pedestal dielectric stack that is over the upper surface of the semiconductor substrate 102. The pedestal dielectric stack (e.g., pedestal oxide stack) includes the first pedestal dielectric sub-layer 402g over the upper surface 120 and the second pedestal dielectric sub-layer 404e over the first pedestal dielectric sub-layer 402g. The opening through the pedestal dielectric stack in which the collector layer 1402 is formed is defined, at least in part, by retrograde sidewalls 1302. The collector layer 1402 is on the n-type doped sub-collector diffusion region 204 in the semiconductor substrate 102. The base layer 1602 (e.g., the monocrystalline base layer 1602a) is over (e.g., on) the collector layer 1402, and the base layer 1602 (e.g., the polycrystalline base layer 1602c) is over (e.g., on) an upper surface of the second pedestal dielectric sub-layer 404e.

The pedestal dielectric stack is in the BJT region 104 and underlies the base layer 1602. The portion of the pedestal dielectric stack directly underlying the base layer 1602 (e.g., including the first and second pedestal dielectric sub-layers 402g, 404e) has a first thickness. The pedestal dielectric stack (e.g. the second pedestal dielectric sub-layer 404e) has sidewalls 3002, 3004 that align with respective sidewalls of the base layer 1602. The pedestal dielectric stack has the first thickness laterally between the sidewalls 3002, 3004, which first thickness may be in a range from 200 Å to 400 Å, in some examples. The first pedestal dielectric sub-layer 402g may have a thickness that is about half of the first thickness between the sidewalls 3002, 3004, and the second pedestal dielectric sub-layer 404e may have a thickness that is about half of the first thickness between the sidewalls 3002, 3004. For example, each of the first and second pedestal dielectric sub-layers 402g, 404e may be in a range from 100 Å to 200 Å.

The pedestal dielectric stack (e.g., the first pedestal dielectric sub-layer 402g) extends laterally from the base layer 1602 (e.g., the polycrystalline base layer 1602c). For example, the pedestal dielectric stack extends over the upper surface 120 of the semiconductor substrate 102 over the n-type doped sub-collector diffusion region 204 and laterally away from a corresponding sidewall of the polycrystalline base layer 1602c (and the aligned sidewall 3002 of the pedestal dielectric stack) to the sidewall 3302 proximate the n-type collector contact region 3712. Additionally, the pedestal dielectric stack (e.g., the first pedestal dielectric sub-layer 402g) extends over the first portion 132a of the isolation structure 132 laterally away from a corresponding sidewall of the polycrystalline base layer 1602c (and the aligned sidewall 3004 of the pedestal dielectric stack) to the sidewall 3304 over the first portion 132a of the isolation structure 132. The pedestal dielectric stack has a second thickness laterally between the sidewalls 3002, 3302, and the pedestal dielectric stack has a third thickness laterally between the sidewalls 3004, 3304. The second and third thicknesses of the pedestal dielectric stack are each less than the first thickness of the pedestal dielectric stack.

The emitter layer 2102 (e.g., the monocrystalline emitter layer 2102a) is over (e.g., on) the base layer 1602 (e.g., the monocrystalline base layer 1602a) and is through an opening defined by a spacer structure, and the emitter layer 2102 (e.g., the polycrystalline emitter layer 2102c) is over (e.g., on) the spacer structure. In the semiconductor device 3800 of FIGS. 38A and 38B, the spacer structure includes the second dielectric spacer layer 1704b, the third dielectric spacer layer 1706d, and emitter dielectric spacer 1902a. In the semiconductor device 4500 of FIGS. 45A and 45B, the spacer structure includes the first dielectric spacer layer 3902d and the second dielectric spacer layer 3904b.

The metal-semiconductor compound 3802 is on the emitter layer 2102 (e.g., the polycrystalline emitter layer 2102c and/or monocrystalline emitter layer 2102a). The metal-semiconductor compound 3806 is on the upper surface 120 of the semiconductor substrate 102 on the n-type collector contact region 3712. In the semiconductor device 3800 of FIGS. 38A and 38B, the metal-semiconductor compound 3804 is on the raised base layer 2802a. In the semiconductor device 4500 of FIGS. 45A and 45B, the metal-semiconductor compound 3804 is on the base layer 1602 (e.g., the polycrystalline base layer 1602c).

In some examples, the BJT may be a heterojunction BJT. As indicated previously, in some examples, the collector layer 1402 and the emitter layer 2102 may be silicon, and the base layer 1602 may include silicon germanium. Hence, in some examples, the base layer 1602 may include a semiconductor material dissimilar from respective semiconductor materials of the collector layer 1402 and emitter layer 2102. The dissimilar semiconductor materials may form one or more heterojunctions in the BJT, and the BJT may therefore be a heterojunction BJT.

Each illustrated semiconductor device 3800, 4500 includes a pFET in the pFET region 110 and an nFET in the nFET region 112. The pFET region 110 and nFET region 112 are in a CFET region. The pFET includes the gate electrode 902b, gate oxide layer 802a, embedded stressors 3502, PSD regions, p-type LDDs 3412, and a channel region in the semiconductor substrate 102 underlying the gate electrode 902b. The gate electrode 902b is over (e.g., on) the gate oxide layer 802a, and the gate oxide layer 802a is over (e.g., on) the upper surface 120 of the semiconductor substrate 102. The p-type LDDs 3412 are on laterally opposing sides of the gate electrode 902b and in the semiconductor substrate 102. The channel region is laterally between the p-type LDDs 3412. The embedded stressors 3502 and PSD regions are on laterally opposing sides of the gate electrode 902b, with the p-type LDDs 3412 and channel region therebetween. Similarly, the nFET includes the gate electrode 902c, gate oxide layer 602b, NSD regions 3714, n-type LDDs 3414, and a channel region in the semiconductor substrate 102 underlying the gate electrode 902c. The gate electrode 902c is over (e.g., on) the gate oxide layer 602b, and the gate oxide layer 602b is over (e.g., on) the upper surface 120 of the semiconductor substrate 102. The n-type LDDs 3414 are on laterally opposing sides of the gate electrode 902c and in the semiconductor substrate 102. The channel region is laterally between the n-type LDDs 3414. The NSD regions 3714 are on laterally opposing sides of the gate electrode 902c, with the n-type LDDs 3414 and channel region therebetween. The pFET and nFET may be complementary devices (e.g., complementary metal-oxide-semiconductor (CMOS) devices). In some examples, the pFET may be a p-type metal-oxide-semiconductor (PMOS) transistor, and the nFET may be an n-type metal-oxide-semiconductor (NMOS) transistor.

The first transition region 106 is between the BJT region 104 and the CFET region (e.g., with the CFET region having a boundary of the pFET region 110 in the illustrated examples). The second transition region 108 extends from a boundary of the BJT region 104 (e.g., opposite from the first transition region 106). A composite structure may remain in the first transition region 106 and/or second transition region 108. The composite structure may include respective residuals of various layers or materials formed during semiconductor processing and/or may be processing artifact(s). As illustrated in FIGS. 38A and 45A, the composite structure includes the residual gate layer 902d and the residual polycrystalline base layer 1602d on the sidewall 1004 of the residual gate layer 902d. The composite structure also includes a residual pedestal dielectric stack and a residual protective dielectric layer 406d over the residual pedestal dielectric stack. The residual pedestal dielectric stack includes the residual first and second pedestal dielectric sub-layers 402f, 404f. The residual gate layer 902b is along aligned respective sidewalls of the residual first and second pedestal dielectric sub-layers 402f, 404f and the residual protective dielectric layer 406d and is over the residual protective dielectric layer 406d. The residual protective dielectric layer 406d has a sidewall that aligns with the sidewall 1004 of the residual gate layer 902d. The residual polycrystalline base layer 1602d is over the residual second pedestal dielectric sub-layer 404f and along the sidewall of the residual protective dielectric layer 406d (that aligns with the sidewall 1004 of the residual gate layer 902d). The residual protective dielectric layer 406d may include a lower portion that is or includes a nitride and may include an upper portion (over the upper portion) that is oxidized like described above. Further, in some examples, the composite structure may include a residual polycrystalline emitter spacer. The composite structure may include one or more other residual dielectric spacers. In other examples, a composite structure including such residual spacers or residual layers may not be formed in the first transition region 106 and/or second transition region 108.

Although various examples have been described in detail, it should be understood that various changes, substitutions, and alterations can be made therein without departing from the scope defined by the appended claims.

What is claimed is:

1. A semiconductor device, comprising:
a semiconductor substrate including a bipolar junction transistor (BJT) region, a complementary field effect transistor (CFET) region, and a transition region between the BJT region and the CFET region;
a pedestal dielectric stack on the semiconductor substrate in the BJT region;
a BJT on the semiconductor substrate in the BJT region, at least a portion of the BJT being in an opening through the pedestal dielectric stack, the opening being defined at least in part by a retrograde sidewall;
a field effect transistor (FET) on the semiconductor substrate in the CFET region; and
a composite structure on the semiconductor substrate in the transition region, the composite structure comprising:
a residual dielectric stack over the semiconductor substrate, the residual dielectric stack having a material that is the same as the pedestal dielectric stack;
a dielectric layer over the residual dielectric stack, the dielectric layer including a nitride; and
a first material that is the same as a gate electrode of the FET, the first material being over the dielectric layer.

2. The semiconductor device of claim 1, wherein:
the BJT comprises:
a collector layer on the semiconductor substrate and in the opening;
a base layer on the collector layer; and
an emitter layer on the base layer; and
the composite structure further comprises a second material that is the same as the base layer, the second material being along aligned respective sidewalls of the dielectric layer and the first material.

3. The semiconductor device of claim 2, wherein the second material is over the residual dielectric stack.

4. The semiconductor device of claim 1, wherein the first material is along aligned respective sidewalls of the residual dielectric stack and the dielectric layer.

5. The semiconductor device of claim 1, wherein the dielectric layer includes a lower portion and an upper portion, the upper portion being over the lower portion, the lower portion including the nitride, the upper portion being oxidized.

6. The semiconductor device of claim 1, wherein the retrograde sidewall includes a sidewall portion having an upper overhang portion and a lower retrograde portion, a first dimension orthogonal to an upper surface of the semiconductor substrate being between the upper overhang portion and the lower retrograde portion, a second dimension parallel to the upper surface of the semiconductor substrate being between the upper overhang portion and the lower retrograde portion, a ratio of the first dimension to the second dimension being equal to or less than 1.376.

7. A method, comprising:
forming a pedestal dielectric stack over a semiconductor substrate in a bipolar junction transistor (BJT) region, the pedestal dielectric stack including a first dielectric sub-layer and a second dielectric sub-layer over the first dielectric sub-layer, the first dielectric sub-layer having a lateral etch rate to an etchant that is greater than a lateral etch rate to the etchant of the second dielectric sub-layer;
forming a protective dielectric layer over the pedestal dielectric stack, the protective dielectric layer including a nitride;
after forming the protective dielectric layer, forming a gate oxide layer of a field effect transistor (FET) on the semiconductor substrate in a complementary field effect transistor (CFET) region;
forming a first opening through the protective dielectric layer and the pedestal dielectric stack, forming the first opening including using an etch process that includes using the etchant; and
forming a BJT on the semiconductor substrate in the BJT region, at least a portion of the BJT being in the first opening.

8. The method of claim 7, further comprising:
forming a gate layer over the gate oxide layer and the protective dielectric layer; and
forming a second opening through the gate layer to the protective dielectric layer in the BJT region, the first opening being formed through the second opening.

9. The method of claim 8, further comprising:
patterning the gate layer into a gate electrode of the FET; and
patterning the pedestal dielectric stack,
wherein:
forming the BJT includes:
forming a collector layer on the semiconductor substrate and in the first opening; and
forming a base layer on the collector layer and the pedestal dielectric stack in the second opening, over the gate layer, and along a sidewall of the gate layer defining at least part of the second opening; and
after patterning the gate layer and patterning the pedestal dielectric stack, a composite structure remains in a region of the semiconductor substrate laterally between the BJT region and the CFET region, the composite structure comprising:
a residual portion of the pedestal dielectric stack;
a residual portion of the protective dielectric layer over the residual portion of the pedestal dielectric stack;
a residual portion of the gate layer over the residual portion of the protective dielectric layer, the residual portion of the gate layer having the sidewall; and
a residual portion of the base layer over the residual portion of the pedestal dielectric stack and along the sidewall.

10. The method of claim 7, wherein forming the gate oxide layer includes performing an oxidation process.

11. The method of claim 7, wherein forming the BJT includes epitaxially growing a collector layer on the semiconductor substrate and in the first opening.

12. The method of claim 7, wherein:
the first dielectric sub-layer includes silicon oxide having a first density; and
the second dielectric sub-layer includes silicon oxide having a second density greater than the first density.

13. The method of claim 7, wherein forming the pedestal dielectric stack includes:
depositing the first dielectric sub-layer using plasma enhanced atomic layer deposition (PEALD) or low pressure chemical vapor deposition (LPCVD), the first dielectric sub-layer including silicon oxide; and
depositing the second dielectric sub-layer using plasma enhanced chemical vapor deposition (PECVD), the second dielectric sub-layer including silicon oxide.

14. The method of claim 7, wherein the first opening is defined at least in part by a retrograde sidewall.

15. A method, comprising:
forming a pedestal oxide stack over a semiconductor substrate in a bipolar junction transistor (BJT) region, the pedestal oxide stack including a first oxide sub-layer and a second oxide sub-layer over the first oxide sub-layer, the first oxide sub-layer having a first density, the second oxide sub-layer having a second density greater than the first density;
forming a protective dielectric layer over the pedestal oxide stack, the protective dielectric layer including a nitride;
forming a gate oxide layer of a field effect transistor (FET) on the semiconductor substrate in a complementary field effect transistor (CFET) region while the protective dielectric layer is over the pedestal oxide stack, forming the gate oxide layer including performing an oxidation process;
forming a first opening through the protective dielectric layer and the pedestal oxide stack, the first opening being defined at least in part by a retrograde sidewall; and
forming a BJT on the semiconductor substrate in the BJT region, at least a portion of the BJT being in the first opening.

16. The method of claim 15, further comprising:
forming a gate layer over the gate oxide layer and the protective dielectric layer; and
forming a second opening through the gate layer to the protective dielectric layer in the BJT region, the first opening being formed through the second opening.

17. The method of claim 16, further comprising:
patterning the gate layer into a gate electrode of the FET; and
patterning the pedestal oxide stack,
wherein:
forming the BJT includes:
forming a collector layer on the semiconductor substrate and in the first opening; and
forming a base layer on the collector layer and the pedestal oxide stack in the second opening, over the gate layer, and along a sidewall of the gate layer defining at least part of the second opening; and
after patterning the gate layer and patterning the pedestal oxide stack, a composite structure remains in a region of the semiconductor substrate laterally between the BJT region and the CFET region, the composite structure comprising:
a residual portion of the pedestal oxide stack;
a residual portion of the protective dielectric layer over the residual portion of the pedestal oxide stack;
a residual portion of the gate layer over the residual portion of the protective dielectric layer, the residual portion of the gate layer having the sidewall; and
a residual portion of the base layer over the residual portion of the pedestal oxide stack and along the sidewall.

18. The method of claim 15, wherein forming the first opening includes etching the pedestal oxide stack using an etchant, the first oxide sub-layer having a first lateral etch rate to the etchant, the second oxide sub-layer having a second lateral etch rate to the etchant that is less than the first lateral etch rate.

19. The method of claim 15, wherein forming the pedestal oxide stack includes:
depositing the first oxide sub-layer using plasma enhanced atomic layer deposition (PEALD) or low pressure chemical vapor deposition (LPCVD); and
depositing the second oxide sub-layer using plasma enhanced chemical vapor deposition (PECVD).

20. The method of claim 15, wherein forming the BJT includes epitaxially growing a collector layer on the semiconductor substrate and in the first opening.
